(19) United States
(12) Patent Application Publication
(10) Pub. No.: US 2026/0223459 A1
(43) Pub. Date: Jul. 30, 2026

(54) SEMICONDUCTOR DEVICE AND MANUFACTURING METHOD OF SEMICONDUCTOR DEVICE

(71) Applicant: SEMICONDUCTOR ENERGY LABORATORY CO., LTD., Atsugi-shi, Kanagawa-ken (JP)

(72) Inventors: Yukinori SHIMA, Tatebayashi, Gunma (JP); Masami JINTYOU, Shimotsuga, Tochigi (JP); Junichi KOEZUKA, Tochigi, Tochigi (JP)

(21) Appl. No.: 19/148,510

(22) PCT Filed: Jan. 26, 2024
(86) PCT No.: PCT/IB2024/050730

§ 371 Date: Jul. 16, 2025

(30) Foreign Application Priority Data
Feb. 2, 2023 (JP) 2023-014450

(51) Int. Cl. H10D 86/40; H10D 30/01; H10D 30/67; H10D 86/01; H10D 86/60; H10K 59/121

(52) U.S. Cl. CPC H10D 86/471; H10D 30/0314; H10D 30/0318; H10D 30/6728; H10D 30/6731; H10D 30/6736; H10D 86/0221; H10D 86/0231; H10D 86/0251; H10D 86/431; H10D 86/60; H10K 59/1213

(57) ABSTRACT

A semiconductor device with favorable electrical characteristics is provided. The semiconductor device includes a transistor and a first insulating layer. The transistor includes a source electrode, a drain electrode, a semiconductor layer, a gate insulating layer, and a gate electrode. The source electrode and the drain electrode each have a top surface with any of a circular shape, an elliptical shape, and a polygonal shape with a rounded corner and are provided in columnar shapes to face each other to be embedded in the first insulating layer. The first insulating layer includes an opening between the source electrode and the drain electrode. In the opening, the semiconductor layer is provided in contact with a side surface of the source electrode and a side surface of the drain electrode facing each other and a side surface of the first insulating layer between the source electrode and the drain electrode. In the opening, the gate insulating layer is provided in contact with a side surface of the semiconductor layer. In the opening, the gate electrode is provided in contact with a side surface of the gate insulating layer to include a region facing the semiconductor layer.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display apparatus including a semiconductor device.

Note that one embodiment of the present invention is not limited to the above technical field. Examples of the technical field of one embodiment of the present invention include a semiconductor device, a display apparatus, a light-emitting apparatus, a power storage device, a memory device, a lighting device, an input device (e.g., a touch sensor), an input/output device (e.g., a touch panel), an electronic appliance including any of them, a method of driving any of them, and a manufacturing method of any of them.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device.

Moreover, a memory device, a display apparatus, a light-emitting apparatus, a lighting device, and an electronic appliance themselves are semiconductor devices and each of them includes a semiconductor device in some cases.

### BACKGROUND ART

Semiconductor devices that include transistors are applied to a wide range of electronic appliances. Uses for a display apparatus are diversified in recent years, and for example, the display apparatus is used for a portable information terminal, a television device (also referred to as a television receiver), digital signage, and a PID (Public Information Display). Examples of the display apparatus include a display apparatus including an organic EL (Electro Luminescence) element or a light-emitting diode (LED), a display apparatus including a liquid crystal element, and electronic paper performing display by an electrophoretic method.

In a display apparatus, when the area occupied by transistors is reduced, the pixel size can be reduced and resolution can be increased. Furthermore, when the area occupied by transistors is reduced, the aperture ratio can be increased. Thus, minute transistors have been required.

As devices requiring high-resolution display apparatuses, for example, devices for virtual reality (VR), augmented reality (AR), substitutional reality (SR), or mixed reality (MR) have been actively developed.

Patent Document 1 discloses a high-resolution display apparatus using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a transistor having a minute size. Another object of one embodiment of the present invention is to provide a transistor having a long channel length. Another object of one embodiment of the present invention is to provide a transistor or a semiconductor device with favorable electrical characteristics. Another object of one embodiment of the present invention is to provide a semiconductor device that occupies a small area. Another object of one embodiment of the present invention is to provide a semiconductor device or a display apparatus with low power consumption. Another object of one embodiment of the present invention is to provide a highly reliable transistor, a highly reliable semiconductor device, or a highly reliable display apparatus. Another object of one embodiment of the present invention is to provide a display apparatus that can easily achieve a higher resolution. Another object of one embodiment of the present invention is to provide a method for manufacturing a semiconductor device with high productivity or a display apparatus with high productivity. Another object of one embodiment of the present invention is to provide a novel transistor, a novel semiconductor device, a novel display apparatus, or manufacturing methods thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a transistor and a first insulating layer. The transistor includes a source electrode, a drain electrode, a semiconductor layer, a gate insulating layer, and a gate electrode. The source electrode and the drain electrode each have a top surface with any of a circular shape, an elliptical shape, and a polygonal shape with a rounded corner and are provided in columnar shapes to face each other to be embedded in the first insulating layer. The first insulating layer includes an opening between the source electrode and the drain electrode. In the opening, the semiconductor layer is provided in contact with a side surface of the source electrode and a side surface of the drain electrode facing each other and a side surface of the first insulating layer between the source electrode and the drain electrode. In the opening, the gate insulating layer is provided in contact with a side surface of the semiconductor layer. In the opening, the gate electrode is provided in contact with a side surface of the gate insulating layer to include a region facing the semiconductor layer.

In the above, it is preferable that the semiconductor layer include a metal oxide.

In the above, it is preferable that the first insulating layer include a second insulating layer, a third insulating layer over the second insulating layer, and a fourth insulating layer over the third insulating layer, that the second insulating layer and the fourth insulating layer include one or both of a nitride and a nitride oxide, and that the third insulating layer include one or both of an oxide and an oxynitride.

In the above, it is preferable that a top surface of the source electrode, a top surface of the drain electrode, and a top surface of the first insulating layer be substantially level with one another.

In the above, it is preferable that a top surface shape of the opening be any of a circle, an ellipse, a polygon with a rounded corner, and a closed curve that combines a straight line and a curve.

Another embodiment of the present invention is a method for manufacturing a semiconductor device. The method includes the steps of forming a first insulating layer; processing the first insulating layer to form a first opening and a second opening; forming a first conductive film over the first insulating layer to fill the first opening and the second opening; performing CMP treatment on the first conductive film until a top surface of the first insulating layer is exposed, thereby forming, in the first opening, a first conductive layer having a top surface substantially level with the top surface of the first insulating layer and forming, in the second opening, a second conductive layer having a top surface substantially level with the top surface of the first insulating layer; processing the first insulating layer to form a third opening between the first conductive layer and the second conductive layer; forming a first metal oxide film in contact with the top surface and a side surface of the first conductive layer, the top surface and a side surface of the second conductive layer, and the top surface and a side surface of the first insulating layer, thereby covering the third opening; processing the first metal oxide film to form a semiconductor layer in contact with the side surface of the first conductive layer in the third opening, the side surface of the second conductive layer in the third opening, and the side surface of the first insulating layer in the third opening; forming a second insulating layer over the semiconductor layer, the first conductive layer, the second conductive layer, and the first insulating layer; forming a second conductive film over the second insulating layer; and processing the second conductive film to form a third conductive layer that includes a region overlapping with the semiconductor layer in a plan view.

In the above, it is preferable that the first insulating layer include a third insulating layer, a fourth insulating layer over the third insulating layer, and a fifth insulating layer over the fourth insulating layer; the third insulating layer and the fifth insulating layer be formed using a material including any one or more of a nitride and a nitride oxide; and the fourth insulating layer be formed using a material including any one or more of an oxide and an oxynitride.

In the above, it is preferable that anisotropic etching be used for processing the first metal oxide film.

In the above, it is preferable that etching treatment through a resist mask be used for processing the first metal oxide film.

In the above, it is preferable that a second metal oxide film be formed after the formation of the third insulating layer and the fourth insulating layer and a fifth insulating layer be formed after the removal of the second metal oxide film.

In the above, it is preferable that a second metal oxide film be formed after the formation of the third insulating layer and the fourth insulating layer and heat treatment be performed after the formation of the second metal oxide film.

In the above, it is preferable that a second metal oxide film be formed after the formation of the third insulating layer and the fourth insulating layer and treatment for supplying oxygen to the fourth insulating layer be performed after the formation of the second metal oxide film.

### Effect of the Invention

According to one embodiment of the present invention, a transistor having a minute size can be provided. According to another embodiment of the present invention, a transistor having a long channel length can be provided. According to another embodiment of the present invention, a transistor or a semiconductor device with favorable electrical characteristics can be provided. According to another embodiment of the present invention, a semiconductor device that occupies a small area can be provided. According to another embodiment of the present invention, a semiconductor device or display apparatus with low power consumption can be provided. According to another embodiment of the present invention, a highly reliable transistor, a highly reliable semiconductor device, or a highly reliable display apparatus can be provided. According to another embodiment of the present invention, a display apparatus that can easily achieve a higher resolution can be provided. According to another embodiment of the present invention, a method for manufacturing a semiconductor device with high productivity or a display apparatus with high productivity can be provided. According to another embodiment of the present invention, a novel transistor, a novel semiconductor device, a novel display apparatus, or manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a schematic perspective view illustrating an example of a semiconductor device. FIG. 1B is a plan view illustrating an example of the semiconductor device.

FIGS. 2A and 2B are cross-sectional views illustrating an example of a semiconductor device.

FIG. 3A is a schematic perspective view illustrating an example of a semiconductor device. FIG. 3B is a plan view illustrating an example of the semiconductor device.

FIG. 4A and FIG. 4B are cross-sectional views illustrating an example of a semiconductor device.

FIG. 5A is a schematic perspective view illustrating an example of a semiconductor device. FIG. 5B is a plan view illustrating an example of the semiconductor device.

FIG. 6A and FIG. 6B are cross-sectional views illustrating an example of a semiconductor device.

FIG. 7A is a schematic perspective view illustrating an example of a semiconductor device. FIG. 7B is a plan view illustrating an example of the semiconductor device.

FIG. 8A and FIG. 8B are cross-sectional views illustrating an example of a semiconductor device.

FIG. 9A is a schematic perspective view illustrating an example of a semiconductor device. FIG. 9B is a plan view illustrating an example of the semiconductor device.

FIG. 10A and FIG. 10B are cross-sectional views illustrating an example of a semiconductor device.

FIG. 11A is a schematic perspective view illustrating an example of a semiconductor device. FIG. 11B is a plan view illustrating an example of the semiconductor device.

FIG. 12A and FIG. 12B are cross-sectional views illustrating an example of a semiconductor device.

FIG. 13A is a plan view illustrating an example of a semiconductor device. FIG. 13B is a cross-sectional view illustrating an example of the semiconductor device.

FIG. 14A is a plan view illustrating an example of a semiconductor device. FIG. 14B is a cross-sectional view illustrating an example of the semiconductor device.

FIG. 15 is a cross-sectional view illustrating an example of a semiconductor device.

FIG. 16A is a plan view illustrating an example of a semiconductor device. FIG. 16B is a cross-sectional view illustrating an example of the semiconductor device.

FIG. 17A to FIG. 17C are cross-sectional views illustrating an example of a method for manufacturing a semiconductor device.

FIG. 18A to FIG. 18C are cross-sectional views illustrating an example of a method for manufacturing a semiconductor device.

FIG. 19A to FIG. 19C are cross-sectional views illustrating an example of a method for manufacturing a semiconductor device.

FIG. 20A and FIG. 20B are cross-sectional views illustrating an example of a method for manufacturing a semiconductor device.

FIG. 21 is a cross-sectional view illustrating an example of a method for manufacturing a semiconductor device.

FIG. 22A to FIG. 22D are cross-sectional views illustrating an example of a method for manufacturing a semiconductor device.

FIG. 23A to FIG. 23C are cross-sectional views illustrating an example of a method for manufacturing a semiconductor device.

FIG. 24A to FIG. 24C are cross-sectional views illustrating an example of a method for manufacturing a semiconductor device.

FIG. 25A to FIG. 25C are cross-sectional views illustrating an example of a method for manufacturing a semiconductor device.

FIG. 26A is a perspective view illustrating an example of a display apparatus. FIG. 26B is a block diagram illustrating an example of the display apparatus.

FIG. 27A is a circuit diagram of a latch circuit. FIG. 27B is a circuit diagram of an inverter circuit.

FIG. 28A and FIG. 28B are circuit diagrams of pixel circuits. FIG. 28C is a cross-sectional view illustrating an example of a pixel circuit.

FIG. 29 is a schematic cross-sectional view illustrating a structure example of a display apparatus.

FIG. 30A and FIG. 30B are diagrams illustrating a structure example of an electronic device.

FIG. 31A and FIG. 31B are diagrams illustrating a structure example of an electronic device.

FIG. 32A and FIG. 32B are diagrams illustrating a structure example of a display apparatus.

FIG. 33 is a diagram illustrating a structure example of a display apparatus.

FIG. 34A to FIG. 34C are perspective views each illustrating a display module.

FIG. 35A and FIG. 35B are diagrams illustrating a structure example of a display apparatus.

FIG. 36A to FIG. 36D are circuit diagrams of pixel circuits.

FIG. 37A to FIG. 37D are circuit diagrams of pixel circuits.

FIG. 38A and FIG. 38B are diagrams illustrating a structure example of a display apparatus.

FIG. 39A to FIG. 39D are diagrams illustrating a structure example of a display apparatus.

FIG. 40A to FIG. 40C are diagrams illustrating a structure example of a display apparatus.

FIG. 41A to FIG. 41F are diagrams illustrating examples of electronic appliances.

FIG. 42A to FIG. 42G are diagrams illustrating examples of electronic appliances.

FIG. 43A is a diagram illustrating a sub-display portion. FIG. 43B1 to FIG. 43B7 are diagrams illustrating pixel structure examples.

FIG. 44A to FIG. 44G are diagrams illustrating pixel structure examples.

FIG. 45A to FIG. 45D are diagrams illustrating structure examples of a light-emitting device.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

In this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor element and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification and the like.

Functions of a “source” and a “drain” are sometimes replaced with each other when a transistor of opposite polarity is used or when the direction of current is changed in circuit operation, for example. Thus, the terms “source” and “drain” can be used interchangeably in this specification and the like. Note that a source and a drain of a transistor can be rephrased as a source terminal and a drain terminal, a source electrode and a drain electrode, or the like as appropriate depending on the circumstances.

A “gate” and a “back gate” can be replaced with each other. Thus, the terms “gate” and “back gate” can be used interchangeably in this specification and the like. Note that the gate and the back gate of a transistor can also be referred to as a gate electrode and a back gate electrode, for example, as appropriate depending on the circumstances.

In this specification and the like, the expression “A and B are connected” means the case where A and B are electrically connected as well as the case where A and B are directly connected. Here, the expression “A and B are electrically connected” means the case where electric signals can be transmitted and received between A and B when an object having any electric action is present between A and B.

Unless otherwise specified, off-state current in this specification and the like refers to leakage current between a source and a drain of a transistor in an off state (also referred to as a non-conduction state or a cut-off state). Unless otherwise specified, the off state refers to a state where voltage V_{gs} between a gate and a source is lower than threshold voltage Vₜᵢₕ in an n-channel transistor (higher than Vth in a p-channel transistor).

In this specification and the like, the expression “having substantially the same top surface shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top surface shapes are substantially the same”. The state of “having the same top surface shape” or “having substantially the same top surface shapes” can be rephrased as the state where “end portions are aligned with each other” or “end portions are substantially aligned with each other”.

Note that in this specification and the like, the top surface shape of a component means the shape of the outline of the component in a plan view. A plan view means that the component is observed from a normal direction of a surface where the component is formed or from a normal direction of a surface of a support (e.g., a substrate) where the component is formed.

In this specification and the like, the expression “substantially level” indicates a structure in which levels from a reference surface (e.g., a flat surface such as a substrate surface) are substantially the same in a cross-sectional view. In addition, in this specification and the like, the expression “substantially aligned” includes both “perfectly aligned” and “substantially aligned”.

In this specification and the like, a tapered shape refers to a shape where at least part of a side surface of a component is inclined with respect to a substrate surface or a formation surface. For example, a tapered shape refers to a shape where the angle formed by the inclined side surface and the substrate surface or the formation surface (such an angle is also referred to as a taper angle) is less than 90°. Note that the side surface, the substrate surface, and the formation surface of the component are not necessarily completely flat and may have a substantially flat shape with a slight curvature or a substantially flat shape with slight unevenness.

In this specification and the like, a device manufactured using a metal mask or an FMM (fine metal mask, high-resolution metal mask) may be referred to as a device having an MM (metal mask) structure. In this specification and the like, a device manufactured without using a metal mask or an FMM may be referred to as a device having an MML (metal maskless) structure. Note that the device having an MML structure can be manufactured without using a metal mask, and thus can break through the resolution limit due to alignment accuracy of the metal mask. Furthermore, the device having an MML structure can eliminate the need for the manufacturing facilities for metal masks and washing process for metal masks. The manufacturing cost of the device having an MML structure can be low, which is suitable for mass production.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer has two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a mask layer (may be referred to as a sacrificial layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

The semiconductor device of one embodiment of the present invention includes a transistor and an insulating layer. A source electrode and a drain electrode of the transistor are provided to face each other and to be embedded in the insulating layer. The insulating layer includes an opening between the source electrode and the drain electrode of the transistor. In the opening, part of a side surface of the source electrode and part of a side surface of the drain electrode are exposed. The height of the opening and the height of each of the exposed portions of the source electrode and the drain electrode are substantially the same. A semiconductor layer of the transistor is provided to include a region that is in the opening and in contact with the side surface or the top surface of each of the source electrode and the drain electrode or both the side surface and the top surface thereof. The semiconductor layer is provided to include a region in contact with a side surface of the insulating layer in the opening. Note that the bottom surface of the opening has a region not provided with the semiconductor layer.

That is, in the semiconductor device of one embodiment of the present invention, a region of the semiconductor layer along the side surface of the insulating layer in the opening positioned between the source electrode and the drain electrode functions as a channel formation region of the transistor. In that case, the distance between the source electrode and the drain electrode along the side surface corresponds to the channel length of the transistor, and the depth (height) of the side surface corresponds to the channel width of the transistor. Therefore, the channel width of the transistor is changed by adjusting the thickness of the insulating layer in which the source electrode and the drain electrode are embedded, so that the amount of on-state current of the transistor can be adjusted.

For example, a smaller thickness of the insulating layer enables a smaller channel width of the transistor and a lower ratio of the channel width to the channel length of the transistor. Thus, the transistor can have a lower on-state current. Conversely, a larger thickness of the insulating layer enables a larger channel width of the transistor and a higher ratio of the channel width to the channel length of the transistor. Accordingly, the transistor can have a higher on-state current.

In the semiconductor device of one embodiment of the present invention, the source electrode and the drain electrode of the transistor each have a columnar shape. The top surface shapes of the columnar source electrode and drain electrode may each be a circle, an ellipse, a polygon such as a quadrangle, or a polygon with rounded corners. More complicated top surface shapes of the source electrode and the drain electrode can increase the contact area (i.e., reduce the contact resistance) between the semiconductor layer of the transistor and each of the source electrode and the drain electrode. Accordingly, the on-state current of the transistor can be increased. When the source electrode and the drain electrode can have a variety of top surface shapes, the degree of flexibility in manufacturing the semiconductor device can be increased.

In the semiconductor device of one embodiment of the present invention, the opening provided in the insulating layer (the opening provided between the source electrode and the drain electrode of the transistor) can have a variety of top surface shapes such as a polygon like a quadrangle, a circle, an ellipse, a polygon with rounded corners, and a closed curve that combines a straight line and a curve. A more complicated top surface shape of the opening increases the channel length of the transistor included in the semiconductor device, resulting in a reduction in the ratio of the channel width to the channel length of the transistor. Accordingly, the on-state current of the transistor included in the semiconductor device can be reduced to a small value.

Moreover, when the opening can have a variety of top surface shapes, the degree of flexibility in manufacturing the semiconductor device can be increased.

As described above, since part of the transistor (specifically, the source electrode and the drain electrode) is embedded in the insulating layer in the semiconductor device of one embodiment of the present invention, the channel width of the transistor can be adjusted by the thickness of the insulating layer. Thus, even a minute transistor can have a sufficient channel width and thus have a high on-state current. Conversely, even when the source electrode and the drain electrode of the transistor each have a large area in a substrate plane, reducing the thickness of the insulating layer can reduce the channel width of the transistor, so that the on-state current can be reduced.

In the semiconductor device of one embodiment of the present invention, when the top surface shape of the source electrode and the drain electrode of the transistor or the top surface shape of the opening in the insulating layer provided between the source electrode and the drain electrode is different for each transistor, a plurality of transistors with different on-state current values can be manufactured in the substrate plane. Thus, even when the semiconductor device includes a plurality of transistors in the substrate plane at a high density, each of the transistors can be manufactured with high productivity and a high yield. Moreover, the degree of flexibility in manufacturing the semiconductor device can be increased.

Structure examples of the semiconductor device of one embodiment of the present invention will be described below with reference to drawings.

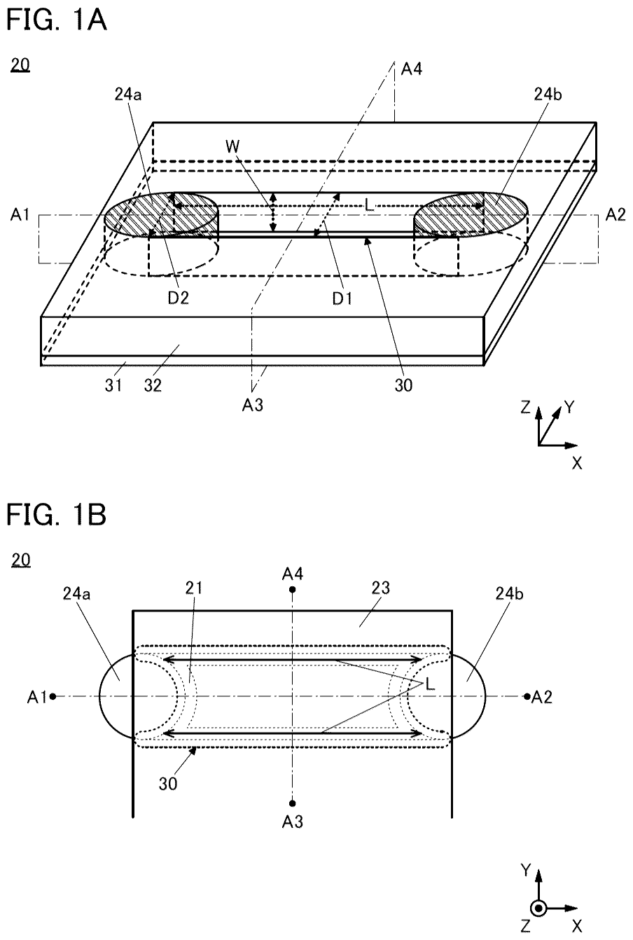

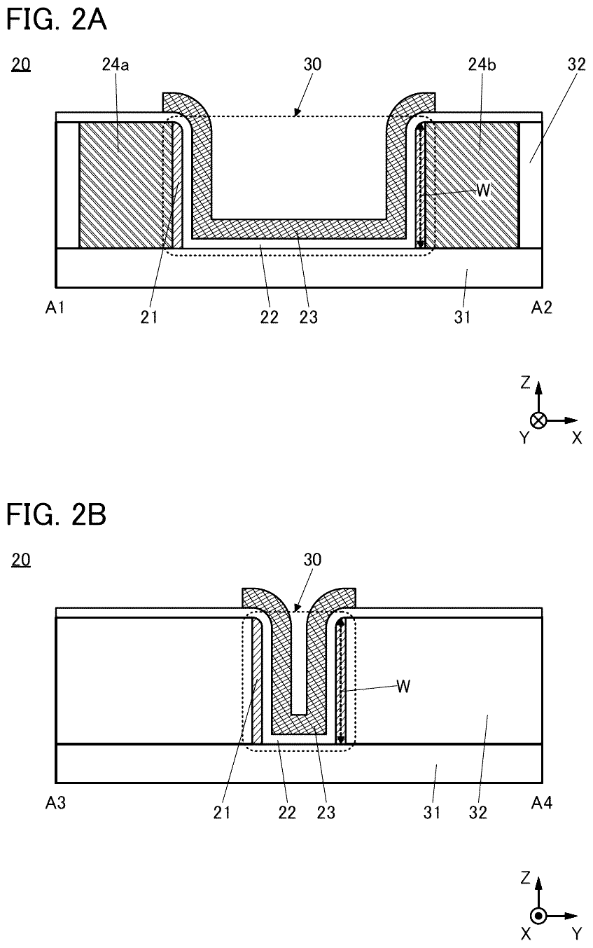

FIG. 1A is a schematic perspective view of a semiconductor device 20. FIG. 1B is a plan view (also referred to as a top view) of the semiconductor device 20. FIG. 2A is a cross-sectional view taken along the dashed-dotted line A1-A2 in FIG. 1A and FIG. 1B. FIG. 2B is a cross-sectional view taken along the dashed-dotted line A3-A4 in FIG. 1A and FIG. 1B. Note that in FIG. 1A, some components of the semiconductor device 20 are omitted for easy viewing.

The semiconductor device 20 includes a transistor and an insulating layer 32. The transistor includes a conductive layer 24a, a conductive layer 24b, a semiconductor layer 21, an insulating layer 22, and a conductive layer 23. In the transistor, the conductive layer 24a functions as one of a source electrode and a drain electrode. The conductive layer 24b functions as the other of the source electrode and the drain electrode. The semiconductor layer 21 functions as a semiconductor layer where a channel is formed. The conductive layer 23 functions as a gate electrode (a first gate electrode). Part of the insulating layer 22 (specifically, a region sandwiched between the semiconductor layer 21 and the conductive layer 23) functions as a gate insulating layer (a first gate insulating layer).

Although the top surface shapes of the source electrode and the drain electrode (the conductive layer 24a and the conductive layer 24b) of the transistor included in the semiconductor device 20 are circular in FIG. 1A and FIG. 1B, one embodiment of the present invention is not limited thereto. The top surface shape is not limited to a circle, but may be an ellipse, a quadrangle, or a quadrangle with rounded corners, for example. It is also possible to employ a regular polygonal shape such as a regular triangle, a square, or a regular pentagon, a polygonal shape other than the regular polygonal shape, or a polygonal shape with rounded corners. Alternatively, a concave polygonal shape, which is a polygon that has at least one interior angle greater than 180°, such as a star polygon, may be employed. A closed curve that combines a straight line and a curve may also be employed. The same applies to structure examples of semiconductor devices described later.

In particular, the top surfaces of the source electrode and the drain electrode (the conductive layer 24a and the conductive layer 24b) of the transistor included in the semiconductor device 20 each preferably have a shape with a curved periphery such as a circle, an ellipse, or a quadrangle with rounded corners. This facilitates processing of the source electrode and the drain electrode even with a minute planar size.

The insulating layer 32 is provided over an insulating layer 31. The conductive layer 24a and the conductive layer 24b are provided over the insulating layer 31 so as to face each other and to be embedded in the insulating layer 32. The insulating layer 32 includes an opening 30 reaching the insulating layer 31 between the conductive layer 24a and the conductive layer 24b. The semiconductor layer 21 is provided in contact with side surfaces of the conductive layer 24a and the conductive layer 24b that face each other and side surfaces of the insulating layer 32 between the conductive layer 24a and the conductive layer 24b in the opening 30. Note that the bottom surface (the top surface of the insulating layer 31) of the opening 30 has a region not provided with the semiconductor layer 21. The insulating layer 22 is provided in contact with side surfaces of the semiconductor layer 21 and the top surface of the insulating layer 31 in the opening 30. The conductive layer 23 is provided in contact with side surfaces of the insulating layer 22 to include a region facing the semiconductor layer 21 in the opening 30.

As illustrated in FIG. 1A and FIG. 2A, the top surface of the conductive layer 24a, the top surface of the conductive layer 24b, and the top surface of the insulating layer 32 are substantially level with one another

Although FIG. 1A, FIG. 2A, and FIG. 2B illustrate an example in which the thickness of the insulating layer 31 in a region overlapping with the opening 30 is equal to the thickness of the insulating layer 31 in a region not overlapping with the opening 30, one embodiment of the present invention is not limited thereto. For example, the thickness of the insulating layer 31 in the region overlapping with the opening 30 may be smaller than the thickness of the insulating layer 31 in the region not overlapping with the opening 30. The same applies to structure examples of semiconductor devices described later.

As described above, the semiconductor layer 21 is provided along a sidewall of the opening 30 (the side surfaces of the conductive layer 24a and the conductive layer 24b and the side surface of the insulating layer 32 between the conductive layer 24a and the conductive layer 24b) (FIG. 1B, FIG. 2A, and FIG. 2B). Thus, in the transistor included in the semiconductor device 20 of one embodiment of the present invention, as illustrated in FIG. 1A, a channel length L corresponds to the distance along the side surface of the insulating layer 32 between the conductive layer 24a and the conductive layer 24b in the opening 30. The channel width W corresponds to the width of the semiconductor layer 21 along the depth direction of the opening 30. That is, the X direction (A1-A2 direction) illustrated in FIG. 1A corresponds to the channel length direction of the transistor included in the semiconductor device 20, and the Z direction corresponds to the channel width direction of the transistor included in the semiconductor device 20.

Here, as an index showing the characteristics of the transistor, the ratio of the channel width W to the channel length L (W/L ratio) is sometimes used. In a planar transistor, for example, the minimum values of the channel length and the channel width depend on the light exposure limit of a light-exposure apparatus; thus, L needs to be increased in the case where the W/L ratio is to be small (i.e., the on-state current is to be small) and W needs to be increased in the case where the W/L ratio is to be large (i.e., the on-state current is to be large), leading to a problem in which the area occupied by the transistor is increased in both cases.

In view of this, in the semiconductor device 20 of one embodiment of the present invention, the channel width W of the transistor included in the semiconductor device can be controlled by the thickness of the insulating layer 32 (the depth of the opening 30). That is, the contact area between the semiconductor layer 21 and each of the conductive layer 24a and the conductive layer 24b (i.e., the area of the side surfaces of the conductive layer 24a and the conductive layer 24b illustrated in FIG. 1A in the opening 30) can be adjusted by the thickness of the insulating layer 32. In other words, the channel width W of the transistor can be adjusted by the thickness of the insulating layer 32. The W/L ratio of the transistor can be changed by adjusting the channel width W of the transistor; thus, the amount of on-state current of the transistor included in the semiconductor device 20 can be controlled by adjusting the thickness of the insulating layer 32. For example, when the thickness of the insulating layer 32 is small (the channel width W of the transistor is small), the W/L ratio of the transistor can be reduced, so that the on-state current of the transistor can be reduced. When the thickness of the insulating layer 32 is large (the channel width W of the transistor is large), the W/L ratio of the transistor can be increased, so that the on-state current of the transistor can be increased.

As described above, the transistor included in the semiconductor device 20 of one embodiment of the present invention includes the columnar conductive layer 24a and conductive layer 24b that can have a variety of top surface shapes. Thus, by adjusting these top surface shapes, the top surface shape of the opening 30, and the position where the opening 30 is formed, the contact area between the semiconductor layer 21 and each of the conductive layer 24a and the conductive layer 24b (i.e., the area of the side surfaces of the conductive layer 24a and the conductive layer 24b illustrated in FIG. 1A in the opening 30) can be changed. A change in the contact area between the semiconductor layer 21 and each of the conductive layer 24a and the conductive layer 24b changes the contact resistance between the semiconductor layer 21 and each of the conductive layer 24a and the conductive layer 24b, thereby changing the amount of on-state current of the transistor. For example, when the conductive layer 24a and the conductive layer 24b each have a top surface shape so as to have a small contact area with the semiconductor layer 21, the contact resistance between the semiconductor layer 21 and each of the conductive layer 24a and the conductive layer 24b is increased, so that the on-state current of the transistor can be reduced. When the conductive layer 24a and the conductive layer 24b each have a top surface shape so as to have a large contact area with the semiconductor layer 21, the contact resistance between the semiconductor layer 21 and each of the conductive layer 24a and the conductive layer 24b is reduced, so that the on-state current of the transistor can be increased.

As described above, in the semiconductor device 20 of one embodiment of the present invention, the opening 30 can have a variety of top surface shapes. Thus, by adjusting these top surface shapes, the distance along the side surface of the insulating layer 32 between the conductive layer 24a and the conductive layer 24b in the opening 30 (i.e., the channel length L of the transistor included in the semiconductor device 20) can be changed. Since the W/L ratio of the transistor can be changed by adjusting the channel length L of the transistor, the amount of on-state current of the transistor included in the semiconductor device 20 can be controlled by adjusting the top surface shape of the opening 30. For example, the channel length L of the transistor included in the semiconductor device 20 increases as the top surface shape of the opening 30 becomes more complicated, which can reduce the W/L ratio of the transistor. Thus, the on-state current of the transistor can be reduced to a small value.

As described above, in the semiconductor device 20 of one embodiment of the present invention, the amount of on-state current of the transistor included in the semiconductor device 20 can be controlled by adjusting the thickness of the insulating layer 32, the top surface shapes of the conductive layer 24a and the conductive layer 24b, and the top surface shape of the opening 30. This allows even a minute transistor to have a high on-state current. Conversely, even a large-sized transistor can have on-state current reduced to a small value. Even when the semiconductor device 20 includes a plurality of transistors in the substrate plane, each of the transistors can be manufactured with high productivity and a high yield. Thus, a high-density semiconductor device with favorable electrical characteristics can be achieved. Moreover, the semiconductor device with a high degree of flexibility in manufacturing is achieved.

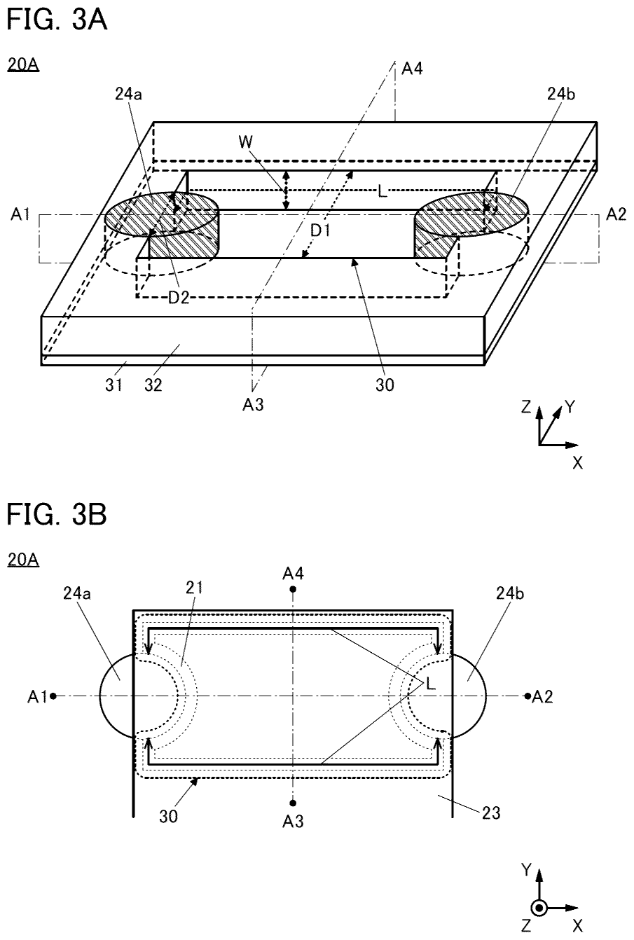

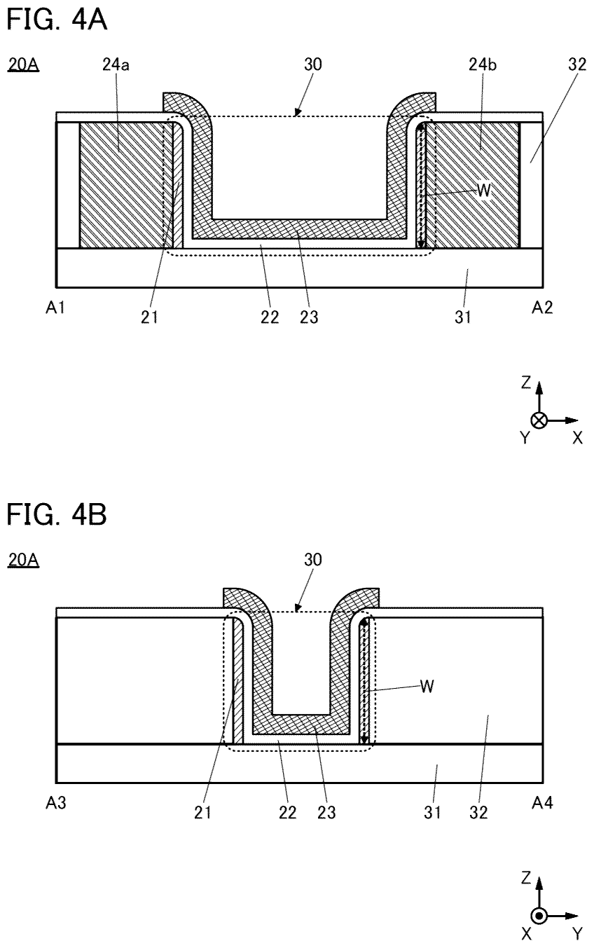

FIG. 3A to FIG. 4B illustrate structure examples of a semiconductor device 20A having a structure different from that of the semiconductor device 20 illustrated in FIG. 1A to FIG. 2B. FIG. 3A is a schematic perspective view of the semiconductor device 20A. FIG. 3B is a plan view of the semiconductor device 20A. FIG. 4A is a cross-sectional view taken along the dashed-dotted line A1-A2 in FIG. 3A and FIG. 3B. FIG. 4B is a cross-sectional view taken along the dashed-dotted line A3-A4 in FIG. 3A and FIG. 3B. Note that some components of the semiconductor device 20A are omitted in FIG. 3A for easy viewing.

Portions of the semiconductor device 20A that are different from those described with reference to the semiconductor device 20 are mainly described below, and the description of the portions already described is omitted in some cases.

The semiconductor device 20A is different from the semiconductor device 20 in that the length of the opening 30 in the Y direction (the A3-A4 direction, that is, a direction orthogonal to the channel length direction in the plan view) is longer than the length of the opening 30 in the Y direction of the semiconductor device 20.

Specifically, in the semiconductor device 20, the length (D1) of the opening 30 in the Y direction (A3-A4 direction) is substantially equal to the length (D2) of each of the conductive layer 24a and the conductive layer 24b in the Y direction (A3-A4 direction) (FIG. 1A). In contrast, the semiconductor device 20A has a structure in which the length D1 is longer than the length D2 (FIG. 3A).

In the transistor included in the semiconductor device 20A, the sum of the distance along the side surface of the insulating layer 32 in the opening 30 in the X direction (A1-A2 direction) and the distance along the side surface of the insulating layer 32 in the opening 30 in the Y direction (A3-A4 direction) between the conductive layer 24a and the conductive layer 24b corresponds to the channel length L. Thus, it can be said that the channel length L of the transistor included in the semiconductor device 20A is longer than that of the transistor included in the semiconductor device 20 by the latter distance.

Meanwhile, in the drawings, the channel width W is assumed to be the same in both the transistor included in the semiconductor device 20 and the transistor included in the semiconductor device 20A. Thus, the W/L ratio of the transistor included in the semiconductor device 20A is smaller than that of the transistor included in the semiconductor device 20. In other words, the semiconductor device 20A includes a transistor having a lower on-state current than the transistor included in the semiconductor device 20.

The description on the semiconductor device 20 can be referred to for components of the semiconductor device 20A other than the above.

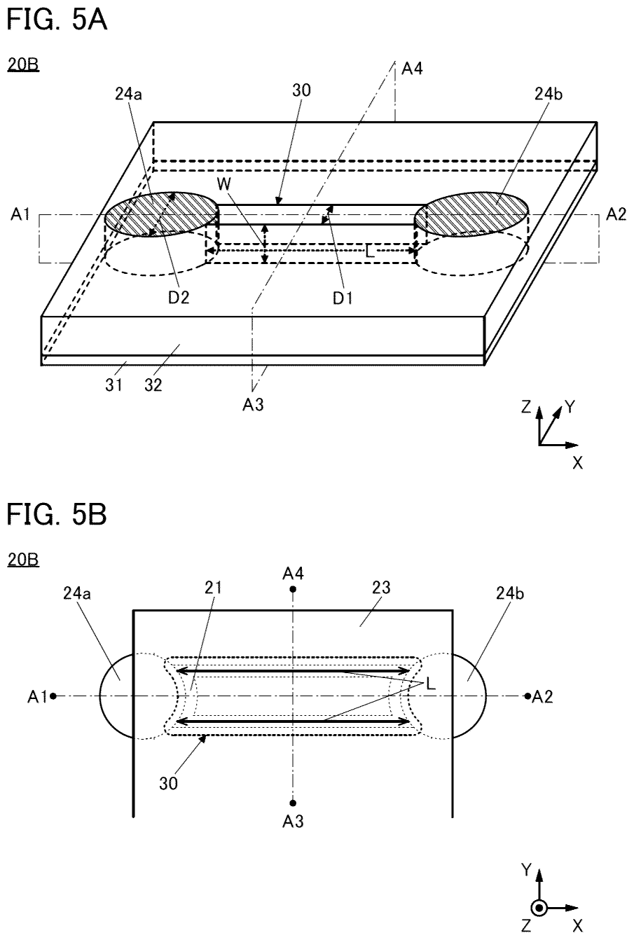

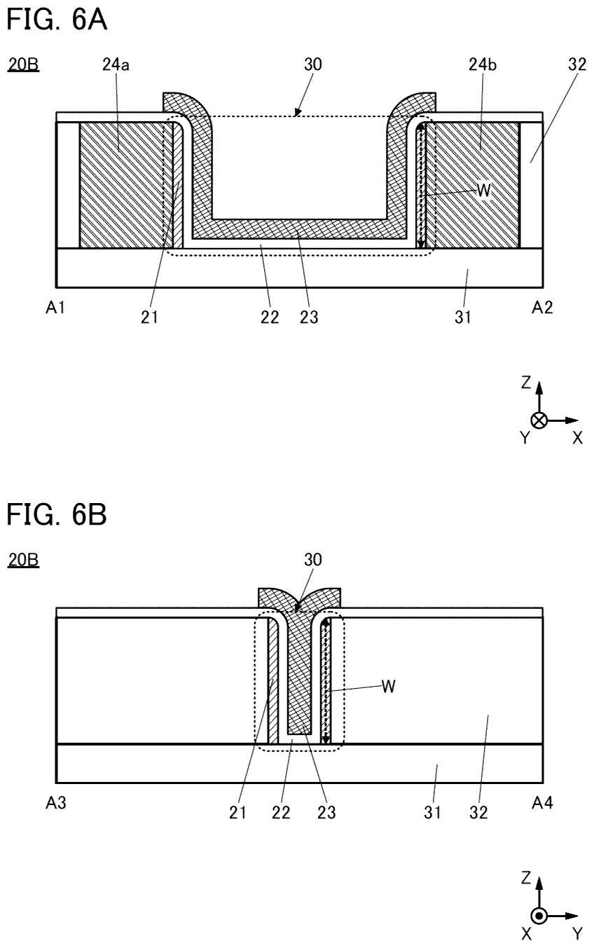

FIG. 5A to FIG. 6B illustrate structure examples of a semiconductor device 20B having a structure different from that of the semiconductor device 20 illustrated in FIG. 1A to FIG. 2B. FIG. 5A is a schematic perspective view of the semiconductor device 20B. FIG. 5B is a plan view of the semiconductor device 20B. FIG. 6A is a cross-sectional view taken along the dashed-dotted line A1-A2 in FIG. 5A and FIG. 5B. FIG. 6B is a cross-sectional view taken along the dashed-dotted line A3-A4 in FIG. 5A and FIG. 5B. Note that some components of the semiconductor device 20B are omitted in FIG. 5A for easy viewing.

Portions of the semiconductor device 20B that are different from those described with reference to the semiconductor device 20 are mainly described below, and the description of the portions already described is omitted in some cases.

The semiconductor device 20B is different from the semiconductor device 20 in that the length of the opening 30 in the Y direction (the A3-A4 direction, that is, a direction orthogonal to the channel length direction in the plan view) is shorter than the length of the opening 30 in the Y direction of the semiconductor device 20.

Specifically, in the semiconductor device 20, the length (D1) of the opening 30 in the Y direction (A3-A4 direction) is substantially equal to the length (D2) of each of the conductive layer 24a and the conductive layer 24b in the Y direction (A3-A4 direction) (FIG. 1A). In contrast, the semiconductor device 20B has a structure in which the length D1 is shorter than the length D2 (FIG. 5A).

FIG. 1A to FIG. 2B and FIG. 5A to FIG. 6B illustrate an example in which each of the semiconductor device 20 and the semiconductor device 20B includes the conductive layer 24a and the conductive layer 24b each with a cylindrical shape. Thus, the transistor included in the semiconductor device 20B with a structure in which the length D1 is shorter than the length D2 has a shorter channel length L than the transistor included in the semiconductor device 20 with a structure in which the length D1 is substantially equal to the length D2 (see FIG. 1B and FIG. 5B).

Meanwhile, the transistor included in the semiconductor device 20B has a smaller contact area between the semiconductor layer 21 and each of the conductive layer 24a and the conductive layer 24b (i.e., the area of the side surfaces of the conductive layer 24a and the conductive layer 24b in the opening 30) than the transistor included in the semiconductor device 20 (see FIG. 1A and FIG. 5A).

As described above, a transistor with a higher W/L ratio has a higher on-state current. On the other hand, a transistor with a smaller contact area between a semiconductor layer and each of a source electrode and a drain electrode has a lower on-state current. In other words, the on-state current of the transistor included in the semiconductor device 20B can be higher or lower than that of the transistor included in the semiconductor device 20 depending on the ratio of the length D2 to the length D1.

The description on the semiconductor device 20 can be referred to for components of the semiconductor device 20B other than the above.

As described above, in one embodiment of the present invention, the W/L ratio of the transistor and the contact area between the semiconductor layer and each of the source electrode and the drain electrode can be adjusted not only by adjusting the depth of the opening 30 (the thickness of the insulating layer 32) but also by adjusting the length of the opening 30 in the Y direction (the A3-A4 direction). For example, in the case where the semiconductor device includes a plurality of the transistors in a substrate plane, it is difficult to change the thickness of the insulating layer 32, in which the source electrode and the drain electrode of each of the transistors are embedded, for each transistor. In such a case, the length of the opening 30 in the Y direction (A3-A4 direction) is adjusted as described above, whereby a plurality of transistors with different W/L ratios in the substrate plane can be manufactured. In addition, a plurality of transistors with different contact areas between a semiconductor layer and each of a source electrode and a drain electrode can be manufactured. That is, a plurality of transistors with different on-state currents can be manufactured.

Note that a method for adjusting the channel length L of the transistor included in the semiconductor device of one embodiment of the present invention is not limited to the above. For example, the channel length L may be adjusted by adjusting the distance between the conductive layer 24a and the conductive layer 24b in the X direction (A1-A2 direction). Specifically, when the distance is shortened, the channel length L can be shortened; thus, a transistor with a high W/L ratio (a high on-state current) can be manufactured. Conversely, the channel length L can be increased when the distance is increased; thus, a transistor with a low W/L ratio (a low on-state current) can be manufactured.

As described above, in one embodiment of the present invention, by adjusting the depth of the opening 30 or the size of the opening 30 in the plan view (the length in the X direction or the length in the Y direction) appropriately, a semiconductor device including a plurality of transistors having desired electrical characteristics can be manufactured with high productivity and a high yield.

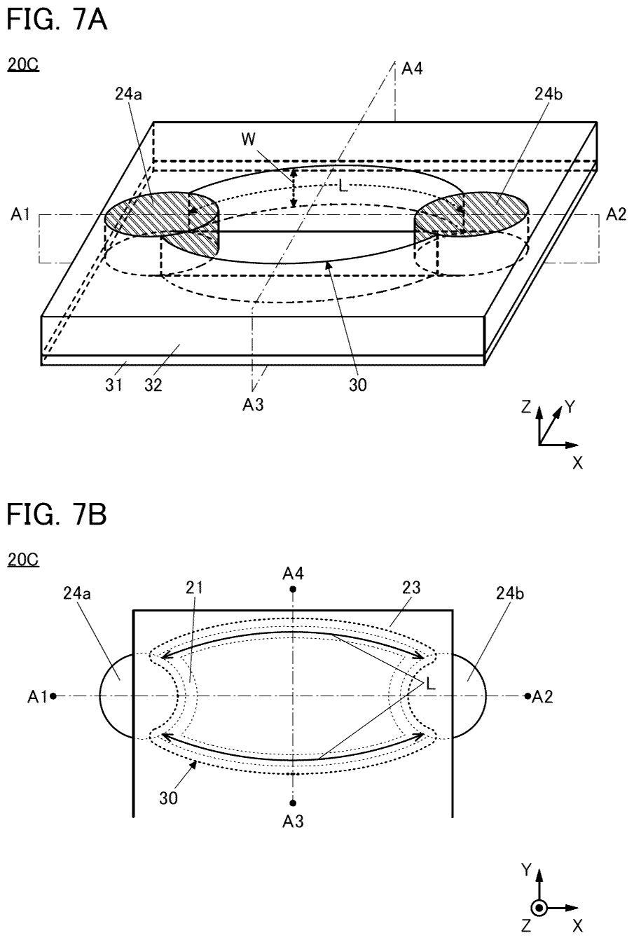

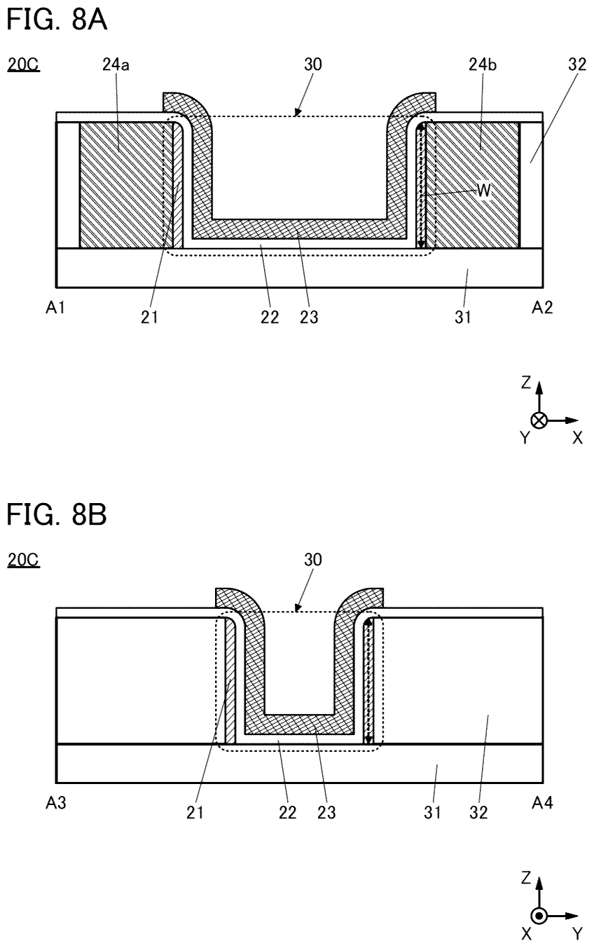

FIG. 7A to FIG. 8B illustrate structure examples of a semiconductor device 20C having a structure different from that of the semiconductor device 20. FIG. 7A is a schematic perspective view of the semiconductor device 20C. FIG. 7B is a plan view of the semiconductor device 20C. FIG. 8A is a cross-sectional view taken along the dashed-dotted line A1-A2 in FIG. 7A and FIG. 7B. FIG. 8B is a cross-sectional view taken along the dashed-dotted line A3-A4 in

FIG. 7A and FIG. 7B. Note that some components of the semiconductor device 20C are omitted in FIG. 7A for easy viewing.

Portions of the semiconductor device 20C that are different from those described with reference to the semiconductor device 20 are mainly described below, and the description of the portions already described is omitted in some cases.

As illustrated in FIG. 7A and FIG. 7B, the semiconductor device 20C is different from the semiconductor device 20 in that the top surface shape (the shape in the XY plane) of the opening 30 is elliptical.

In the semiconductor device 20C, the length of part of the periphery of the opening 30, which is positioned between the conductive layer 24a and the conductive layer 24b and indicated by an arrow (see FIG. 7B), corresponds to the channel length L of the transistor included in the semiconductor device 20C. Thus, in the case where the conductive layer 24a and the conductive layer 24b have a constant distance between them, the transistor included in the semiconductor device 20C can have a longer channel length L than the transistor included in the semiconductor device 20 (see FIG. 1B and FIG. 7B). That is, the transistor included in the semiconductor device 20C can have a lower on-state current than the transistor included in the semiconductor device 20.

The description on the semiconductor device 20C can be referred to for components of the semiconductor device 20 other than the above.

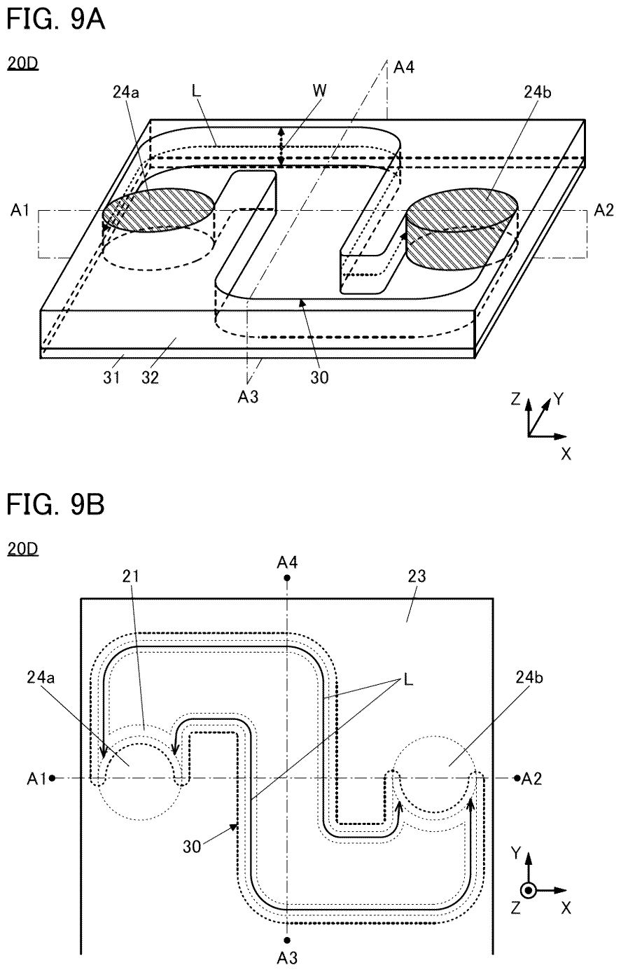

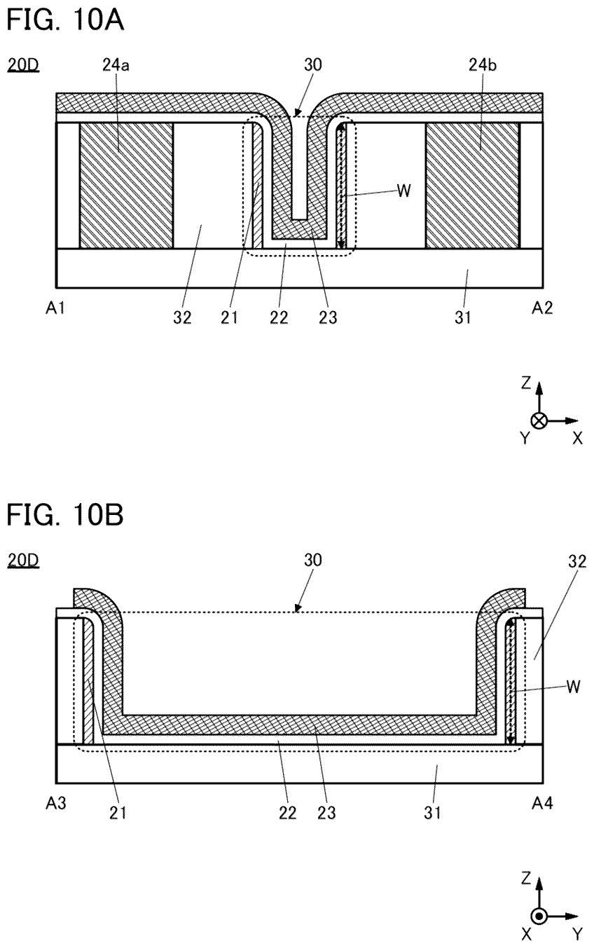

FIG. 9A to FIG. 10B illustrate structure examples of a semiconductor device 20D having a structure different from that of the semiconductor device 20 illustrated in FIG. 1A to FIG. 2B. FIG. 9A is a schematic perspective view of the semiconductor device 20D. FIG. 9B is a plan view of the semiconductor device 20D. FIG. 10A is a cross-sectional view taken along the dashed-dotted line A1-A2 in FIG. 9A and FIG. 9B. FIG. 10B is a cross-sectional view taken along the dashed-dotted line A3-A4 in FIG. 9A and FIG. 9B. Note that some components of the semiconductor device 20D are omitted in FIG. 9A for easy viewing.

Portions of the semiconductor device 20D that are different from those described with reference to the semiconductor device 20 are mainly described below, and the description of the portions already described is omitted in some cases.

The semiconductor device 20D is different from the semiconductor device 20 in that the top surface shape (the shape in the XY plane) of the opening 30 is an S shape (including an upside-down S shape and a zigzag shape).

In the semiconductor device 20D, the length of part of the periphery of the opening 30, which is positioned between the conductive layer 24a and the conductive layer 24b and indicated by an arrow (see FIG. 9B), corresponds to the channel length L of the transistor included in the semiconductor device 20D. Thus, in the case where the conductive layer 24a and the conductive layer 24b have a constant distance between them, the transistor included in the semiconductor device 20D can have a longer channel length L than the transistor included in the semiconductor device 20 (see FIG. 1B and FIG. 9B). Furthermore, the transistor included in the semiconductor device 20D can have a longer channel length L than the transistor included in the semiconductor device 20C (see FIG. 7B and FIG. 9B). That is, the transistor included in the semiconductor device 20D can have a lower on-state current than the transistor included in the semiconductor device 20, and can have a lower on-state current than the transistor included in the semiconductor device 20C.

The description on the semiconductor device 20D can be referred to for components of the semiconductor device 20 other than the above.

Thus, in the semiconductor device of one embodiment of the present invention, the opening 30 may have a top surface shape other than a quadrangular shape. This allows changing the channel length L of the transistor included in the semiconductor device, thereby controlling the amount of on-state current of the transistor. In addition, the degree of flexibility in the processing shape of the opening 30 can be increased; thus, in the case where the semiconductor device including a plurality of the transistors is manufactured in a substrate plane, the degree of integration of the transistors can be increased.

Note that the top surface shape of the opening 30 included in the semiconductor device of one embodiment of the present invention is not limited to the above and may be a variety of shapes. For example, a circular shape or a quadrangular shape with rounded corners may be employed. It is also possible to employ a regular polygonal shape such as a regular triangular shape, a square shape, or a regular pentagonal shape or a polygonal shape other than the regular polygonal shape. The channel length L can be increased by employing a concave polygonal shape, which is a polygon that has at least one interior angle greater than 180°, such as a star polygon. Alternatively, an elliptical shape, a quadrangular shape with rounded corners, and a closed curve that combines a straight line and a curve may also be employed. A more complicated top surface shape of the opening 30 thus increases the channel length L of the transistor included in the semiconductor device. Accordingly, the on-state current of the transistor included in the semiconductor device can be reduced to a small value.

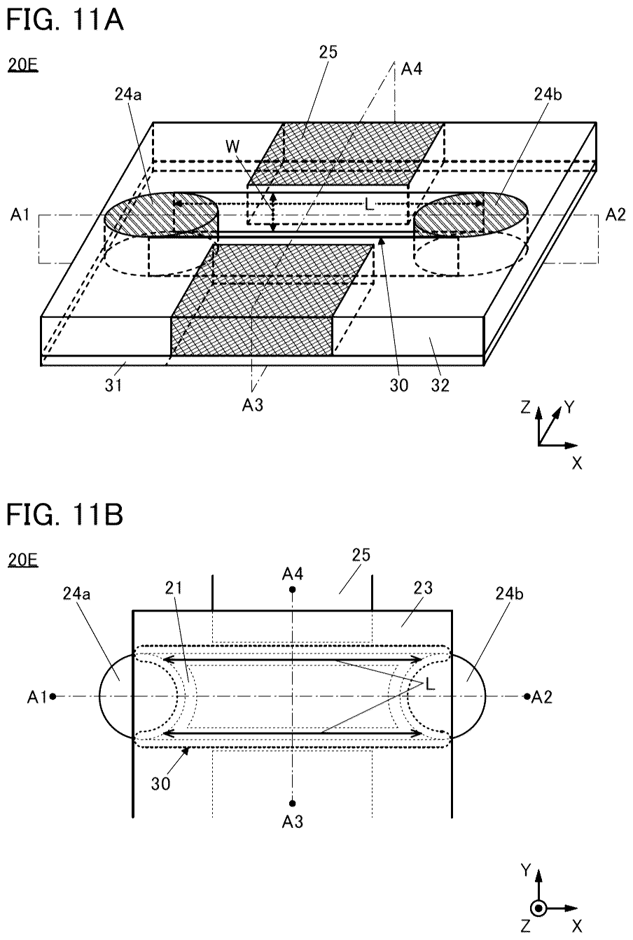

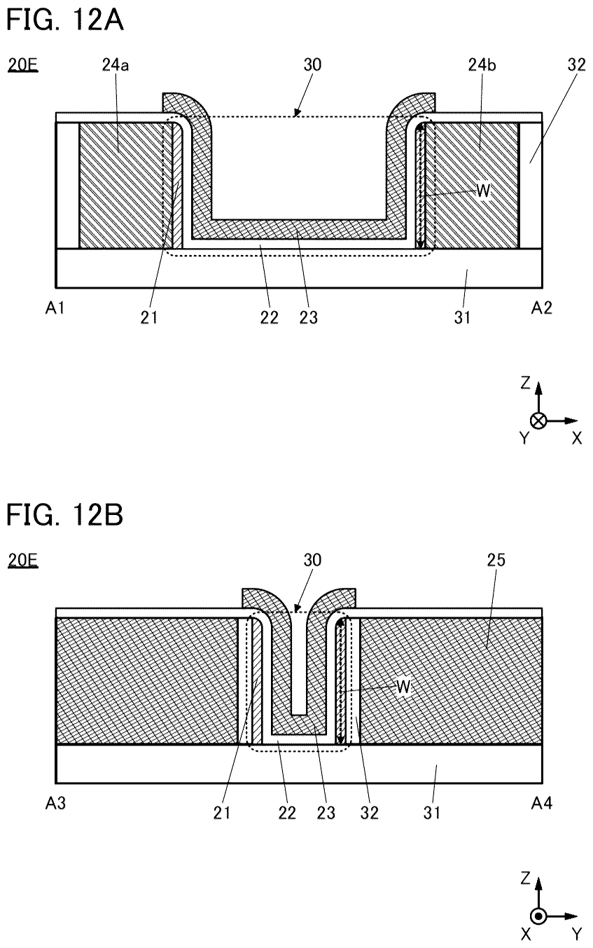

FIG. 11A is a schematic perspective view of a semiconductor device 20E. FIG. 11B is a plan view of the semiconductor device 20E. FIG. 12A is a cross-sectional view taken along the dashed-dotted line A1-A2 in FIG. 11A and FIG. 11B. FIG. 12B is a cross-sectional view taken along the dashed-dotted line A3-A4 in FIG. 11A and FIG. 11B. Note that in FIG. 11A, some components of the semiconductor device 20E are omitted for easy viewing.

The semiconductor device 20E is different from the semiconductor device 20 in that a conductive layer 25 provided over the insulating layer 31 is included so as to be embedded in the insulating layer 32.

As illustrated in FIG. 11A, FIG. 11B, and FIG. 12B, the conductive layer 25 is provided to sandwich the opening 30 in the Y direction (A3-A4 direction). The top surface of the conductive layer 24a, the top surface of the conductive layer 24b, the top surface of the conductive layer 25, and the top surface of the insulating layer 32 are substantially level with each other.

As illustrated in FIG. 12B, in the Y direction (A3-A4 direction), the conductive layer 25 is provided to face the semiconductor layer 21 with the insulating layer 32 therebetween. In the transistor included in the semiconductor device 20E, the conductive layer 25 functions as a back gate electrode (a second gate electrode). A region of the insulating layer 32 that is sandwiched between the semiconductor layer 21 and the conductive layer 25 functions as a back gate insulating layer (a second gate insulating layer).

As illustrated in FIG. 12B, the transistor included in the semiconductor device 20E has a structure in which two gate electrodes (the conductive layer 23 and the conductive layer 25) are provided to sandwich the semiconductor layer 21. In that case, the effect of the gate electric field on carriers in a channel formation region can be increased as compared to that in the transistor that is included in the semiconductor device 20 and provided with only one gate electrode (the conductive layer 23), which can increase the controllability of source-drain current. Accordingly, the semiconductor device 20E can have a higher on-state current than the semiconductor device 20 and reduce the off-state current.

Although not illustrated, the conductive layer 23 and the conductive layer 25, which respectively function as the first gate electrode and the second gate electrode of the transistor included in the semiconductor device 20E, may be electrically connected to each other. With this structure, the transistor can be driven by applying potentials having the same value to the semiconductor layer 21 from the conductive layer 23 and the conductive layer 25 between which the semiconductor layer 21 is sandwiched. This is preferable because the conductive layer 23 and the conductive layer 25 can be connected to the same power source and the number of components can be reduced. Another structure may be employed in which the conductive layer 23 and the conductive layer 25 are not electrically connected to each other and each independently apply a potential to the semiconductor layer 21. This structure is preferable because a potential for controlling the threshold voltage can be applied to one of the conductive layers and a potential for driving can be applied to the other of the conductive layers, so that the transistor can be driven while the threshold voltage of the transistor is controlled.

The description on the semiconductor device 20 can be referred to for components of the semiconductor device 20E other than the above.

At least part of this embodiment can be implemented in combination with any of the other embodiments described in this specification as appropriate.

### Embodiment 2

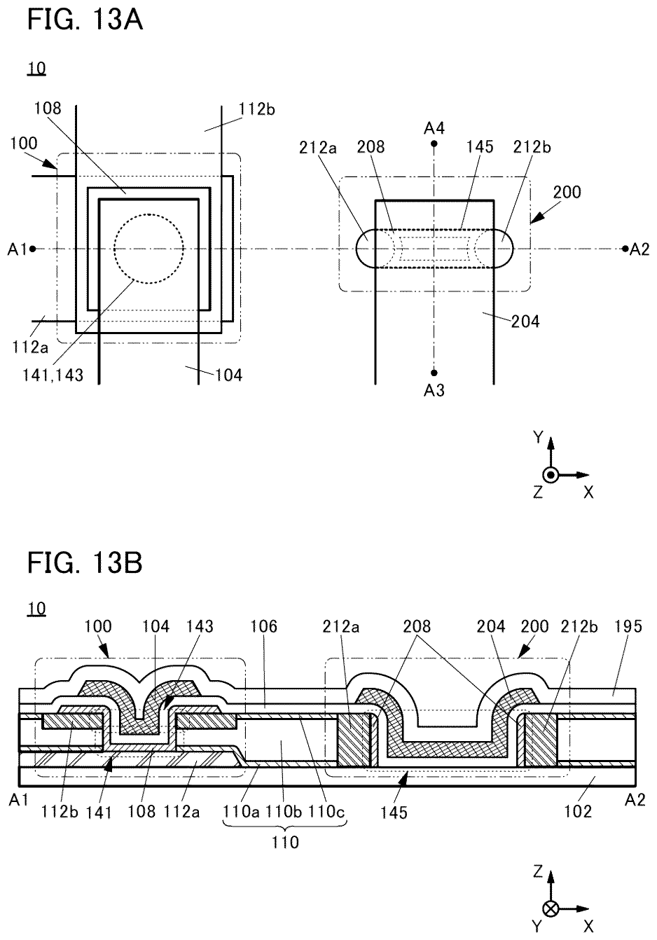

In this embodiment, a more detailed structure of the semiconductor device of one embodiment of the present invention will be described with reference to FIG. 13A to FIG. 16B.

Note that the above description on the semiconductor device 20 and the like can also be applied to a semiconductor device described later. The following description on the semiconductor device can also be applied to the semiconductor device 20 and the like described above.

FIG. 13A is a plan view of a semiconductor device 10. FIG. 13B is a cross-sectional view taken along the dashed-dotted line A1-A2 in FIG. 13A. Note that in FIG. 13A, some components (e.g., an insulating layer) of the semiconductor device 10 are not illustrated.

The semiconductor device 10 includes a transistor 100, a transistor 200, and an insulating layer 110 (an insulating layer 110a, an insulating layer 110b, and an insulating layer 110c). The transistor 100 and the transistor 200 are provided over a substrate 102.

Note that the substrate 102 preferably includes an insulating surface. A material that can be used for the substrate 102 is described later; in the case where a material having conductivity such as silicon is used, for example, a defect such as a short circuit between the substrate 102 and a conductive layer formed over the substrate 102 occurs in some cases. The insulating surface of the substrate 102 is preferably less permeable to impurities (e.g., water and hydrogen). Thus, impurities contained in the substrate 102 can be prevented from diffusing into the upper semiconductor layer and adversely affecting the electrical characteristics and reliability of the transistor 100 and the transistor 200.

The transistor 100 and the transistor 200 have different structures. The transistor 100 and the transistor 200 can be formed with some processes in common.

The structure of the transistor 200 will be described.

The structure of the transistor included in the semiconductor device 20 or the like can be used for the transistor 200. The transistor 200 includes a conductive layer 212a, a conductive layer 212b, a semiconductor layer 208, an insulating layer 106, and a conductive layer 204. In the transistor 200, the conductive layer 212a functions as one of a source electrode and a drain electrode. The conductive layer 212b functions as the other of the source electrode and the drain electrode. The semiconductor layer 208 functions as a semiconductor layer where a channel is formed. The conductive layer 204 functions as a gate electrode. Part of the insulating layer 106 (specifically, a region sandwiched between the semiconductor layer 208 and the conductive layer 204) functions as a gate insulating layer. The layers included in the transistor 200 may each have a single-layer structure or a stacked-layer structure. For the conductive layer 212a, the conductive layer 212b, the semiconductor layer 208, the insulating layer 106, and the conductive layer 204, the above description on the conductive layer 24a, the conductive layer 24b, the semiconductor layer 21, the insulating layer 22, and the conductive layer 23 can be referred to.

The conductive layer 212a and the conductive layer 212b are provided over the substrate 102 so as to face each other and to be embedded in the insulating layer 110. The insulating layer 110 includes an opening 145 reaching the substrate 102 between the conductive layer 212a and the conductive layer 212b. For the insulating layer 110 and the opening 145, the above description on the insulating layer 32 and the opening 30 can be referred to, respectively.

As illustrated in FIG. 13A, in the plan view, each of end portions of the conductive layer 212a and the conductive layer 212b on the A3 side is aligned with an end portion of the insulating layer 110 on the A3 side in the opening 145. In the plan view, each of end portions of the conductive layer 212a and the conductive layer 212b on the A4 side is aligned with an end portion of the insulating layer 110 on the A4 side in the opening 145.

The conductive layer 212a and the conductive layer 212b can be formed using the same material. The conductive layer 212a and the conductive layer 212b can be formed in the same process. For example, two openings are formed in the insulating layer 110, and a film to be the conductive layer 212a and the conductive layer 212b is formed over the insulating layer 110 to fill the openings. Then, the film is processed until the top surface of the insulating layer 110 is exposed, thereby forming the columnar conductive layer 212a and conductive layer 212b embedded in the openings.

In the opening 145, the semiconductor layer 208 is provided in contact with a side surface of the conductive layer 212a, a side surface of the conductive layer 212b, and a side surface of the insulating layer 110. The semiconductor layer 208 is not provided on the bottom portion of the opening 145 (the top surface of the substrate 102).

In the transistor 200, a region of the semiconductor layer 208 that is in contact with the conductive layer 212a functions as one of a source region and a drain region, and a region in contact with the conductive layer 212b functions as the other of the source region and the drain region. In the semiconductor layer 208, a channel formation region is provided between the source region and the drain region. That is, in the semiconductor layer 208 illustrated in FIG. 13A, a region sandwiched between the conductive layer 212a and the conductive layer 212b (a region extending in the X direction (A1-A2 direction)) functions as a channel formation region. Thus, the transistor 200 can be regarded as a transistor including two channel formation regions. That is, a region of the semiconductor layer 208 that is in contact with a side surface of the insulating layer 110 positioned on the A3 side in the opening 145 and a region of the semiconductor layer 208 that is in contact with a side surface of the insulating layer 110 positioned on the A4 side in the opening 145 function as channel formation regions. Accordingly, the transistor 200 can have a higher on-state current than a transistor including only one channel formation region.

The insulating layer 106 is provided to cover the opening 145. The insulating layer 106 is provided over the semiconductor layer 208, the conductive layer 212a, the conductive layer 212b, and the insulating layer 110. The insulating layer 106 includes regions in contact with the top surface and a side surface of the semiconductor layer 208, the top surface of the conductive layer 212a, the top surface of the conductive layer 212b, the side surface of the insulating layer 110, and the top surface of the substrate 102. The insulating layer 106 has a shape along the shapes of the top surface and the side surface of the semiconductor layer 208, the top surface of the conductive layer 212a, the top surface of the conductive layer 212b, the side surface of the insulating layer 110, and the top surface of the substrate 102.

The conductive layer 204 is provided over the insulating layer 106 and includes a region in contact with the top surface of the insulating layer 106. The conductive layer 204 includes a region overlapping with the semiconductor layer 208 with the insulating layer 106 therebetween. The conductive layer 204 has a shape along the shape of the top surface of the insulating layer 106.

In the transistor 200, a side surface of a region of the semiconductor layer 208 that is positioned between the conductive layer 212a and the conductive layer 212b (in the XZ plane illustrated in FIG. 13A) serves as a current path between the source and the drain (the channel formation region of the semiconductor layer 208). Thus, in the transistor 200, a plane in the direction perpendicular or substantially perpendicular (the vertical direction or the substantially vertical direction) to the surface of the substrate 102, which is the formation surface, serves as a current path between the source and the drain. It can be also said that, in the transistor 200, source-drain current flows in the direction parallel or substantially parallel (the horizontal direction or the substantially horizontal direction) to the surface of the substrate 102, which is the formation surface. In this manner, the transistor 200 has a structure in which both the vertical direction and the horizontal direction contribute as current paths between the source and the drain, and thus can be referred to as a VLFET (Vertical Lateral Field Effect Transistor).

Next, the structure of the transistor 100 is described.

The transistor 100 includes a conductive layer 104, the insulating layer 106, a semiconductor layer 108, a conductive layer 112a, and a conductive layer 112b. In the transistor 100, the conductive layer 104 functions as a gate electrode. Part of the insulating layer 106 (specifically, a region sandwiched between the semiconductor layer 108 and the conductive layer 104) functions as a gate insulating layer. The conductive layer 112a functions as one of a source electrode and a drain electrode. The conductive layer 112b functions as the other of the source electrode and the drain electrode. The layers included in the transistor 100 may each have a single-layer structure or a stacked-layer structure.

The conductive layer 112a is provided over the substrate 102, and the insulating layer 110 is provided over the conductive layer 112a. The insulating layer 110 is provided to cover the top surface and the side surface of the conductive layer 112a. The insulating layer 110 has an opening 141 reaching the conductive layer 112a in a region overlapping with the conductive layer 112a. In other words, the conductive layer 112a is exposed in the opening 141.

The conductive layer 112b is provided so as to be embedded in a depressed portion of the insulating layer 110. The top surface of the insulating layer 110 and the top surface of the conductive layer 112b are substantially level with each other. The conductive layer 112b includes a region overlapping with the conductive layer 112a with the insulating layer 110 therebetween. The conductive layer 112b has an opening 143 in a region overlapping with the conductive layer 112a. The opening 143 is provided in a region overlapping with the opening 141. The conductive layer 112b can be formed using the same material as that for the conductive layer 212a and the conductive layer 212b. The conductive layer 112b can be formed in the same process as the conductive layer 212a and the conductive layer 212b. For example, a film to be the conductive layer 112b, the conductive layer 212a, and the conductive layer 212b is formed and the film is processed, whereby the conductive layer 112b, the conductive layer 212a, and the conductive layer 212b can be formed.

The semiconductor layer 108 is provided to cover the opening 141 and the opening 143. The semiconductor layer 108 can be formed using the same material as that for the semiconductor layer 208. The semiconductor layer 108 can be formed in the same process as the semiconductor layer 208. For example, a film to be the semiconductor layer 108 and the semiconductor layer 208 is formed and then processed, whereby the semiconductor layer 108 and the semiconductor layer 208 can be formed.

The semiconductor layer 108 includes regions in contact with the top surface and a side surface of the conductive layer 112b, the side surface of the insulating layer 110, and the top surface of the conductive layer 112a. The semiconductor layer 108 is electrically connected to the conductive layer 112a through the opening 141 and the opening 143. The semiconductor layer 108 has a shape along the shapes of the top surface and the side surface of the conductive layer 112b, the side surface of the insulating layer 110, and the top surface of the conductive layer 112a. The semiconductor layer 108 includes a region overlapping with the conductive layer 112a with the insulating layer 110 therebetween. In other words, the insulating layer 110 includes a region sandwiched between the conductive layer 112a and the semiconductor layer 108.

In the semiconductor layer 108, a region in contact with the conductive layer 112a functions as one of a source region and a drain region, and a region in contact with the conductive layer 112b functions as the other of the source region and the drain region. In the semiconductor layer 108, a channel formation region is provided between the source region and the drain region.

The insulating layer 106 is provided to cover the opening 141 and the opening 143. The insulating layer 106 is provided over the semiconductor layer 108, the conductive layer 112b, and the insulating layer 110. The insulating layer 106 includes regions in contact with the top surface and the side surface of the semiconductor layer 108, the top surface of the conductive layer 112b, and the top surface of the insulating layer 110. The insulating layer 106 has a shape along the shapes of the top surface and the side surface of the semiconductor layer 108, the top surface of the conductive layer 112b, and the top surface of the insulating layer 110.

The conductive layer 104 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106. The conductive layer 104 can be formed using the same material as that for the conductive layer 204. The conductive layer 104 can be formed in the same process as the conductive layer 204. For example, a film to be the conductive layer 104 and the conductive layer 204 is formed and then processed, whereby the conductive layer 104 and the conductive layer 204 can be formed.

The transistor 100 is what is called a top-gate transistor including the gate electrode above the semiconductor layer 108. Furthermore, since the bottom surface of the semiconductor layer 108 (the surface on the substrate 102 side) is in contact with the conductive layer 112a and the conductive layer 112b functioning as the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102, which is the formation surface, and a drain current flows in a direction perpendicular or substantially perpendicular to the surface of the substrate 102 (the Z direction in FIG. 13B). In other words, the drain current flows in the vertical direction or the substantially vertical direction in the transistor 100. Accordingly, the transistor 100 can be referred to as a vertical-channel transistor or a VFET (Vertical Field Effect Transistor).

The channel length of the transistor 100 can be controlled by the thickness of the insulating layer 110 (specifically, the insulating layer 110b) provided between the conductive layer 112a and the conductive layer 112b. Accordingly, a transistor with a channel length smaller than the definition limit of a light-exposure apparatus used for manufacturing the transistor can be manufactured with high accuracy. In addition, variation in characteristics among a plurality of transistors 100 can be reduced. This stabilizes the operation of the semiconductor device including the transistors 100 to improve the reliability thereof. A reduction in the variation in characteristics among the plurality of transistors 100 increases the degree of flexibility in circuit design, thereby reducing the operation voltage of the semiconductor device including the transistors 100. As a result, the power consumption of the semiconductor device can be reduced.

In the transistor 100, the source electrode, the semiconductor layer including the channel formation region, and the drain electrode can be provided to overlap with one another; thus, the area occupied by the transistor can be significantly smaller than the area occupied by what is called a planar transistor in which a semiconductor layer including a channel formation region is provided in a planar shape.

The conductive layer 112a, the conductive layer 112b, and the conductive layer 104 can function as wirings, and the transistor 100 can be provided in the region where these wirings overlap with one another. That is, the areas occupied by the transistor 100 and the wirings can be reduced in the circuit including the transistor 100 and the wirings. Accordingly, the area occupied by the circuit can be reduced, which makes it possible to reduce the size of the semiconductor device.

As described above, the semiconductor device of one embodiment of the present invention can include not only VLFETs (e.g., the transistor included in the above-described semiconductor device 20 or the like and the transistor 200) but also a VLFET and a transistor having a structure different from the VLFET (e.g., a VFET such as the transistor 100) in combination. Thus, the semiconductor device that exhibits high performance by utilizing the characteristics of different transistors can be achieved.

For example, a VFET with a short channel length such as the transistor 100 is used as a transistor that requires a high on-state current, and a VLFET with a long channel length such as the transistor 200 is used as a transistor that requires high saturability, whereby the semiconductor device 10 with high performance can be achieved. Note that as described later, the transistor 100 and the transistor 200 can be formed over the same substrate with some processes in common. Hence, even the semiconductor device 10 including transistors (VLFET and VFET) with different structures does not need a much larger number of manufacturing steps than a semiconductor device including only VLFETs.

Note that in this specification and the like, a small change in Id with respect to Vd in a saturation region of drain current (Id)-drain voltage (Vd) characteristics of a transistor is expressed as “high saturability” in some cases.

Note that the semiconductor device of one embodiment of the present invention is not limited to the above, and may have a structure including only VLFETs as the semiconductor device 20 described above. For example, in the case where the semiconductor device 10 has a structure not including the transistor 100 (VFET) and including only a plurality of transistors 200 (VLFETs), the semiconductor device 10 including a plurality of transistors 200 with different on-state current values can be achieved when the transistors 200 have different top surface shapes of the openings 145. For specific examples of the top surface shape of the opening 145, description on the top surface shape of the opening 30 in the semiconductor device 20 or the like in the above embodiment can be referred to.

When the semiconductor device of one embodiment of the present invention is used for a pixel circuit of a display device, the area occupied by the pixel circuit can be reduced and the display device can have high resolution, for example. When the semiconductor device of one embodiment of the present invention is used for a driver circuit (e.g., one or both of a gate line driver circuit and a source line driver circuit) of the display device, the area occupied by the driver circuit can be reduced and the display device can have a narrow bezel, for example.

An insulating layer 195 is provided to cover the transistor 100 and the transistor 200. The insulating layer 195 functions as a protective layer of the transistor 100 and the transistor 200. Components (the transistor 100, the transistor 200, and the insulating layer 110) of the semiconductor device 10 of one embodiment of the present invention will be described in more detail below.

A semiconductor material used for the semiconductor layer 108 and the semiconductor layer 208 is not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may include an impurity as a dopant.

There is no particular limitation on the crystallinity of the semiconductor material used for the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

Silicon can be used for the semiconductor layer 108 and the semiconductor layer 208. Examples of silicon include single crystal silicon, polycrystalline silicon, microcrystalline silicon, and amorphous silicon. An example of polycrystalline silicon is low-temperature polysilicon (LTPS). A transistor including amorphous silicon in a channel formation region can be formed over a large glass substrate, and can be manufactured at low cost. A transistor including polycrystalline silicon in a channel formation region has high field-effect mobility and enables high-speed operation. A transistor including microcrystalline silicon in a channel formation region has higher field-effect mobility and enables higher speed operation than a transistor including amorphous silicon.

Each of the semiconductor layer 108 and the semiconductor layer 208 preferably includes a metal oxide exhibiting semiconductor characteristics (also referred to as an oxide semiconductor).

The band gap of a metal oxide used for the semiconductor layer 108 and the semiconductor layer 208 is preferably 2.0 eV or more, further preferably 2.5 eV or more.

A transistor including an oxide semiconductor (hereinafter referred to as an OS transistor) has much higher field-effect mobility than a transistor including amorphous silicon.

In addition, the OS transistor has an extremely low off-state current, and charge accumulated in a capacitor that is connected in series to the transistor can be retained for a long period. Furthermore, the power consumption of the semiconductor device can be reduced by employing the OS transistor.

The insulating layer 110 preferably includes one or more inorganic insulating films. Examples of a material that can be used for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride.

Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide.

Note that in this specification and the like, an oxynitride refers to a material that contains more oxygen than nitrogen in its composition. A nitride oxide refers to a material that contains more nitrogen than oxygen in its composition.

In the transistor 200, a region of the semiconductor layer 208 that is in contact with the insulating layer 110 functions as a channel formation region. In the transistor 100, a region of the semiconductor layer 108 that is in contact with the insulating layer 110 functions as a channel formation region. In the case where a metal oxide is used for the semiconductor layer 108 and the semiconductor layer 208, at least part of the region of the insulating layer 110 that is in contact with the semiconductor layer 108 and at least part of the region of the insulating layer 110 that is in contact with the semiconductor layer 208 preferably contain oxygen to improve the characteristics of the interface between the semiconductor layer 108 and the insulating layer 110 and the interface between the semiconductor layer 208 and the insulating layer 110. Specifically, the region of the insulating layer 110 that is in contact with the channel formation region of the semiconductor layer 108 and the region of the insulating layer 110 that is in contact with the channel formation region of the semiconductor layer 208 preferably contain oxygen. One or more of an oxide and an oxynitride can be suitably used for the region of the insulating layer 110 that is in contact with the channel formation region of the semiconductor layer 108 and the region of the insulating layer 110 that is in contact with the channel formation region of the semiconductor layer 208.

The insulating layer 110 preferably has a stacked-layer structure. FIG. 13B and the like illustrate an example in which the insulating layer 110 includes the insulating layer 110a, the insulating layer 110b over the insulating layer 110a, and the insulating layer 110c over the insulating layer 110b.

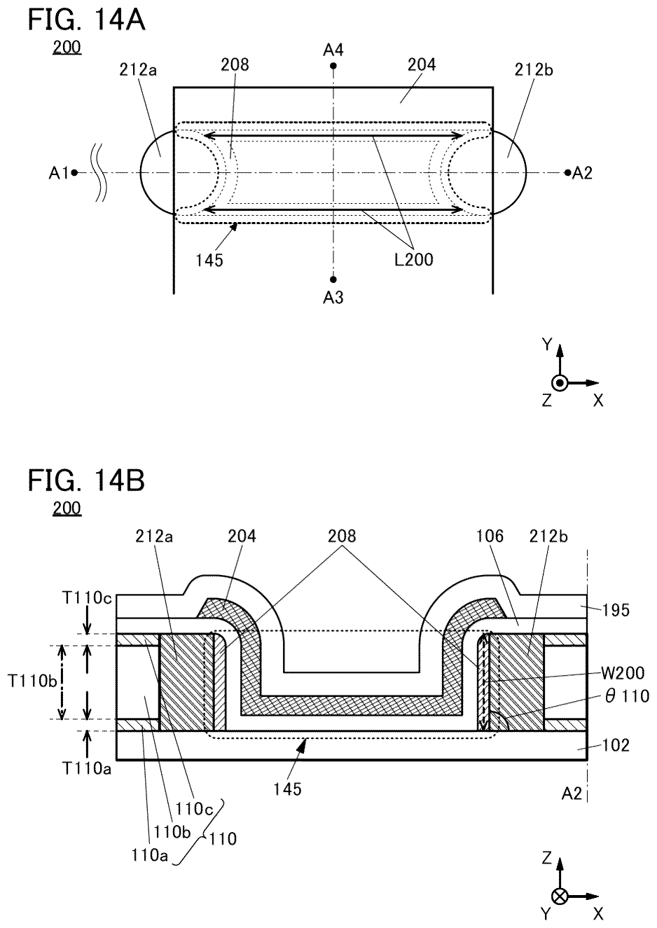

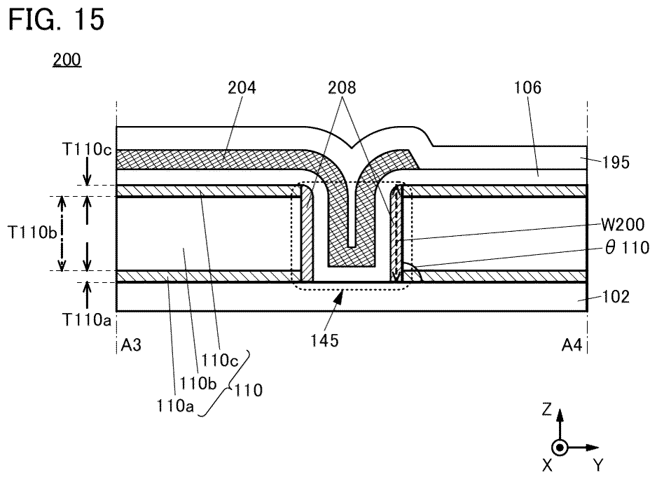

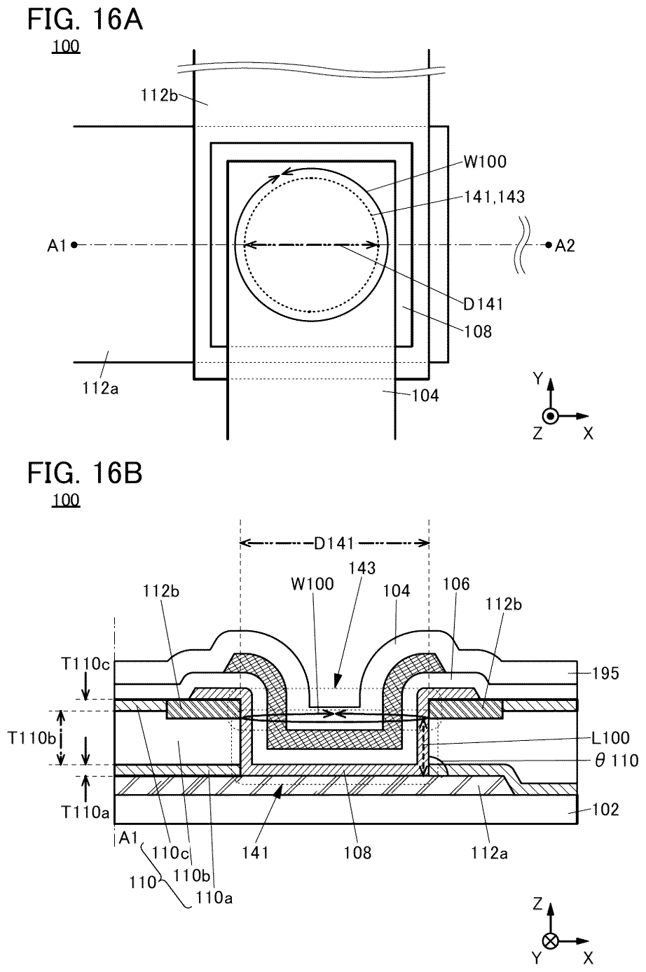

FIG. 14A to FIG. 15 are enlarged views of the transistor 200 included in the semiconductor device 10 illustrated in FIG. 13A and FIG. 13B, and FIG. 16A and FIG. 16B are enlarged views of the transistor 100. FIG. 14A is a plan view of the transistor 200. FIG. 14B is a cross-sectional view taken along the dashed-dotted line A1-A2 in FIG. 14A. FIG. 15 is a cross-sectional view taken along the dashed-dotted line A3-A4 in FIG. 14A. FIG. 16A is a plan view of the transistor 100. FIG. 16B is a cross-sectional view taken along the dashed-dotted line A1-A2 in FIG. 16A.

The insulating layer 110b preferably contains oxygen and preferably includes any one or more of the oxide and oxynitride described above. Specifically, one or both of silicon oxide and silicon oxynitride can be suitably used for the insulating layer 110b. Thus, at least a region of the semiconductor layer 208 that is in contact with the insulating layer 110b and a region of the semiconductor layer 108 that is in contact with the insulating layer 110b can function as channel formation regions.

It is further preferable that a film from which oxygen is released by heating be used as the insulating layer 110b. When the insulating layer 110b releases oxygen by being heated during the manufacturing process of the transistor 100 and the transistor 200, the oxygen can be supplied to the semiconductor layer 108 and the semiconductor layer 208. Supplying oxygen from the insulating layer 110b to the semiconductor layer 108 and the semiconductor layer 208, particularly to the channel formation region, allows oxygen vacancies (V_{O}) to be repaired and reduced. Thus, the transistor 100 and the transistor 200 can have favorable electrical characteristics and high reliability.

For example, the insulating layer 110b can be supplied with oxygen when heat treatment in an atmosphere containing oxygen or plasma treatment in an atmosphere containing oxygen is performed. Alternatively, an oxide film may be formed over the top surface of the insulating layer 110b by a sputtering method in an atmosphere containing oxygen to supply oxygen. After that, the oxide film may be removed. Note that Embodiment 3 described later shows an example in which oxygen is supplied to the insulating layer 110b by forming a metal oxide film 137.

In the case where a metal oxide is used for the semiconductor layer 108 and the semiconductor layer 208, the insulating layer 110b is preferably formed by a film formation method such as a sputtering method, a plasma-enhanced chemical vapor deposition (PECVD) method, or an atomic layer deposition (ALD) method. In particular, by a sputtering method, which is a method not using a hydrogen gas as a film formation gas, a film having an extremely low hydrogen content can be formed. Thus, supply of hydrogen to the channel formation region is inhibited and the electrical characteristics of the transistor 100 and the transistor 200 can be stabilized.

In the case where a metal oxide is used for the semiconductor layer 108 and the semiconductor layer 208, a substance is preferably easily diffused in the insulating layer 110b. In other words, the diffusion coefficient of the substance in the insulating layer 110b is preferably high. In particular, oxygen is preferably easily diffused in the insulating layer 110b. That is, the diffusion coefficient of oxygen in the insulating layer 110b is preferably high. Oxygen contained in the insulating layer 110b is diffused in the insulating layer 110b to be supplied to the semiconductor layer 108 through the interface between the insulating layer 110b and the semiconductor layer 108, and also supplied to the semiconductor layer 208 through the interface between the insulating layer 110b and the semiconductor layer 208.

Here, the use of a metal oxide material having high conductivity for the semiconductor layer 108 and the semiconductor layer 208 enables the transistor to have a high on-state current. However, the use of the metal oxide material having high conductivity facilitates the formation of oxygen vacancies (V₀); the increased oxygen vacancies (V₀) in the channel formation region shift the threshold voltage of the transistor, which might increase drain current flowing at a gate voltage of 0 V (hereinafter also referred to as cut-off current). For example, a shift of the threshold voltage in the negative direction might increase the cut-off current in the case of an n-channel transistor. Provision of the insulating layer 110b enables oxygen to be supplied to at least the region of the semiconductor layer 108 that is in contact with the insulating layer 110b and the region of the semiconductor layer 208 that is in contact with the insulating layer 110b, i.e., the channel formation regions of the transistor 100 and the transistor 200, thereby reducing the oxygen vacancies (V_{O}) in the channel formation regions. This inhibits a shift of the threshold voltage and allows the transistor 100 and the transistor 200 to have both a low cut-off current and a high on-state current. Consequently, the semiconductor device 10 can have both low power consumption and high performance.

In the semiconductor layer 108, a region in contact with the conductive layer 112a functions as one of a source region and a drain region of the transistor 100, and a region in contact with the conductive layer 112b functions as the other of the source region and the drain region of the transistor 100. The source region and the drain region have lower electric resistance than the channel formation region. In other words, the source region and the drain region are each a region having a higher carrier concentration or a higher oxygen vacancy density than the channel formation region.

The insulating layer 110a is provided between the insulating layer 110b and the substrate 102. The insulating layer 110c is provided between the insulating layer 110b and the insulating layer 106. It is preferable that the amount of impurities (e.g., hydrogen and water) released from the insulating layer 110a and the insulating layer 110c themselves be small and the impurities be unlikely to pass therethrough. Thus, the impurities contained in the insulating layer 110a and the insulating layer 110c can be inhibited from being diffused into the channel formation region. Thus, the transistor can have favorable electrical characteristics and high reliability.

As each of the insulating layer 110a and the insulating layer 110c, a film that does not easily transmit oxygen is preferably used. In that case, oxygen contained in the insulating layer 110b can be inhibited from being diffused into the substrate 102 side through the insulating layer 110a. Similarly, oxygen contained in the insulating layer 110b can be inhibited from being diffused into the insulating layer 106 side through the insulating layer 110c. Thus, diffusion of oxygen contained in the insulating layer 110b to the insulating layer 110a side and the insulating layer 110c side is inhibited, thereby inhibiting a reduction in the amount of oxygen supplied from the insulating layer 110b to the channel formation region, which can reduce oxygen vacancies (V_{O}) in the channel formation region and defects in which hydrogen has entered an oxygen vacancy (hereinafter sometimes referred to as VoH).

When a film that does not easily diffuse oxygen is used as each of the insulating layer 110a and the insulating layer 110c, oxygen can be effectively supplied from the insulating layer 110b to the channel formation region. Note that one or both of the insulating layer 110a and the insulating layer 110c are not necessarily provided.

Each of the insulating layer 110a and the insulating layer 110c preferably contains nitrogen, and any one or more of the nitride and nitride oxide described above are preferably used. For example, silicon nitride or silicon nitride oxide can be suitably used for each of the insulating layer 110a and the insulating layer 110c. Alternatively, any one or more of an oxide and an oxynitride may be used for one or both of the insulating layer 110a and the insulating layer 110c.

Aluminum oxide can be suitably used for each of the insulating layer 110a and the insulating layer 110c, for example. Note that for the insulating layer 110a and the insulating layer 110c, the same material or different materials may be used.

Note that in this specification and the like, different materials mean materials in which some or all of constituent elements are different or materials having the same constituent elements and different compositions.

A thickness T110a of the insulating layer 110a can be, for example, greater than or equal to 3 nm and less than 1 μm, greater than or equal to 5 nm and less than or equal to 500 nm, greater than or equal to 10 nm and less than or equal to 400 nm, greater than or equal to 20 nm and less than or equal to 300 nm, greater than or equal to 50 nm and less than or equal to 200 nm, greater than or equal to 70 nm and less than or equal to 150 nm, or greater than or equal to 70 nm and less than or equal to 120 nm. As illustrated in FIG. 14B and the like, the thickness T110a can be the shortest distance between the formation surface of the insulating layer 110a (here, the top surface of the substrate 102) and the bottom surface of the insulating layer 110b in the cross-sectional view.

If the thickness T110a of the insulating layer 110a is large, a large amount of impurities might be released from the insulating layer 110a, resulting in an increase in the amount of impurities diffused into the channel formation region. Meanwhile, if the thickness T110a is small, oxygen contained in the insulating layer 110b might be diffused into the substrate 102 side through the insulating layer 110a, resulting in a reduction in the amount of oxygen supplied to the channel formation region. With the thickness T110a within the above range, the oxygen vacancies (V_{O}) and VoH in the channel formation region can be reduced. Furthermore, the conductive layer 112a can be prevented from being oxidized by oxygen contained in the insulating layer 110b and from having higher electric resistance.

A thickness T110c of the insulating layer 110c can be, for example, greater than or equal to 3 nm and less than or equal to 1 μm, greater than or equal to 5 nm and less than or equal to 500 nm, greater than or equal to 10 nm and less than or equal to 300 nm, greater than or equal to 15 nm and less than or equal to 200 nm, greater than or equal to 20 nm and less than or equal to 150 nm, greater than or equal to 20 nm and less than or equal to 120 nm, or greater than or equal to 20 nm and less than or equal to 100 nm. As illustrated in FIG. 14B and the like, the thickness T110c can be the shortest distance between the formation surface of the insulating layer 110c (here, the top surface of the insulating layer 110b) and the bottom surface of the insulating layer 106 in the cross-sectional view.

If the thickness T110c of the insulating layer 110c is large, a large amount of impurities might be released from the insulating layer 110c, resulting in an increase in the amount of impurities diffused into the channel formation region. Meanwhile, if the thickness T110c is small, oxygen contained in the insulating layer 110b might be diffused into the insulating layer 106 side through the insulating layer 110c, resulting in a reduction in the amount of oxygen supplied to the channel formation region. With the thickness T110c within the above range, the oxygen vacancies (V_{O}) and V_{O}H in the channel formation region can be reduced.

At least one of a region of the semiconductor layer 208 that is in contact with the insulating layer 110a, a region of the semiconductor layer 208 that is in contact with the insulating layer 110c, and a region of the semiconductor layer 108 that is in contact with the insulating layer 110a is a region having lower electric resistance than the channel formation region (hereinafter, also referred to as a low-resistance region) in some cases. In other words, the region is a region having a higher carrier concentration than the channel formation region or a region having a higher oxygen vacancy density than the channel formation region. When a material that releases an impurity (e.g., water or hydrogen) is used for the insulating layer 110a, the region in contact with the insulating layer 110a is a low-resistance region in some cases. Similarly, when a material that releases an impurity is used for the insulating layer 110c, the region in contact with the insulating layer 110c is a low-resistance region in some cases.

As described above, an excessive amount of impurities is released from the insulating layer 110a and the insulating layer 110c, impurities might be diffused into the channel formation region. Even when a material that releases an impurity is used for the insulating layer 110a and the insulating layer 110c, the amount of released impurities is preferably small.

The insulating layer 110 preferably includes at least the insulating layer 110b. For example, a structure without one or both of the insulating layer 110a and the insulating layer 110c may be employed. The insulating layer 110 may have a single-layer structure or a stacked-layer structure of two, four, or more layers.

There is no limitation on the top surface shape of the opening 145, the opening 141, and the opening 143, and the shape can be a circular shape; an elliptical shape; a polygonal shape such as a triangular shape, a tetragonal shape (including a rectangular shape, a rhombic shape, and a square shape), or a pentagonal shape; or any of these polygonal shapes with rounded corners, for example. Note that the polygonal shape may be either a concave polygonal shape (a polygonal shape that has at least one interior angle greater than 180°) or a convex polygonal shape (a polygonal shape with all interior angles less than or equal to 180°).

In this specification and the like, the top surface shape of the opening 145 refers to the shape of an end portion of the top surface of the insulating layer 110 on the opening 145 side. The top surface shape of the opening 141 refers to the shape of an end portion of the top surface of the insulating layer 110 on the opening 141 side. The top surface shape of the opening 143 refers to the shape of an end portion of the bottom surface of the conductive layer 112b on the opening 143 side.

As illustrated in FIG. 16A and the like, the top surface shape of the opening 141 and the top surface shape of the opening 143 can be the same or substantially the same. In that case, the end portion of the bottom surface of the conductive layer 112b on the opening 143 side is preferably aligned or substantially aligned with the end portion of the top surface of the insulating layer 110 on the opening 141 side as illustrated in FIG. 16B and the like. Here, the bottom surface of the conductive layer 112b refers to the surface thereof on the insulating layer 110 side. The top surface of the insulating layer 110 refers to the surface thereof on the conductive layer 112b side.

Note that the opening 141 and the opening 143 do not necessarily have the same top surface shape. In the case where the top surface shapes of the opening 141 and the opening 143 are circular, the opening 141 and the opening 143 may be concentrically arranged, but not necessarily concentrically arranged.

The channel length and the channel width of the transistor 200 are described with reference to FIG. 14A to FIG. 15.

In FIG. 14A, a channel length L200 of the transistor 200 is indicated by a solid double-headed arrow. The channel length L200 corresponds to the distance between the conductive layer 212a and the conductive layer 212b along the periphery direction of the opening 145. In FIG. 14B and FIG. 15, a channel width W200 of the transistor 200 is indicated by a dashed double-headed arrow. The channel width W200 is the width of the semiconductor layer 208 along the depth direction of the opening 145.

The channel length and the channel width of the transistor 100 are described with reference to FIG. 16A and FIG. 16B.

In FIG. 16B, a channel length L100 of the transistor 100 is indicated by a dashed double-headed arrow. The channel length L100 of the transistor 100 corresponds to the length of the side surfaces of the insulating layer 110a and the insulating layer 110b on the opening 141 side in a cross-sectional view. That is, the channel length L100 is determined by the thickness T110a of the insulating layer 110a, a thickness T110b of the insulating layer 110b, and an angle θ110 formed by the side surfaces of the insulating layer 110a and the insulating layer 110b on the opening 141 side and the formation surface of the insulating layer 110a and the insulating layer 110b (here, the top surface of the conductive layer 112a). Thus, the channel length L100 can be a value smaller than the definition limit of a light-exposure apparatus, which enables the transistor 100 to have a minute size. Specifically, a transistor with an extremely short channel length that could not be achieved with a conventional light-exposure apparatus for mass production of flat panel displays (with a minimum line width of approximately 2 μm or approximately 1.5 μm, for example) can be achieved. Moreover, a transistor with a channel length of less than 10 nm can also be achieved without using an extremely expensive light-exposure apparatus used in the latest LSI technology.

The channel length L100 can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm. For another example, the channel length L100 can be greater than or equal to 100 nm and less than or equal to 1 μm.

The on-state current of the transistor 100 can be increased by reducing the channel length L100. With the use of the transistor 100, a circuit capable of high-speed operation can be manufactured. Furthermore, the area occupied by the circuit can be reduced. Thus, a small semiconductor device can be achieved. For example, when the semiconductor device of one embodiment of the present invention is used in a large display apparatus or a high-resolution display apparatus, signal delay in wirings can be reduced and display unevenness can be inhibited even in the case where the number of wirings is increased. Furthermore, a reduction in the area occupied by the circuit results in narrowing the bezel of a display apparatus.

By adjusting the thickness T110b of the insulating layer 110b and the angle θ110 of the side surfaces of the insulating layer 110a and the insulating layer 110b with respect to the top surface of the conductive layer 112a, the channel length L100 of the transistor 100 and the channel width W200 of the transistor 200 can be controlled. Note that in FIG. 16B and the like, the thickness T110b of the insulating layer 110b is indicated by a dashed-dotted double-headed arrow.

The thickness T110b of the insulating layer 110b can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm.

The side surface of the insulating layer 110 on the opening 141 side and the side surface of the insulating layer 110 on the opening 145 side preferably have a vertical shape or a tapered shape. The angle θ110 is preferably smaller than or equal to 90°. By reducing the angle θ110, the coverage with a layer (e.g., the semiconductor layer 108 and the semiconductor layer 208) formed over the insulating layer 110 can be improved. The smaller the angle θ110 is, the larger the channel length L100 of the transistor 100 and the channel width W200 of the transistor 200 can be. Conversely, the larger the angle θ110 is, the smaller the channel width W200 of the transistor 200 can be, which can reduce the size of the transistor 100 and the transistor 200.

The angle θ110 can be, for example, greater than or equal to 30° and less than or equal to 90°, greater than or equal to 35° and less than or equal to 85°, greater than or equal to 40° and less than or equal to 80°, greater than or equal to 45° and less than or equal to 80°, greater than or equal to 50° and less than or equal to 80°, greater than or equal to 55° and less than or equal to 80°, greater than or equal to 60° and less than or equal to 80°, greater than or equal to 65° and less than or equal to 80°, or greater than or equal to 70° and less than or equal to 80°. Although FIG. 16B and the like illustrate a structure where the side surface of the insulating layer 110 on the opening 141 side has a linear shape in the cross-sectional view, one embodiment of the present invention is not limited thereto. In the cross-sectional view, the side surface of the insulating layer 110 on the opening 141 side may have a curved shape, or may include both a linear region and a curved region.

Although FIG. 14B and the like illustrate a structure where the side surface of the insulating layer 110 on the opening 145 side has a linear shape in the cross-sectional view, one embodiment of the present invention is not limited thereto. In the cross-sectional view, the side surface of the insulating layer 110 on the opening 145 side may have a curved shape, or may include both a linear region and a curved region.

In FIG. 16A and FIG. 16B, a width D141 of the opening 141 is indicated by the dashed-two dotted double-headed arrow. FIG. 16A shows an example in which the top surface shape of the opening 141 is a circle. In this case, the width D141 corresponds to the diameter of the circle and a channel width W100 of the transistor 100 is the length of the circumference of the circle.

That is, the channel width W100 is π×D141. Accordingly, in the case where the opening 141 has a circular top surface shape, the channel width W100 of the transistor can be smaller than that in the case where the opening 141 has any other shape.

The width D141 of the opening 141 sometimes varies in the depth direction. As the width D141 of the opening 141, for example, the average value of the following three diameters can be used: the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels. For another example, any of the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels can be used as the width D141.

The diameter of the opening 145 in a plan view (which is the maximum diameter, or the diameter in the case where the top-view shape of the opening 145 is circular) also sometimes varies in the depth direction. As the diameter of the opening 145, for example, the average value of the following three diameters can be used: the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels. For another example, any of the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels can be used as the diameter of the opening 145.

In the case where the opening 141 and the opening 145 are formed by a photolithography method, the width D141 of the opening 141 and the diameter of the opening 145 in a plan view are each larger than or equal to the definition limit of a light-exposure apparatus. Each of the width D141 and the diameter of the opening 145 in a plan view can be, for example, greater than or equal to 200 nm and less than 5 μm, greater than or equal to 300 nm and less than or equal to 4.5 μm, greater than or equal to 400 nm and less than or equal to 4 μm, greater than or equal to 500 nm and less than or equal to 3.5 μm, greater than or equal to 500 nm and less than or equal to 3 μm, greater than or equal to 500 nm and less than or equal to 2.5 μm, greater than or equal to 500 nm and less than or equal to 2 μm, greater than or equal to 500 nm and less than or equal to 1.5 μm, or greater than or equal to 500 nm and less than or equal to 1 μm.

In the case where the channel length L100 of the transistor 100 and the channel length L200 of the transistor 200 are made short, materials for the insulating layer 110a and the insulating layer 110c are each preferably selected such that the amount of hydrogen released from the insulating layer 110a and the insulating layer 110c can be as small as possible. In the case where the materials used for the insulating layer 110a and the insulating layer 110c release even a small amount of hydrogen, their thicknesses are preferably small. For example, when the channel length L100 of the transistor 100 is less than or equal to 100 nm, the thickness T110a of the insulating layer 110a and the thickness T110c of the insulating layer 110c are each preferably greater than or equal to 1 nm and less than or equal to 50 nm, greater than or equal to 3 nm and less than or equal to 40 nm, greater than or equal to 5 nm and less than or equal to 30 nm, greater than or equal to 5 nm and less than or equal to 20 nm, greater than or equal to 5 nm and less than or equal to 15 nm, or greater than or equal to 5 nm and less than or equal to 10 nm. Accordingly, the amount of impurities diffusing into the channel formation region can be reduced, and the transistor 100 can have favorable electrical characteristics and high reliability even with the short channel length L100.

Although the structure in which the region of the semiconductor layer 108 that is in contact with the insulating layer 110b functions as a channel formation region of the transistor 100 is described as an example, one embodiment of the present invention is not limited thereto. The region of the semiconductor layer 108 that is in contact with the insulating layer 110a may also function as the channel formation region of the transistor 100.

Although FIG. 16B and the like show an example in which the semiconductor layer 108, the insulating layer 106, and the conductive layer 104 cover the opening 141 and the opening 143 in the transistor 100, one embodiment of the present invention is not limited thereto. A step may be formed between the insulating layer 110 and the conductive layer 112a, and the semiconductor layer 108, the insulating layer 106, and the conductive layer 104 may be provided along the step.

As described above, the channel length L100 of the transistor 100 can be a value smaller than the definition limit of a light-exposure apparatus and the channel length L200 of the transistor 200 can be a value larger than or equal to the definition limit of the light-exposure apparatus. For example, the transistor 100 is used as a transistor that requires a high on-state current, and the transistor 200 is used as a transistor that requires high saturability, whereby the semiconductor device 10 with high performance can be achieved utilizing the advantages of the both transistors. Furthermore, the transistor 100 and the transistor 200 can be formed with some processes in common. Specifically, the semiconductor layer 108 can be formed in the same process as the semiconductor layer 208. Part of the insulating layer 106 functions as the gate insulating layer of the transistor 100 and another part of the insulating layer 106 functions as the gate insulating layer of the transistor 200. The conductive layer 104 and the conductive layer 204 can be formed in the same process. The conductive layer 112b, the conductive layer 212a, and the conductive layer 212b can be formed in the same process. This allows higher productivity and lower manufacturing cost of the semiconductor device 10.

In the case where the semiconductor device 10 has a structure including only the transistors 200, the semiconductor device 10 including a plurality of transistors 200 with different channel lengths L200 may be achieved by changing the top surface shapes of the openings 145 for the respective transistors 200. For example, by adjusting the W/L ratio by changing the top surface shapes of the openings 145 for the respective transistors 200, in the semiconductor device 10, the transistor 200 having a high W/L ratio may be used as the transistor that requires a high on-state current, and the transistor 200 having a low W/L ratio may be used as the transistor that requires high saturability.

Materials that can be used for the semiconductor device 10 of one embodiment of the present invention are described in detail below. [Semiconductor layer 108 and Semiconductor layer 208]

Metal oxides that can be used for the semiconductor layer 108 and the semiconductor layer 208 are specifically described. Examples of the metal oxide include indium oxide, gallium oxide, and zinc oxide. The metal oxide preferably contains at least indium or zinc. The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more kinds of the above elements, further preferably one or more kinds selected from aluminum, gallium, tin, and yttrium, still further preferably one or more kinds of gallium and tin. In this specification and the like, a metal element and a metalloid element may be collectively referred to as a “metal element”, and a “metal element” described in this specification and the like may refer to a metalloid element.

For example, for each of the semiconductor layer 108 and the semiconductor layer 208, indium oxide (In oxide), indium-zinc oxide (In—Zn oxide), indium tin oxide (also referred to as In—Sn oxide or ITO), indium titanium oxide (In—Ti oxide), indium gallium oxide (In—Ga oxide), indium tungsten oxide (also referred to as In—W oxide or IWO), indium gallium aluminum oxide (In—Ga-A1 oxide), indium gallium tin oxide (also referred to as In—Ga —Sn oxide), gallium zinc oxide (also referred to as Ga—Zn oxide or GZO), aluminum zinc oxide (also referred to as A1-Zn oxide or AZO), indium aluminum zinc oxide (also referred to as In-A1-Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga-A1-Zn oxide, IGAZO, IGZAO, or IAGZO) can be used. Alternatively, indium tin oxide containing silicon (also referred to as ITSO), gallium tin oxide (Ga—Sn oxide), aluminum tin oxide (A1-Sn oxide), or the like can be used. Note that a material that does not contain Zn, typically indium oxide or the like, is preferred because of having excellent compatibility with a Si process. By contrast, a material that contains Zn is preferred in that crystallinity can be easily increased.

By increasing the proportion of the number of indium atoms in the total number of atoms of all the metal elements contained in the metal oxide, the field-effect mobility of the transistor can be increased. In addition, the transistor having a high on-state current can be obtained.

Note that the metal oxide may contain, instead of or in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the number of element M atoms in the total number of atoms of all the metal elements contained in the metal oxide, oxygen vacancies (V_{O}) can be inhibited from being formed in the metal oxide. Accordingly, generation of carriers due to oxygen vacancies (V_{O}) is inhibited, which makes the off-state current of the transistor low. Furthermore, a change in electrical characteristics of the transistor is suppressed, and the reliability of the transistor can be increased.

Electrical characteristics and reliability of a transistor depend on the composition of the metal oxide used for the semiconductor layer 108 and the semiconductor layer 208. Thus, by varying the composition of the metal oxide in accordance with the electrical characteristics and reliability required for the transistor, the semiconductor device can have both good electrical characteristics and high reliability.

When a metal oxide is In-M-Zn oxide, the atomic proportion of In is preferably higher than or equal to the atomic proportion of the element M in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8,

In:M:Zn=5:2:5, In:M:Zn=10:1:10, In:M:Zn=20:1:10, In:M:Zn=40:1:10, and a composition in the neighborhood of any of these atomic ratios. Note that a composition in the neighborhood includes the range of +30% of an intended atomic ratio. By increasing the atomic proportion of indium in the metal oxide, the on-state current, field-effect mobility, or the like of the transistor can be increased.

The atomic proportion of In may be lower than the atomic proportion of the element M in the In-M-Zn oxide. Examples of the atomic ratio of the metal elements in such In-M-Zn oxide include In:M:Zn=1:3:2, In:M:Zn=1:3:3, In:M:Zn=1:3:4, and a composition in the neighborhood of any of these atomic ratios. By increasing the atomic proportion of M in the metal oxide, generation of oxygen vacancies (V_{O}) can be inhibited.

In the case where a plurality of metal elements are contained as the element M, the sum of the proportions of the numbers of atoms of the metal elements can be the proportion of the number of element M atoms.

In this specification and the like, the proportion of the number of indium atoms in the total number of atoms of all the metal elements contained is sometimes referred to as the content percentage of indium. The same applies to other metal elements.

The use of a material with a high content percentage of indium for the semiconductor layer 108 and the semiconductor layer 208 enables an increase in the on-state current, field-effect mobility, or the like of the transistor. Furthermore, with the element M, generation of oxygen vacancies (V_{O}) can be inhibited. The content percentage of the element M (the proportion of the number of element M atoms in the total number of atoms of all the metal elements contained) is preferably greater than or equal to 0.1% and less than or equal to 3%, further preferably greater than or equal to 0.1% and less than or equal to 2%. Accordingly, the transistor can have favorable electrical characteristics. For example, a metal oxide with In:M:Zn=40:1:10 or the neighborhood thereof is preferably used. The element Mis preferably any one or more kinds of the above elements, further preferably one or more kinds selected from aluminum, gallium, tin, and yttrium. Specifically, a metal oxide with In:Sn:Zn=40:1:10 or the neighborhood thereof can be suitably used. Alternatively, a metal oxide with In:Al:Zn=40:1:10 or the neighborhood thereof can be suitably used.

Here, in the case where a metal oxide having a polycrystalline structure is used for the semiconductor layer 108 and the semiconductor layer 208, the crystal grain boundary becomes a recombination center and captures carriers and thus decreases the on-state current of the transistor, in some cases. In the case where a metal oxide with a composition that tends to form a polycrystalline structure is used, the metal oxide preferably contains an element that hinders crystallization. For example, indium tin oxide containing silicon (ITSO) is less likely to have a polycrystalline structure than indium tin oxide (ITO) and can be suitably used for the semiconductor layer 108 and the semiconductor layer 208. In the case where ITSO is used, the content percentage of silicon (the proportion of the number of silicon atoms in the total number of atoms of all the metal elements contained) is preferably greater than or equal to 1% and less than or equal to 20%, further preferably greater than or equal to 3% and less than or equal to 20%, further preferably greater than or equal to 3% and less than or equal to 15%, still further preferably greater than or equal to 5% and less than or equal to 15%. Specifically, a metal oxide with In:Sn:Si=45:5:4, In:Sn:Si=95:5:8, or a composition in the neighborhood thereof can be suitably used.

For analysis of the composition of the semiconductor layer 108 and the semiconductor layer 208, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used, for example. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an ALD method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The semiconductor layer 108 and the semiconductor layer 208 may have a stacked-layer structure including two or more metal oxide layers. The two or more metal oxide layers included in the semiconductor layer 108 and the semiconductor layer 208 may have the same composition or substantially the same compositions. Employing a stacked-layer structure of metal oxide layers having the same composition can reduce the manufacturing cost because the metal oxide layers can be formed using the same sputtering target, for example.

The two or more metal oxide layers included in the semiconductor layer 108 and the semiconductor layer 208 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In addition, it is particularly preferable to use gallium, aluminum, or tin as the element M. The elements M in the first metal oxide layer and the second metal oxide layer may be the same or different. For example, the first metal oxide layer and the second metal oxide layer may be IGZO layers having different compositions.

For example, a stacked-layer structure of a first metal oxide layer having In:Zn=4:1 [atomic ratio] or a composition in the neighborhood thereof and a second metal oxide layer having

In:M:Zn=1:1:1 [atomic ratio] or a composition in the neighborhood thereof and being formed over the first metal oxide layer can be suitably employed.

For example, a stacked-layer structure of any one selected from indium oxide, indium gallium oxide, and IGZO, and any one selected from IAZO, IAGZO, and ITZO (registered trademark) may be employed.

Note that when the first metal oxide layer containing a first metal oxide and the second metal oxide layer containing a second metal oxide form a stacked-layer structure and the first metal oxide and the second metal oxide have the same or substantially the same compositions, the boundary (interface) between the first metal oxide layer and the second metal oxide layer cannot clearly be observed in some cases.

It is preferable to use a metal oxide having crystallinity for the semiconductor layer 108 and the semiconductor layer 208. Examples of a structure of the metal oxide having crystallinity include a CAAC (C-Axis Aligned Crystal) structure, a polycrystalline structure, and a nano-crystal (nc) structure. With use of the metal oxide layer having crystallinity, the density of defect states in the semiconductor layer 108 and the semiconductor layer 208 can be reduced, which enables the semiconductor device to have high reliability.

For the semiconductor layer 108 and the semiconductor layer 208, a CAAC-OS or an nc-OS is preferably used.

The CAAC-OS includes a plurality of layered crystals. The c-axes of the crystals are aligned in the normal direction of the formation surface. Each of the semiconductor layer 108 and the semiconductor layer 208 preferably includes a layered crystal parallel or substantially parallel to the formation surface. For example, the semiconductor layer 108 preferably includes a layered crystal parallel or substantially parallel to the top surface of the conductive layer 112b in a region in contact with the top surface, and a layered crystal parallel or substantially parallel to the side surface of the conductive layer 112b in a region in contact with the side surface. In particular, the semiconductor layer 108 preferably includes a layered crystal parallel or substantially parallel to the side surface of the insulating layer 110, which is the formation surface, in the opening 141. With such a structure, the layered crystals of the semiconductor layer 108 are formed substantially parallel to the channel length direction of the transistor 100, so that the on-state current of the transistor can be increased. Similarly, the semiconductor layer 208 preferably includes a layered crystal parallel or substantially parallel to the side surface of the conductive layer 212a, the side surface of the conductive layer 212b, and the side surface of the insulating layer 110. In particular, in a region overlapping with the conductive layer 204, the semiconductor layer 208 preferably includes a layered crystal parallel or substantially parallel to the side surface of the insulating layer 110, which is the formation surface. Thus, the transistor 200 can have a high on-state current.

When a metal oxide having high crystallinity is used for the channel formation region, the density of defect states in the channel formation region can be reduced. By contrast, when a metal oxide having low crystallinity is used, a transistor through which a large amount of current can flow can be achieved.

In the case where a metal oxide is formed by a sputtering method, a higher substrate temperature at the time of formation enables higher crystallinity of the formed metal oxide. For example, the substrate temperature at the time of formation can be adjusted by the temperature of the stage on which the substrate is placed at the time of formation. As the proportion of the flow rate of an oxygen gas to the total flow rate of the film formation gas used for formation (hereinafter also referred to as an oxygen flow rate ratio) or the oxygen partial pressure in a processing chamber is higher, the metal oxide can be formed to have higher crystallinity.

The crystallinity of the semiconductor layer 108 and the semiconductor layer 208 can be analyzed with X-ray diffraction (XRD), a transmission electron microscope (TEM), or electron diffraction (ED), for example. Alternatively, any of these methods may be combined with each other for the analysis.

In the case where a metal oxide is used for each of the semiconductor layer 108 and the semiconductor layer 208, V_{O}H in the channel formation region is preferably reduced as much as possible so that the semiconductor layer 108 and the semiconductor layer 208 become highly purified intrinsic or substantially highly purified intrinsic layers. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to repair oxygen vacancies (V_{O}). When a metal oxide with sufficiently reduced impurities such as VOH is used for a channel formation region of a transistor, the transistor can have stable electrical characteristics.

Supplying oxygen to the metal oxide to repair oxygen vacancies (V_{O}) is sometimes referred to as oxygen adding treatment.

When a metal oxide is used for each of the semiconductor layer 108 and the semiconductor layer 208, the carrier concentration in the channel formation region is preferably lower than or equal to 1×10¹⁸ cm-3, further preferably lower than 1×10¹⁷ cm-3, still further preferably lower than 1×10¹⁶ cm-3, yet further preferably lower than 1×10¹³ cm-3, yet still further preferably lower than 1×10¹² cm-3. Note that the lower limit of the carrier concentration in the channel formation region is not particularly limited and can be, for example, 1×10-9 cm-3.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Each of the semiconductor layer 108 and the semiconductor layer 208 may contain a layered substance that functions as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered substance has a high electrical conduction property in a unit layer, that is, a high two-dimensional electrical conduction property. When a material that functions as a semiconductor and has a high two-dimensional electrical conduction property is used for a channel formation region, a transistor having a high on-state current can be provided.

Examples of the layered substances include graphene, silicene, and chalcogenide.

Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a channel formation region of a transistor include molybdenum sulfide (typically MoS2), molybdenum selenide (typically MoSe2), molybdenum telluride (typically MoTe2), tungsten sulfide (typically WS2), tungsten selenide (typically WSe2), tungsten telluride (typically WTe2), hafnium sulfide (typically HfS2), hafnium selenide (typically HfSe2), zirconium sulfide (typically ZrS2), and zirconium selenide (typically ZrSe2).

[Conductive layer 112a, conductive layer 112b, conductive layer 104, conductive layer 212a, conductive layer 212b, and conductive layer 204]

The conductive layer 112a, the conductive layer 112b, the conductive layer 104, the conductive layer 212a, the conductive layer 212b, and the conductive layer 204 may each have a single-layer structure or a stacked-layer structure of two or more layers. The conductive layer 112a, the conductive layer 112b, the conductive layer 104, the conductive layer 212a, the conductive layer 212b, and the conductive layer 204 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a, the conductive layer 112b, the conductive layer 104, the conductive layer 212a, the conductive layer 212b, and the conductive layer 204, a conductive material with low resistance that contains one or more of copper, silver, gold, and aluminum can be suitably used. Copper or aluminum is particularly preferable because of its high mass-productivity.

For each of the conductive layer 112a, the conductive layer 112b, the conductive layer 104, the conductive layer 212a, the conductive layer 212b, and the conductive layer 204, a metal oxide having a conduction property (an oxide conductor) can be used. Examples of an oxide conductor (OC) include indium oxide, zinc oxide, In—Sn oxide (ITO), In—Zn oxide, In—W oxide, In—W—Zn oxide, In—Ti oxide, In—Ti —Sn oxide, In—Sn —Si oxide (also referred to as ITO containing silicon or ITSO), zinc oxide to which gallium is added, and In—Ga—Zn oxide. A conductive oxide containing indium is particularly preferable because of its high conduction property.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, the conductive layer 104, the conductive layer 212a, the conductive layer 212b, and the conductive layer 204 may have a stacked-layer structure of a conductive film containing the above-described oxide conductor (the metal oxide) and a conductive film containing a metal or an alloy. The use of the conductive film containing a metal or an alloy can reduce wiring resistance.

A Cu—X alloy film (X is Mn, Ni, Cr, Fe, Co, Mo, Ta, or Ti) may be used as each of the conductive layer 112a, the conductive layer 112b, the conductive layer 104, the conductive layer 212a, the conductive layer 212b, and the conductive layer 204. The use of a Cu—X alloy film enables the manufacturing cost to be reduced because a wet etching method can be used in the processing.

Note that the conductive layer 112a, the conductive layer 112b, the conductive layer 104, the conductive layer 212a, the conductive layer 212b, and the conductive layer 204 may be formed using the same material or different materials.

Each of the conductive layer 112a and the conductive layer 112b has a region that is in contact with the semiconductor layer 108. Each of the conductive layer 212a and the conductive layer 212b has a region that is in contact with the semiconductor layer 208. In the case where a metal oxide is used for the semiconductor layer 108 and a metal that is likely to be oxidized (e.g., aluminum) is used for the conductive layer 112a and the conductive layer 112b, an insulating oxide (e.g., aluminum oxide) is formed between the conductive layer 112a and the semiconductor layer 108 and between the conductive layer 112b and the semiconductor layer 108, which might prevent electrical continuity between them. Similarly, in the case where a metal oxide is used for the semiconductor layer 208 and a metal that is likely to be oxidized is used for the conductive layer 212a and the conductive layer 212b, an insulating oxide is formed between the conductive layer 212a and the semiconductor layer 208 and between the conductive layer 212b and the semiconductor layer 208, which might prevent electrical continuity between them. Therefore, the conductive layer 112a, the conductive layer 112b, the conductive layer 212a, and the conductive layer 212b are preferably formed using a conductive material that is less likely to be oxidized, a conductive material that maintains low electric resistance even after being oxidized, or an oxide conductive material.

For each of the conductive layer 112a, the conductive layer 112b, the conductive layer 212a, and the conductive layer 212b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain low electric resistance even after being oxidized.

The above-described oxide conductor can be used for each of the conductive layer 112a, the conductive layer 112b, the conductive layer 212a, and the conductive layer 212b. Specifically, a conductive oxide such as indium oxide, zinc oxide, ITO, In—Zn oxide, In—W oxide, In—W—Zn oxide, In—Ti oxide, In—Ti —Sn oxide, In—Sn oxide containing silicon, or zinc oxide to which gallium is added can be used.

For each of the conductive layer 112a, the conductive layer 112b, the conductive layer 212a, and the conductive layer 212b, a nitride conductor may be used. Examples of the nitride conductor include tantalum nitride and titanium nitride.

The conductive layer 112a, the conductive layer 112b, the conductive layer 104, the conductive layer 212a, the conductive layer 212b, and the conductive layer 204 may each have a stacked-layer structure. In that case, at least regions that are in contact with the semiconductor layer 108 and the semiconductor layer 208 are preferably formed using a conductive material that is less likely to be oxidized, a conductive material that maintains low electric resistance even after being oxidized, or an oxide conductive material. A material with low electrical resistivity is preferably used for regions that are not in contact with the semiconductor layer 108 and the semiconductor layer 208. In this case, the electric resistance of each of the conductive layers can be reduced. For example, In—Sn —Si oxide (ITSO) can be suitably used for the regions that are in contact with the semiconductor layer 108 and the semiconductor layer 208, and copper or tungsten can be suitably used for the regions that are not in contact with the semiconductor layer 108 and the semiconductor layer 208.

### [Insulating Layer 106]

The insulating layer 106 may have either a single-layer structure or a stacked-layer structure of two or more layers. The insulating layer 106 preferably includes one or more inorganic insulating films. Examples of a material that can be used for the inorganic insulating film include an oxide, a nitride, an oxynitride, and a nitride oxide. For the insulating layer 106, a material that can be used for the insulating layer 110 can be used.

The insulating layer 106 includes regions in contact with the semiconductor layer 108 and the semiconductor layer 208. In the case where a metal oxide is used for the semiconductor layer 108 and the semiconductor layer 208, at least a film of the insulating layer 106 that is in contact with the semiconductor layer 108 and the semiconductor layer 208 is preferably formed using any of the above-described oxide and oxynitride. It is further preferable that a film from which oxygen is released by heating be used as the insulating layer 106.

Specifically, in the case where the insulating layer 106 has a single-layer structure, an oxide or an oxynitride is preferably used for the insulating layer 106. Specifically, silicon oxide or silicon oxynitride can be suitably used for the insulating layer 106.

In the case where the insulating layer 106 has a stacked-layer structure, it is preferable that the insulating film on the side that is in contact with the semiconductor layer 108 and the semiconductor layer 208 contain an oxide or an oxynitride and the insulating film on the side that is in contact with the conductive layer 104 and the conductive layer 204 contain a nitride or a nitride oxide. As the oxide or the oxynitride, for example, silicon oxide or silicon oxynitride can be suitably used. As the nitride or the nitride oxide, silicon nitride or silicon nitride oxide can be suitably used.

Silicon nitride and silicon nitride oxide release a smaller amount of impurities (e.g., water and hydrogen) and are less likely to transmit oxygen and hydrogen, and thus can be suitably used for the insulating layer 106. Diffusion of impurities from the insulating layer 106 to the semiconductor layer 108 and the semiconductor layer 208 is inhibited, whereby the transistor can have favorable electrical characteristics and high reliability.

A transistor having a minute size and including a thin gate insulating layer may have a high leakage current. When a high relative dielectric constant material (also referred to as a high-k material) is used for the gate insulating layer, the voltage at the time of operation of the transistor can be reduced while the physical thickness is maintained. Examples of the high-k material that can be used for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Insulating Layer 195]

It is preferable to use a material that does not easily allow diffusion of impurities for the insulating layer 195 functioning as a protective layer of the transistor 100 and the transistor 200. Provision of the insulating layer 195 can effectively inhibit diffusion of impurities into the transistors from the outside and increase the reliability of the semiconductor device 10. Examples of the impurities include water and hydrogen.

The insulating layer 195 can be an insulating layer containing an inorganic material or an insulating layer containing an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of acrylic resins and polyimide resins can be used. As the organic material, a photosensitive material may be used. A stack including two or more of the above insulating films may also be used. The insulating layer 195 may have a stacked-layer structure of an insulating layer containing an inorganic material and an insulating layer containing an organic material.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate using silicon or silicon carbide as a material, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shapes of the semiconductor substrate and an insulating substrate may each be a circle or a square.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of the semiconductor device completed thereover can be separated from the substrate 102 and transferred onto another substrate. In such a case, the transistor 100 and the like can be transferred to a substrate having low heat resistance or a flexible substrate as well.

This embodiment can be combined with the other embodiments as appropriate. In this specification, in the case where a plurality of structure examples are shown in one embodiment, the structure examples can be combined as appropriate.

### Embodiment 3

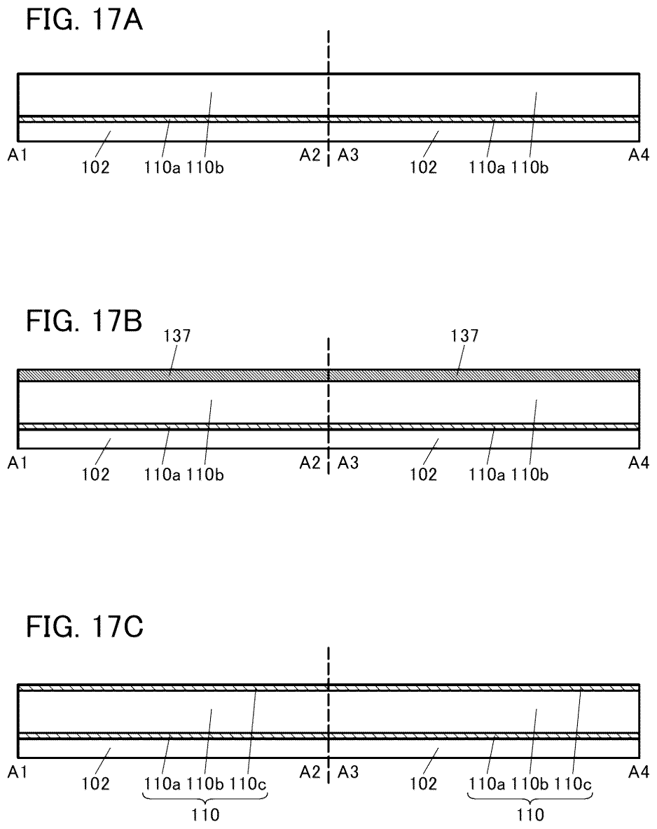

In this embodiment, a method for manufacturing the semiconductor device 10 of one embodiment of the present invention will be described with reference to FIG. 17A to FIG. 25C. Note that as for a material and a formation method of each component, portions similar to those described in Embodiment 2 are not described in some cases.

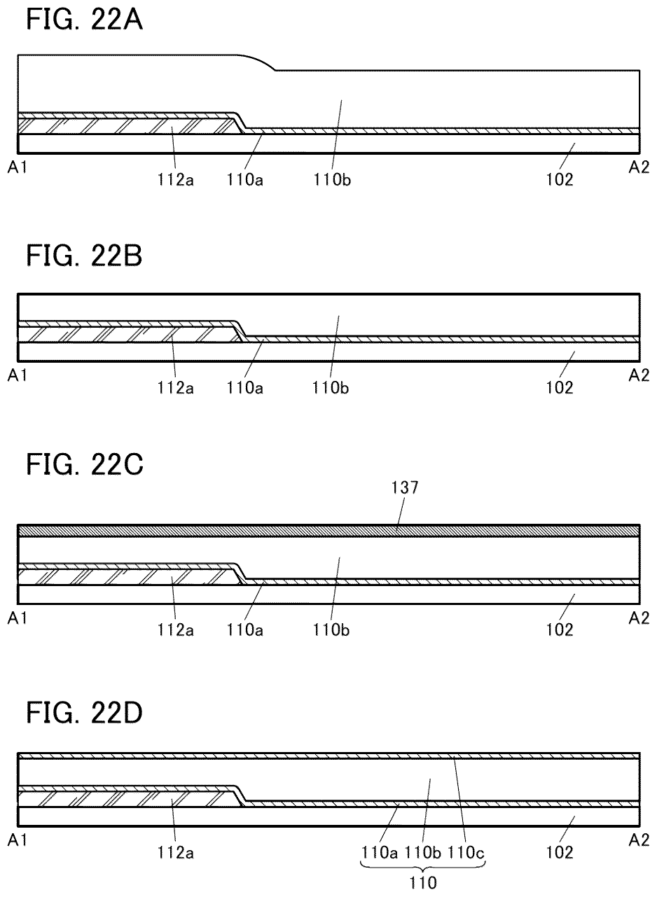

Note that a manufacturing method example of only the transistor 200 (VLFET) in the semiconductor device 10 is described with reference to FIG. 17A to FIG. 21, and a manufacturing method example in the case of concurrently forming the transistor 200 (VLFET) and the transistor 100 (VFET) is described with reference to FIG. 22A to FIG. 25C.

First, the manufacturing method example of the transistor 200 included in the semiconductor device 10 is described.

FIG. 17A to FIG. 21 each illustrate, side by side, a cross-sectional view taken along the dashed-dotted line A1-A2 in FIG. 14A and a cross-sectional view taken along the dashed-dotted line A3-A4 in FIG. 14A.

Thin films included in the semiconductor device (e.g., insulating films, semiconductor films, and conductive films) can be formed by a sputtering method, a chemical vapor deposition

(CVD) method, a vacuum evaporation method, a pulsed laser deposition (PLD) method, an ALD method, or the like. Examples of the CVD method include a PECVD method and a thermal CVD method. An example of a thermal CVD method is a metal organic chemical vapor deposition (MOCVD: Metal Organic CVD) method.

The thin films included in the semiconductor device (e.g., insulating films, semiconductor films, and conductive films) can be formed by a wet film formation method such as spin coating, dipping, spray coating, inkjetting, dispensing, screen printing, offset printing, a doctor knife method, slit coating, roll coating, curtain coating, or knife coating.

When the thin films included in the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of a photolithography method. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. The light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely minute processing can be performed. Note that a photomask is not needed when the light exposure is performed by scanning with a beam such as an electron beam.

For etching of thin films, one or more of a dry etching method, a wet etching method, and a sandblasting method can be used.

First, the insulating layer 110a and the insulating layer 110b are formed in this order over the substrate 102 (FIG. 17A).

A sputtering method or a PECVD method can be suitably used for the formation of the insulating layer 110a and the insulating layer 110b. It is preferable that the insulating layer 110b be formed in a vacuum successively after the formation of the insulating layer 110a, without exposure of the surface of the insulating layer 110a to the air. By forming the insulating layer 110a and the insulating layer 110b successively, attachment of impurities derived from the air to the surface of the insulating layer 110a can be inhibited. Examples of the impurities include water and organic substances.

The substrate temperatures at the time of forming the insulating layer 110a and the insulating layer 110b are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating layer 110a and the insulating layer 110b are in the above range, impurities (e.g., water and hydrogen) released from the insulating layers themselves can be reduced, which inhibits diffusion of the impurities into the semiconductor layer 208. Consequently, the transistor 200 can have favorable electrical characteristics and high reliability.

Note that since the insulating layer 110a and the insulating layer 110b are formed earlier than the semiconductor layer 208, there is no need to consider the probability of oxygen release from the semiconductor layer 208 due to heat applied thereto at the time of forming the insulating layer 110a and the insulating layer 110b.

After the insulating layer 110b is formed, oxygen may be supplied to the insulating layer 110b. As a method for supplying oxygen, an ion implantation method, an ion doping method, a plasma immersion ion implantation method, or plasma treatment can be used, for example. For the plasma treatment, an apparatus in which an oxygen gas is brought into a plasma state by high-frequency power can be suitably used. Examples of the apparatus in which a gas is brought into a plasma state by high-frequency power include a PECVD apparatus, a plasma etching apparatus, and a plasma ashing apparatus. The plasma treatment is preferably performed in an atmosphere containing oxygen. For example, the plasma treatment is preferably performed in an atmosphere containing one or more of oxygen, dinitrogen monoxide (N₂O), nitrogen dioxide (NO₂), carbon monoxide, and carbon dioxide.

Note that the plasma treatment may be successively performed in a vacuum without exposure of the surface of the insulating layer 110b to the air. For example, in the case where a PECVD apparatus is used to form the insulating layer 110b, the plasma treatment is preferably performed with the PECVD apparatus. Accordingly, the productivity can be increased.

Specifically, after the insulating layer 110b is formed with the PECVD apparatus, N₂O plasma treatment can be successively performed in a vacuum.

The metal oxide film 137 is preferably formed over the insulating layer 110b (FIG. 17B). The formation of the metal oxide film 137 by a sputtering method in an atmosphere containing oxygen enables oxygen supply to the insulating layer 110b.

There is no limitation on the conductivity of the metal oxide film 137. As the metal oxide film 137, at least one of an insulating film, a semiconductor film, and a conductive film can be used. For the metal oxide film 137, aluminum oxide, hafnium oxide, hafnium aluminate, indium oxide, indium tin oxide (ITO), or indium tin oxide containing silicon (ITSO) can be used, for example.

For the metal oxide film 137, an oxide material containing one or more elements that are the same as those of the semiconductor layer 208 is preferably used. It is particularly preferable to use a metal oxide material that can be used for the semiconductor layer 208.

At the time of forming the metal oxide film 137, the amount of oxygen supplied into the insulating layer 110b can be increased with a higher oxygen flow rate ratio of the film formation gas introduced into a processing chamber of a film formation apparatus or with a higher oxygen partial pressure in the processing chamber. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide film 137 is formed by a sputtering method in an atmosphere containing oxygen in the above manner, oxygen can be supplied to the insulating layer 110b and release of oxygen from the insulating layer 110b can be prevented at the time of the formation of the metal oxide film 137. As a result, a large amount of oxygen can be enclosed in the insulating layer 110b. Then, a large amount of oxygen can be supplied to the semiconductor layer 208 by heat treatment performed later. As a result, oxygen vacancies (V_{O}) and V_{O}H in the semiconductor layer 208 can be reduced, so that the transistor 200 can have high reliability and exhibit favorable electrical characteristics.

After the metal oxide film 137 is formed, heat treatment may be performed. By performing the heat treatment after the metal oxide film 137 is formed, oxygen can be effectively supplied from the metal oxide film 137 to the insulating layer 110b.

The heat treatment temperature is preferably higher than or equal to 150° C. and lower than the strain point of the substrate, higher than or equal to 200° C. and lower than or equal to 450° C., higher than or equal to 230° C. and lower than or equal to 400° C., higher than or equal to 250° C. and lower than or equal to 350° C., or higher than or equal to 250° C. and lower than or equal to 300° C. The heat treatment can be performed in an atmosphere containing one or more of a noble gas, nitrogen, and oxygen. As an atmosphere containing nitrogen or an atmosphere containing oxygen, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating layer 110a and the insulating layer 110b can be prevented as much as possible. An oven, a rapid thermal annealing (RTA) apparatus, or the like can be used for the heat treatment. The use of the RTA apparatus can shorten the heat treatment time.

After the formation of the metal oxide film 137 or after the above-described heat treatment, oxygen may be further supplied to the insulating layer 110b through the metal oxide film 137. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide film 137 is removed. There is no particular limitation on a method for removing the metal oxide film 137, and a wet etching method can be suitably used. With use of a wet etching method, the insulating layer 110b can be inhibited from being etched during the removal of the metal oxide film 137. This can inhibit a reduction in the thickness of the insulating layer 110b and the thickness of the insulating layer 110b can be uniform. The metal oxide film 137 may be removed by chemical mechanical polishing (CMP) treatment.

After the metal oxide film 137 is removed, oxygen may be further supplied to the insulating layer 110b. The above description can be referred to for a method for supplying oxygen. For example, a film may be formed over the insulating layer 110b and then oxygen may be supplied to the insulating layer 110b through the film. As the treatment, plasma treatment in an atmosphere containing oxygen can be used.

As the film, a conductive film or a semiconductor film is preferably used. As the film, a metal oxide film, a metal film, or an alloy film can be used. The film is preferably formed using a metal oxide in an atmosphere containing oxygen by a sputtering method or the like, in which case oxygen can be supplied to the insulating layer 110b also at the time of forming the film.

The thickness of the film is preferably small. Specifically, the thickness of the film is preferably greater than or equal to 1 nm and less than or equal to 20 nm, greater than or equal to 2 nm and less than or equal to 15 nm, or greater than or equal to 3 nm and less than or equal to 10 nm, for example. Typically, the thickness of the film can be approximately 5 nm.

The substrate temperature at the time of forming the film is preferably lower than or equal to 350° C., further preferably lower than or equal to 340° C., still further preferably lower than or equal to 330° C., yet still further preferably lower than or equal to 300° C. Thus, a large amount of oxygen can be supplied to the insulating layer 110b.

As a treatment apparatus used for oxygen supply, a dry etching apparatus, an ashing apparatus, or a PECVD apparatus can be suitably used. In particular, an ashing apparatus is preferably used. When a bias voltage is applied between a pair of electrodes included in the treatment apparatus, the bias voltage is set to higher than or equal to 10 V and lower than or equal to 1 kV, for example. Alternatively, the power density of the bias is set to higher than or equal to 1 W/cm² and lower than or equal to 5 W/cm², for example.

Next, the film is removed. For the removal of the film, a wet etching method can be suitably used. Alternatively, the film may be removed by CMP treatment.

The treatment for supplying oxygen to the insulating layer 110b is not necessarily performed by the above-described method. An oxygen radical, an oxygen atom, an oxygen atomic ion, or an oxygen molecular ion is supplied to the insulating layer 110b by an ion doping method, an ion implantation method, or plasma treatment, for example. Alternatively, a film that inhibits oxygen release may be formed over the insulating layer 110b and then oxygen may be supplied to the insulating layer 110b through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

Next, the insulating layer 110c is formed over the insulating layer 110b (FIG. 17C). The description on the formation of the insulating layer 110a and the insulating layer 110b can be referred to for the formation of the insulating layer 110c; thus, the detailed description thereof is omitted.

Then, a resist mask 158 is formed over the insulating layer 110c. The resist mask 158 is provided to overlap with a region other than regions where the conductive layer 212a and the conductive layer 212b are formed later.

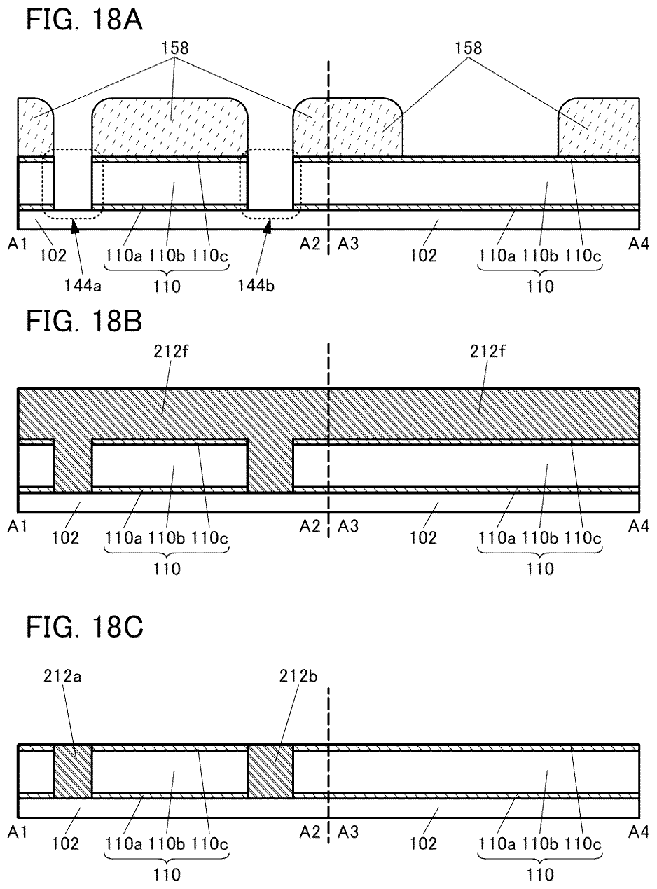

Next, the insulating layer 110 (the insulating layer 110a, the insulating layer 110b, and the insulating layer 110c) is processed to form an opening 144a and an opening 144b in which the conductive layer 212a and the conductive layer 212b are formed later (FIG. 18A). For the processing of the insulating layer 110, one or both of a wet etching method and a dry etching method can be suitably used. In particular, an anisotropic dry etching method can be suitably used. The use of an anisotropic dry etching method enables the formation of the opening 144a and the opening 144b with a minute size and a high aspect ratio, so that the area occupied by the transistor 200 formed later in the substrate plane can be reduced. The processing sometimes makes the thickness of the substrate 102 in a region overlapping with the opening 144a and the opening 144b smaller than the thickness of the substrate 102 in a region not overlapping with the opening 144a and the opening 144b.

Subsequently, the resist mask 158 is removed.

Then, a conductive film 212f to be the conductive layer 212a and the conductive layer 212b later is formed over the substrate 102 and the insulating layer 110 to fill the opening 144a and the opening 144b (FIG. 18B). For the formation of the conductive film 212f, a sputtering method can be suitably used, for example.

Next, CMP treatment is performed on the top surface of the conductive film 212f until the top surface of the insulating layer 110c is exposed. By the treatment, the conductive layer 212a having a top surface substantially level with the top surface of the insulating layer 110c is formed in the opening 144a, and the conductive layer 212b having a top surface substantially level with the top surface of the insulating layer 110c is formed in the opening 144b (FIG. 18C).

Subsequently, a resist mask 159 is formed over the conductive layer 212a, the conductive layer 212b, and the insulating layer 110c. The resist mask 159 is provided to overlap with a region other than regions where the transistor 200 is formed later.

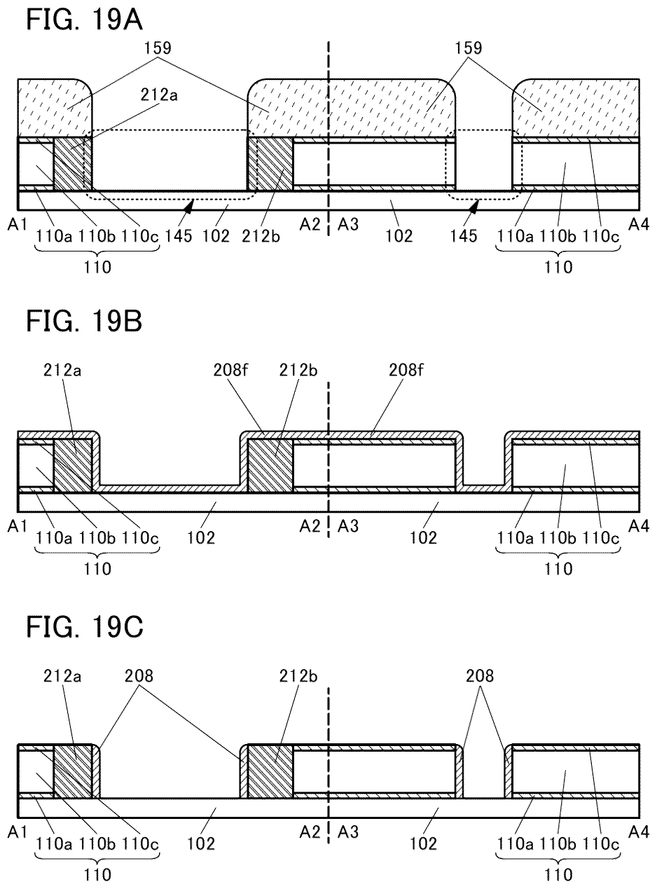

Next, the insulating layer 110 (the insulating layer 110a, the insulating layer 110b, and the insulating layer 110c) is processed so that the opening 145 reaching the substrate 102 is formed between the conductive layer 212a and the conductive layer 212b (FIG. 19A). For the processing of the insulating layer 110, one or both of a wet etching method and a dry etching method can be suitably used. In particular, an anisotropic dry etching method can be suitably used. The use of an anisotropic dry etching method enables the formation of the opening 145 with a minute size and a substantially perpendicular side surface, so that the area occupied by the transistor 200 formed later in the substrate plane can be reduced. By the processing, the side surface of the conductive layer 212a and the side surface of the conductive layer 212b are exposed. The processing sometimes makes the thickness of the substrate 102 in a region overlapping with the opening 145 smaller than the thickness of the substrate 102 in a region not overlapping with the opening 145.

Subsequently, the resist mask 159 is removed.

Next, a metal oxide film 208f to be the semiconductor layer 208 later is formed over the substrate 102, the conductive layer 212a, the conductive layer 212b, and the insulating layer 110 to cover the opening 145 (FIG. 19B). The metal oxide film 208f is provided in contact with the top surface and the side surface of the conductive layer 212a, the top surface and the side surface of the conductive layer 212b, the top surface and the side surface of the insulating layer 110, and the top surface of the substrate 102.

The metal oxide film 208f is preferably formed by a sputtering method using a metal oxide target. Alternatively, the metal oxide film 208f is preferably formed by an ALD method. An ALD method offers high coverage and thus can be suitably used for forming the metal oxide film 208f provided to cover the opening 145. With use of an ALD method, the metal oxide film can be formed also on the side surface of the insulating layer 110 with good coverage. In an ALD method, the thickness is easily controlled by the number of cycles; thus, a thin film can be formed with a high yield.

The metal oxide film 208f is preferably a dense film having as few defects as possible. The metal oxide film 208f is preferably a high-purity film in which impurities including a hydrogen element are reduced as much as possible. It is particularly preferable to use a metal oxide film having crystallinity as the metal oxide film 208f.

In the case of using a sputtering method, an oxygen gas is preferably used in forming the metal oxide film 208f. With use of an oxygen gas, oxygen can be suitably supplied into the insulating layer 110. For example, in the case of using an oxide or an oxynitride for the insulating layer 110b, oxygen can be suitably supplied into the insulating layer 110b.

By the supply of oxygen to the insulating layer 110b, oxygen is supplied to the channel formation region in the semiconductor layer 208 in a later step, so that oxygen vacancies (V_{O}) and V_{O}H in the channel formation region can be reduced.

In forming the metal oxide film 208f, an oxygen gas and an inert gas (e.g., a helium gas, an argon gas, or a xenon gas) may be mixed. Note that the crystallinity of the metal oxide film can be increased and the transistor 200 can have higher reliability when the proportion of the oxygen gas to the whole film formation gas (oxygen flow rate ratio) or the oxygen partial pressure in the treatment chamber is higher in forming the metal oxide film. On the other hand, as the oxygen flow rate ratio or the oxygen partial pressure is lower, the metal oxide film can have lower crystallinity and a higher electrical conduction property, and the transistor 200 can have a higher on-state current.

Here, when the oxygen flow rate ratio or the oxygen partial pressure is high, the metal oxide film has a polycrystalline structure in some cases. In the case where the metal oxide film has a polycrystalline structure, the crystal grain boundary becomes a recombination center and captures carriers, which might decrease the on-state current of the transistor. Therefore, the oxygen flow rate ratio or the oxygen partial pressure is preferably adjusted so that the metal oxide film 208f does not have a polycrystalline structure. Since the ease of forming a polycrystalline structure depends on the composition of the metal oxide film, the oxygen flow rate ratio or the oxygen partial pressure is adjusted in accordance with the composition of the metal oxide film 208f.

As the substrate temperature in forming the metal oxide film is higher, a denser metal oxide film having higher crystallinity can be formed. On the other hand, as the substrate temperature is lower, a metal oxide film having lower crystallinity and a higher electrical conduction property can be formed.

The substrate temperature at the time of forming the metal oxide film 208f is preferably higher than or equal to room temperature and lower than or equal to 250° C., further preferably higher than or equal to room temperature and lower than or equal to 200° C., still further preferably higher than or equal to room temperature and lower than or equal to 140° C. For example, when the substrate temperature is preferably set higher than or equal to room temperature and lower than or equal to 140° C. to achieve high productivity. Furthermore, the metal oxide film 208f that is formed with the substrate temperature set at room temperature or without heating the substrate can have low crystallinity.

When the substrate temperature is high, the metal oxide film 208f may have a polycrystalline structure. The substrate temperature is preferably adjusted so that the metal oxide film 208f does not have a polycrystalline structure. The substrate temperature is adjusted in accordance with the composition applied to the metal oxide film 208f.

In the case of using an ALD method, a film formation method such as a thermal ALD method or a PEALD (Plasma Enhanced ALD) method is preferably used. A thermal ALD method is preferable because of offering extremely high coverage. A PEALD method is preferable because a PEALD method can reduce the amount of organic residues derived from a precursor and can form a film with a favorable film quality, in addition to offering high coverage.

For example, the metal oxide film 208f can be formed by an ALD method using a precursor containing a constituent metal element and an oxidizer.

For example, in the case where In—Ga—Zn oxide is formed, three precursors of a precursor containing indium, a precursor containing gallium, and a precursor containing zinc can be used. Alternatively, two precursors of a precursor containing indium and a precursor containing gallium and zinc may be used.

Examples of the precursor containing indium include triethylindium, tris(2,2,6,6-tetramethyl-3,5-heptanedionato) indium, cyclopentadienylindium, indium (III) chloride, and (3-(dimethylamino) propyl)dimethylindium.

Examples of the precursor containing gallium include trimethylgallium, triethylgallium, gallium trichloride, tris(dimethylamido) gallium, gallium (III) acetylacetonate, tris(2,2,6,6-tetramethyl-3,5-heptanedionato) gallium, dimethylchlorogallium, diethylchlorogallium, and gallium (III) chloride.

Examples of the precursor containing zinc include dimethylzinc, diethylzinc, bis(2,2,6,6-tetramethyl-3,5-heptanedionato) zinc, and zinc chloride.

Examples of the oxidizer include ozone, oxygen, and water.

As a method for controlling the composition of a film to be obtained, adjusting one or more of the kinds of source gases, the flow rate ratio of source gases, the flowing time of the source gases, and the order in which the source gases flow is given. By adjusting these, the composition of the metal oxide film 208f can be controlled. Moreover, by adjusting these, a film whose composition is continuously changed can be formed. The composition of the metal oxide film 208f may be continuously changed.

It is preferable to perform at least one of treatment for desorbing water, hydrogen, an organic substance, and the like adsorbed onto the surface of the insulating layer 110 and treatment for supplying oxygen into the insulating layer 110 before the formation of the metal oxide film 208f. For example, heat treatment can be performed at a temperature higher than or equal to 70° C. and lower than or equal to 200° C. in a reduced-pressure atmosphere. Alternatively, plasma treatment may be performed in an atmosphere containing oxygen. Alternatively, oxygen may be supplied to the insulating layer 110 by plasma treatment in an atmosphere containing an oxidizing gas such as dinitrogen monoxide (N20). Performing plasma treatment including a dinitrogen monoxide gas can supply oxygen while suitably removing an organic substance on the surface of the insulating layer 110. It is preferable that the metal oxide film 208f be formed successively after such treatment, without exposure of the surface of the insulating layer 110 to the air.

Note that in the case where the semiconductor layer 208 has a stacked-layer structure, an upper metal oxide film is preferably formed successively after the formation of a lower metal oxide film without exposure of a surface of the lower metal oxide film to the air.

In the case where the semiconductor layer 208 has a stacked-layer structure, all the layers included in the semiconductor layer 208 may be formed by the same film formation method (e.g., a sputtering method or an ALD method), or the layers may be formed by different film formation methods. For example, the first metal oxide layer may be formed by a sputtering method, and the second metal oxide layer may be formed by an ALD method.

Next, the metal oxide film 208f is processed by anisotropic etching, so that the semiconductor layer 208 in contact with the side surface of the conductive layer 212a in the opening 145, the side surface of the conductive layer 212b in the opening 145, and the side surface of the insulating layer 110 in the opening 145 is formed (FIG. 19C). By the processing, the top surface of the conductive layer 212a, the top surface of the conductive layer 212b, the top surface of the insulating layer 110c, and the top surface of the substrate 102 in the opening 145 are exposed. Note that the processing makes the thickness of the conductive layer 212a, the thickness of the conductive layer 212b, the thickness of the insulating layer 110c, and the thickness of the substrate 102 in the opening 145 smaller than those before the processing in some cases.

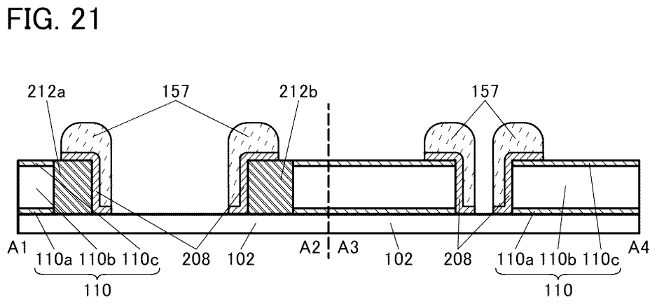

Note that the method for processing the semiconductor layer 208 in the semiconductor device of one embodiment of the present invention is not limited to the above. For example, the semiconductor layer 208 may be formed by performing etching treatment on the metal oxide film 208f through a resist mask. FIG. 21 illustrates a method for forming the semiconductor layer 208 by etching treatment through a resist mask 157.

The resist mask 157 is preferably formed to overlap with a region that extends across both the inner side and the outer side of the opening 145. By performing the etching treatment on the metal oxide film 208f in this state, the semiconductor layer 208 one end portion of which is positioned inside the opening 145 and the other end portion of which is positioned outside the opening 145 can be formed. Note that one or both of a wet etching method and a dry etching method can be suitably used for the etching treatment.

By the etching treatment, part of the top surface of the substrate 102, part of the top surface of the conductive layer 212a, part of the top surface of the conductive layer 212b, and part of the top surface of the insulating layer 110c are exposed. By the etching treatment, the thickness of each of exposed regions of the substrate 102, the conductive layer 212a, the conductive layer 212b, and the insulating layer 110c is sometimes smaller than the thickness of each of the regions of these components that are not exposed. After the etching treatment, the resist mask 157 is removed.

It is preferable that heat treatment be performed after the metal oxide film 208f is formed or after the metal oxide film 208f is processed into the semiconductor layer 208. By the heat treatment, hydrogen or water contained in the metal oxide film 208f or the semiconductor layer 208 or adsorbed onto a surface thereof can be removed. Furthermore, the film quality of the metal oxide film 208f or the semiconductor layer 208 is improved (e.g., the number of defects is reduced or the crystallinity is increased) by the heat treatment in some cases.

Oxygen can be supplied from the insulating layer 110b to the metal oxide film 208f or the semiconductor layer 208 by heat treatment. Thus, oxygen vacancies (V_{O}) in the channel formation region can be reduced. Here, it is further preferable that the heat treatment be performed before the metal oxide film 208f is processed into the semiconductor layer 208. The above description can be referred to for the heat treatment; thus, the detailed description thereof is omitted. Note that supply of oxygen to the channel formation region may be performed not only through the heat treatment but also in a heat application step in and after the formation of the metal oxide film 208f (e.g., the step of forming the insulating layer 106).

Note that the heat treatment is not necessarily performed. The heat treatment is not necessarily performed in this step, and heat treatment performed in a later step may also serve as the heat treatment in this step. In some cases, treatment at a high temperature in a later step (e.g., film formation step) can serve as the heat treatment in this step.

Next, the insulating layer 106 is formed over the semiconductor layer 208, the conductive layer 212a, the conductive layer 212b, the insulating layer 110, and the substrate 102 to cover them

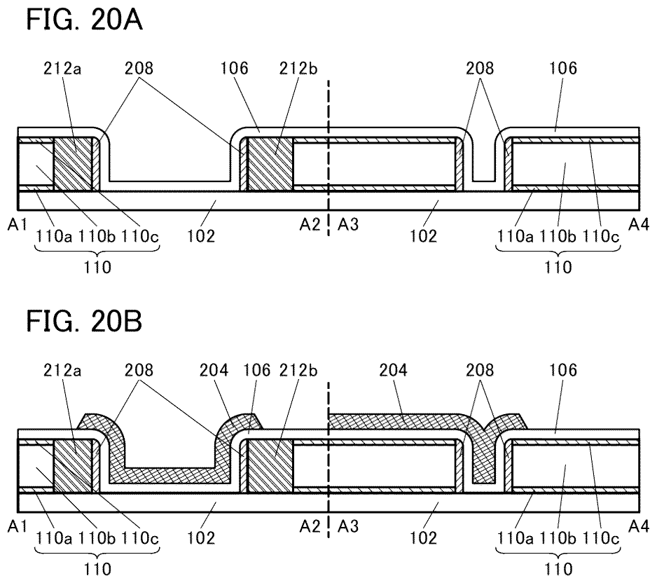

(FIG. 20A). The insulating layer 106 includes regions in contact with the side surface and the top surface of the semiconductor layer 208, the top surface of the conductive layer 212a, the top surface of the conductive layer 212b, the top surface of the insulating layer 110c, and the top surface of the substrate 102. For the formation of the insulating layer 106, for example, a PECVD method or an ALD method can be suitably used.

In the case where a metal oxide is used for the semiconductor layer 208, the insulating layer 106 preferably functions as a barrier film that inhibits diffusion of oxygen. When the insulating layer 106 has a function of inhibiting diffusion of oxygen, oxygen contained in the semiconductor layer 208 is inhibited from diffusing to above the insulating layer 106, and an increase in oxygen vacancies (V_{O}) in the semiconductor layer 208 can be inhibited.

Consequently, the transistor 200 can have favorable electrical characteristics and high reliability.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

By increasing the temperature at the time of forming the insulating layer 106 functioning as the gate insulating layer, the insulating layer including few defects can be obtained. However, the high temperature at the time of forming the insulating layer 106 sometimes allows release of oxygen from the semiconductor layer 208, which increases the amount of oxygen vacancy (V_{O}) and V_{O}H in the semiconductor layer 208 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 208 can be inhibited while the defects in the insulating layer 106 can be reduced. Thus, the transistor 200 can have favorable electrical characteristics and high reliability.

Before the formation of the insulating layer 106, a surface of the semiconductor layer 208 may be subjected to plasma treatment. By the plasma treatment, an impurity adsorbed onto the surface of the semiconductor layer 208, such as water, can be reduced. Accordingly, impurities at the interface between the semiconductor layer 208 and the insulating layer 106 can be reduced, enabling the transistor 200 to have high reliability. The plasma treatment is particularly suitable in the case where the surface of the semiconductor layer 208 is exposed to the air after the formation of the semiconductor layer 208 and before the formation of the insulating layer 106. For example, the plasma treatment can be performed in an atmosphere containing oxygen, ozone, nitrogen, dinitrogen monoxide, argon, or the like. The plasma treatment and the formation of the insulating layer 106 are preferably performed successively without exposure to the air.

Next, a conductive film to be the conductive layer 204 is formed over the insulating layer 106 and the conductive film is processed, so that the conductive layer 204 is formed (FIG. 20B). The conductive layer 204 is preferably formed to include a region overlapping with the semiconductor layer 208 in the plan view. In particular, the conductive layer 204 is preferably formed such that its end portion is positioned outward from an outer side end portion of the semiconductor layer 208 in the plan view. Thus, an electric field from the conductive layer 204 can be applied to the whole semiconductor layer 208 through the insulating layer 106. For the formation of the conductive film, a sputtering method, a thermal CVD method (including an MOCVD method), or an ALD method can be suitably used, for example.

Then, the insulating layer 195 is formed to cover the conductive layer 204 and the insulating layer 106. For the formation of the insulating layer 195, a PECVD method can be suitably used.

Heat treatment may be performed after the formation of the insulating layer 195. Note that the heat treatment is not necessarily performed. The heat treatment in this step may be omitted, and heat treatment performed in a later step may also serve as the heat treatment in this step. In the case where treatment at a high temperature (e.g., film formation step) is performed in a later step, such treatment can also serve as the heat treatment in this step in some cases.

Through the above steps, the transistor 200 included in the semiconductor device 10 of one embodiment of the present invention can be manufactured (FIG. 14A to FIG. 15).

At least part of the structure examples, the drawings corresponding thereto, and the like described as examples in this embodiment can be combined with the other structure examples, the other drawings, and the like as appropriate.

Described next is an example of a method for manufacturing the semiconductor device 10, in which the transistor 200 and the transistor 100 are formed at the same time. Note that the same description as the foregoing description is omitted in some cases.

FIG. 22A to FIG. 25C are cross-sectional views each taken along the dashed-dotted line A1-A2 in FIG. 13A.

First, a film to be the conductive layer 112a is formed over the substrate 102 and the film is processed to form the conductive layer 112a. For the formation of the film, a sputtering method can be suitably used, for example.

Then, the insulating layer 110a and the insulating layer 110b are formed in this order over the conductive layer 112a and the substrate 102 (FIG. 22A). The description in FIG. 17A can be referred to for the formation method of the insulating layer 110a and the insulating layer 110b.

Next, CMP treatment is performed on the top surface of the insulating layer 110b. The treatment makes the top surface of the insulating layer 110b flat (FIG. 22B).

After the insulating layer 110b is formed, oxygen may be supplied to the insulating layer 110b. The description in FIG. 17A can be referred to for a method for supplying oxygen.

The metal oxide film 137 is then preferably formed over the insulating layer 110b (FIG. 22C). The description in FIG. 17B can be referred to for the materials, the formation methods, and the like that can be used for the metal oxide film 137. The formation of the metal oxide film 137 enables oxygen supply to the insulating layer 110b. Thus, a large amount of oxygen can be supplied to the semiconductor layer 108 and the semiconductor layer 208 by the later heat treatment, so that oxygen vacancies (V_{O}) and V_{O}H in the semiconductor layer 108 and the semiconductor layer 208 can be reduced. Thus, the transistor 100 and the transistor 200 can have favorable electrical characteristics and high reliability.

Then, the metal oxide film 137 is removed. The description in FIG. 17B can be referred to for a method for removing the metal oxide film 137, for example.

Note that the method for supplying oxygen to the insulating layer 110b is not limited to the above, and the description in FIG. 17B can be referred to.

Next, the insulating layer 110c is formed over the insulating layer 110b (FIG. 22D). The description in FIG. 17C can be referred to for a method for forming the insulating layer 110c, for example.

Then, a resist mask 156 is formed over the insulating layer 110c. The resist mask 156 is provided to overlap with a region other than regions where the transistor 100 is formed later.

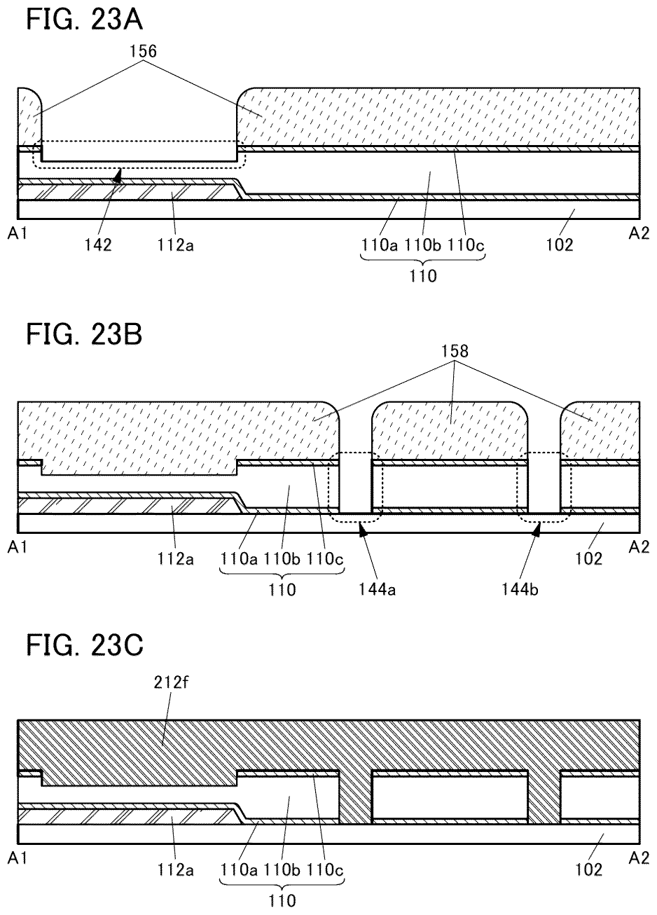

Next, the insulating layer 110c and the insulating layer 110b are processed to form a depressed portion 142 having a bottom surface in the insulating layer 110b (FIG. 23A). The depressed portion 142 is formed to include a region overlapping with the conductive layer 112a. For the processing of the insulating layer 110c and the insulating layer 110b, one or both of a wet etching method and a dry etching method can be suitably used. In particular, an anisotropic dry etching method can be suitably used. The use of an anisotropic dry etching method enables the formation of the depressed portion 142 with a minute size and a high aspect ratio, so that the area occupied by the transistor 100 formed later in the substrate plane can be reduced.

Subsequently, the resist mask 156 is removed.

Then, the resist mask 158 is formed over the insulating layer 110. The resist mask 158 is provided to overlap with a region other than regions where the conductive layer 212a and the conductive layer 212b are formed later.

Next, the insulating layer 110 (the insulating layer 110a, the insulating layer 110b, and the insulating layer 110c) is processed to form the opening 144a and the opening 144b in which the conductive layer 212a and the conductive layer 212b are formed later (FIG. 23B). The description in FIG. 18A can be referred to for a method for forming the insulating layer 110, for example.

Subsequently, the resist mask 158 is removed.

Although an example in which the opening 144a and the opening 144b are formed (FIG. 23B) after the formation of the depressed portion 142 (FIG. 23A) is described above, one embodiment of the present invention is not limited thereto. For example, the depressed portion 142 may be formed after the opening 144a and the opening 144b are formed.

Then, the conductive film 212f to be the conductive layer 212a and the conductive layer 212b later is formed over the substrate 102 and the insulating layer 110 to fill the opening 144a and the opening 144b (FIG. 23C). The description in FIG. 18B can be referred to for a method for forming the conductive film 212f, for example.

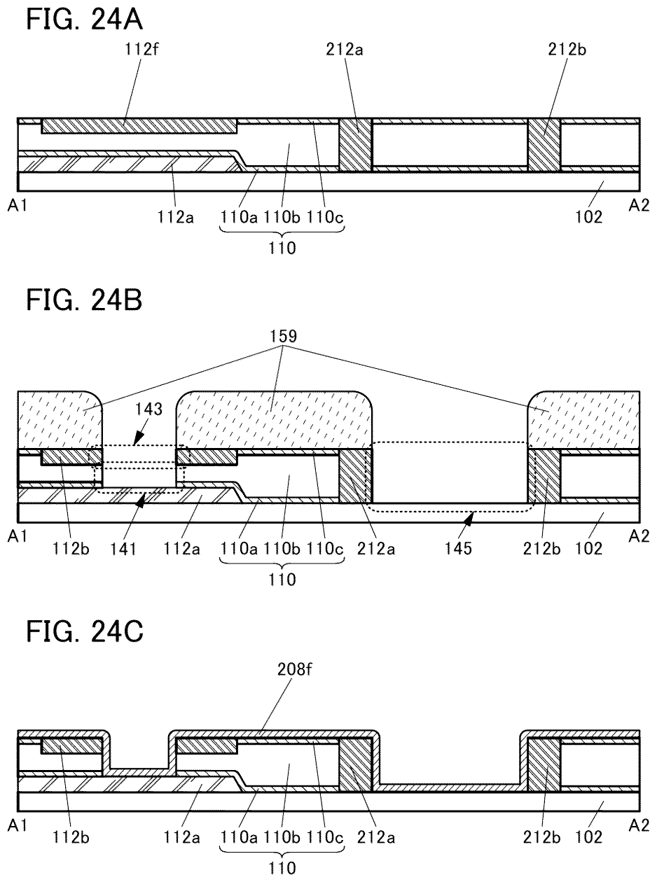

Next, CMP treatment is performed on the top surface of the conductive film 212f until the top surface of the insulating layer 110c is exposed. By the treatment, a conductive layer 112f having a top surface substantially level with the top surface of the insulating layer 110c is formed in the depressed portion 142, the conductive layer 212a having a top surface substantially level with the top surface of the insulating layer 110c is formed in the opening 144a, and the conductive layer 212b having a top surface substantially level with the top surface of the insulating layer 110c is formed in the opening 144b (FIG. 24A).

Subsequently, the resist mask 159 is formed over the conductive layer 112f, the conductive layer 212a, the conductive layer 212b, and the insulating layer 110c. The resist mask 159 is provided to overlap with a region other than regions where the transistor 100 and the transistor 200 are formed later.

Next, the conductive layer 112f and the insulating layer 110 (the insulating layer 110a, the insulating layer 110b, and the insulating layer 110c) are processed so that the opening 143 and the opening 141 reaching the conductive layer 112a and the opening 145 reaching the substrate 102 are formed (FIG. 24B). For the processing method of the conductive layer 112f and the insulating layer 110, the description on the processing method of the insulating layer 110 in FIG. 19A can be referred to, for example. By the processing, the conductive layers 112b are formed from the conductive layer 112f. In addition, the side surface of the conductive layer 212a and the side surface of the conductive layer 212b are exposed by the processing. The processing sometimes makes the thickness of the conductive layer 112a in a region overlapping with the opening 143 and the opening 141 smaller than the thickness of the conductive layer 112a in a region not overlapping with the opening 143 and the opening 141. In other cases, the thickness of the substrate 102 in a region overlapping with the opening 145 is made smaller than that of the substrate 102 in a region not overlapping with the opening 145.

Subsequently, the resist mask 159 is removed.

Although an example in which the formation of the opening 143 and the opening 141 and the formation of the opening 145 are performed at the same time is described above, one embodiment of the present invention is not limited thereto. The following example may be employed: first, a first resist mask is provided to overlap with a region other than the region where the transistor 100 is formed, and the conductive layer 112f and the insulating layer 110 are processed to form the opening 143 and the opening 141; then, after the first resist mask is removed, a second resist mask is provided to overlap with a region other than the region where the transistor 200 is formed, and the insulating layer 110 is processed to form the opening 145; finally, the second resist mask is removed. Alternatively, in contrast to the above, the opening 143 and the opening 141 may be formed after the opening 145 is formed. The opening 143 and the opening 141 may be formed at a time or separately. For example, after the opening 143 is formed, the opening 141 may be formed under different processing conditions.

Next, the metal oxide film 208f to be the semiconductor layer 108 and the semiconductor layer 208 later is formed over the conductive layer 112a, the conductive layer 112b, the substrate 102, the conductive layer 212a, the conductive layer 212b, and the insulating layer 110 to cover the opening 143, the opening 141, and the opening 145 (FIG. 24C). The metal oxide film 208f is provided in contact with the top surface of the conductive layer 112a, the top surface and the side surface of the conductive layer 112b, the top surface and the side surface of the conductive layer 212a, the top surface and the side surface of the conductive layer 212b, the top surface and the side surface of the insulating layer 110, and the top surface of the substrate 102. The description in FIG. 19B can be referred to for a method for forming the metal oxide film 208f, for example.

Then, a resist mask 155 is formed over the metal oxide film 208f. The resist mask 155 is provided to include a region overlapping with the opening 143 and the opening 141.

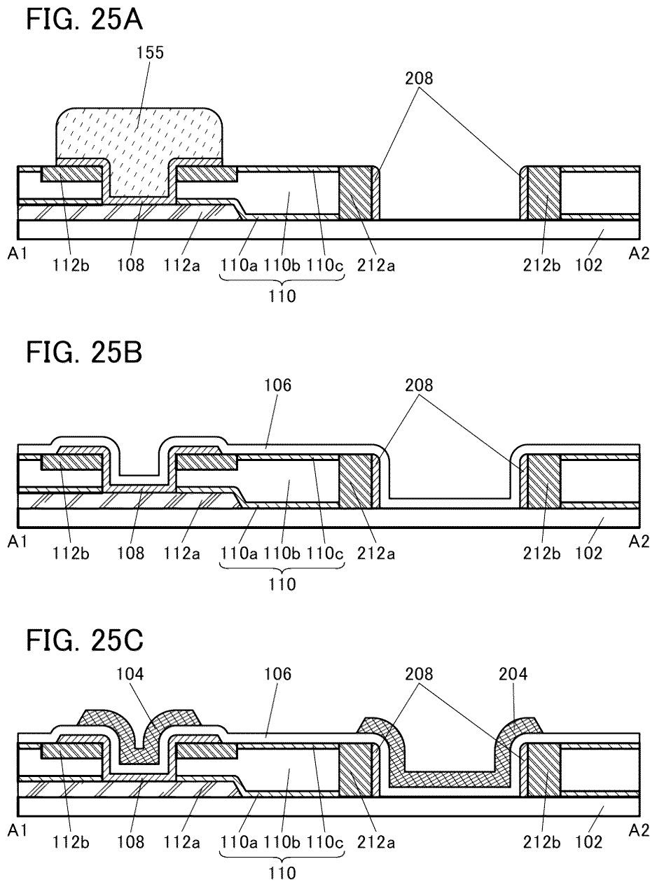

Next, the metal oxide film 208f is processed by anisotropic etching, so that the semiconductor layer 108 and the semiconductor layer 208 are formed (FIG. 25A). The semiconductor layer 108 includes regions in contact with the top surface of the conductive layer 112a in the opening 141, the side surface of the insulating layer 110 in the opening 141, the side surface of the conductive layer 112b in the opening 143, and the top surface of the conductive layer 112b. The semiconductor layer 208 includes regions in contact with the side surface of the conductive layer 212a in the opening 145, the side surface of the conductive layer 212b in the opening 145, and the side surface of the insulating layer 110 in the opening 145. By the processing, part of the top surface of the conductive layer 112b, the top surface of the conductive layer 212a, the top surface of the conductive layer 212b, the top surface of the insulating layer 110c, and the top surface of the substrate 102 in the opening 145 are exposed. Note that the processing makes the thickness of the exposed part of the conductive layer 112b, the thickness of the conductive layer 212a, the thickness of the conductive layer 212b, the thickness of the insulating layer 110c, and the thickness of the substrate 102 in the opening 145 smaller than those before the processing in some cases.

Note that the method for processing the semiconductor layer 208 in the semiconductor device of one embodiment of the present invention is not limited to the above. For example, the semiconductor layer 208 may be formed by performing etching treatment on the metal oxide film 208f through a resist mask. The description in FIG. 21 can be referred to for a method for forming the semiconductor layer 208, for example.

Heat treatment may be performed after the metal oxide film 208f is formed or after the metal oxide film 208f is processed into the semiconductor layer 108 and the semiconductor layer 208. For the heat treatment method or the like, the description on the heat treatment or the like that can be performed after the formation of the metal oxide film 208f or the processing of the semiconductor layer 208 described with reference to FIG. 19C can be referred to.

Subsequently, the resist mask 155 is removed.

Next, the insulating layer 106 is formed over the semiconductor layer 108, the conductive layer 112b, the semiconductor layer 208, the conductive layer 212a, the conductive layer 212b, the insulating layer 110, and the substrate 102 to cover them (FIG. 25B). The description in FIG. 20A can be referred to for a method for forming the insulating layer 106, for example.

Next, a conductive film to be the conductive layer 104 and the conductive layer 204 is formed over the insulating layer 106 and the conductive film is processed, so that the conductive layer 104 and the conductive layer 204 are formed (FIG. 25C). The conductive layer 104 is preferably formed to include a region overlapping with the conductive layer 112b in a plan view. Thus, an electric field from the conductive layer 104 can be certainly applied to the whole channel formation region in the semiconductor layer 108 through the insulating layer 106. The conductive layer 204 is preferably formed to include a region overlapping with the semiconductor layer 208 in the plan view. In particular, the conductive layer 204 is preferably formed such that its end portion is positioned outward from an outer side end portion of the semiconductor layer 208 in the plan view. Thus, an electric field from the conductive layer 204 can be certainly applied to the whole semiconductor layer 208 through the insulating layer 106. For the formation method of the conductive film, the description on the formation method of the conductive film to be the conductive layer 204 in FIG. 20B can be referred to.

Then, the insulating layer 195 is formed to cover the conductive layer 104, the conductive layer 204, and the insulating layer 106. For the formation method of the insulating layer 195, the description in FIG. 20B can be referred to.

Through the above steps, the transistor 100 and the transistor 200 included in the semiconductor device 10 of one embodiment of the present invention can be manufactured (FIG. 13A and FIG. 13B).

At least part of the structure examples, the drawings corresponding thereto, and the like described as examples in this embodiment can be combined with the other structure examples, the other drawings, and the like as appropriate.

### Embodiment 4

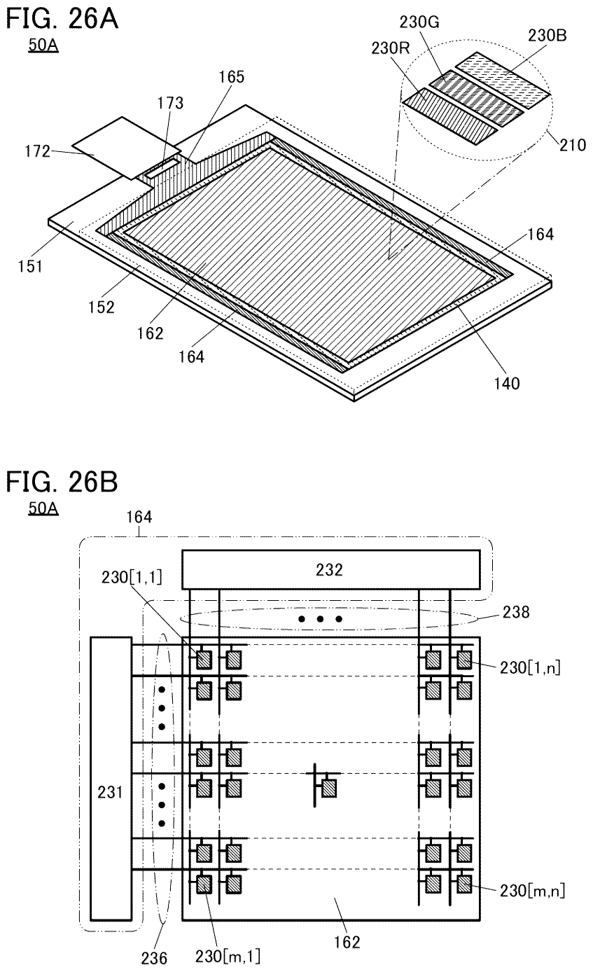

In this embodiment, the display apparatus of one embodiment of the present invention will be described with reference to FIG. 26A to FIG. 29.

The display apparatus of this embodiment can be a high-definition display apparatus or a large-sized display apparatus. Accordingly, for example, the display apparatus of this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, a desktop or laptop computer, a monitor of a computer or the like, digital signage, and a large game machine such as a pachinko machine.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display apparatus or a module including the display apparatus. Examples of the module including the display apparatus include a module in which a connector such as a flexible printed circuit board (hereinafter referred to as an FPC) or a TCP (Tape Carrier Package) is attached to the display apparatus, a module in which the display apparatus is mounted with an integrated circuit (IC) by a COG (Chip On Glass) method, a COF (Chip On Film) method, or the like. The display apparatus of this embodiment may have a function of a touch panel. The display apparatus can employ any of a variety of sensor elements that can sense proximity or touch of a sensing target such as a finger, for example.

Examples of the sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of the mutual capacitive type is preferable because multiple points can be sensed simultaneously.

Examples of a touch panel include an out-cell type, an on-cell type, and an in-cell type. Note that an in-cell touch panel has a structure in which an electrode included in a sensor element is provided on one or both of a substrate supporting a display element (also referred to as a display device) and a counter substrate.

### Structure Example 1

FIG. 26A illustrates a perspective view of a display apparatus 50A.

The display apparatus 50A has a structure in which a substrate 152 and a substrate 151 are attached to each other. In FIG. 26A, the substrate 152 is indicated by a dashed line.

The display apparatus 50A includes a display portion 162, a connection portion 140, a circuit portion 164, a conductive layer 165, and the like. FIG. 26A illustrates an example in which an IC 173 and an FPC 172 are mounted on the display apparatus 50A. Thus, the structure illustrated in FIG. 26A can be regarded as a display module including the display apparatus 50A, the IC, and the FPC.

The connection portion 140 is provided outside the display portion 162. The connection portion 140 can be provided along one or more sides of the display portion 162. The number of connection portions 140 may be one or more. In the example illustrated in FIG. 26A, the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or input to the conductive layer 165 from the IC 173. FIG. 26A illustrates an example in which the IC 173 is provided on the substrate 151 by a COG method, a COF method, or the like. An IC including one or both of a scan line driver circuit and a signal line driver circuit can be used as the IC 173, for example. Note that the display apparatus 50A and the display module may be configured not to include an IC. The IC may be mounted on the FPC by a COF method or the like.

The semiconductor device of one embodiment of the present invention can be used for one or both of the display portion 162 and the circuit portion 164 of the display apparatus 50A, for example.

When the semiconductor device of one embodiment of the present invention is used for a pixel circuit of a display apparatus, the area occupied by the pixel circuit can be reduced and the display apparatus can have high resolution, for example. When the semiconductor device of one embodiment of the present invention is used for a driver circuit (e.g., one or both of a gate line driver circuit and a source line driver circuit) of the display apparatus, the area occupied by the driver circuit can be reduced and the display apparatus can have a narrow bezel, for example.

Since the semiconductor device of one embodiment of the present invention has favorable electrical characteristics, the display apparatus can have increased reliability by using the semiconductor device.

The display portion 162 of the display apparatus 50A is a region where an image is to be displayed, and includes a plurality of pixels 210 that are periodically arranged. FIG. 26A illustrates an enlarged view of one pixel 210.

There is no particular limitation on the arrangement of the pixels in the display apparatus of this embodiment, and a variety of methods can be used. Examples of the arrangement of the pixels include a stripe arrangement, an S-stripe arrangement, a matrix arrangement, a delta arrangement, a Bayer arrangement, and a PenTile arrangement.

The pixel 210 illustrated in FIG. 26A includes a pixel 230R that emits red light, a pixel 230G that emits green light, and a pixel 230B that emits blue light. Since one pixel 210 is formed by the pixel 230R, the pixel 230G, and the pixel 230B, full-color display can be achieved. The pixel 230R, the pixel 230G, and the pixel 230B each function as a subpixel. The display apparatus 50A illustrated in FIG. 26A shows an example in which the pixels 230 each functioning as a subpixel are arranged in a stripe pattern. The number of subpixels for forming one pixel 210 is not limited to three, and may be four or more. For example, four subpixels which emit light of R, G, B, and white (W) may be included. Alternatively, four subpixels which emit light of four colors, R, G, B, and Y may be included.

The pixel 230R, the pixel 230G, and the pixel 230B each include a display element and a circuit for controlling the driving of the display element.

A variety of elements can be used as the display element, and a liquid crystal element or a light-emitting device can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

Examples of a display apparatus using a liquid crystal element include a transmissive liquid crystal display apparatus, a reflective liquid crystal display apparatus, and a transflective liquid crystal display apparatus.

Examples of a mode that can be employed for a display apparatus including a liquid crystal element include a vertical alignment (VA) mode, an FFS (Fringe Field Switching) mode, an IPS (In-Plane-Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of the light-emitting device include self-luminous light-emitting devices such as an LED, an OLED (Organic LED), and a semiconductor laser. As the LED, for example, a mini LED or a micro LED can be used.

Examples of a light-emitting substance contained in the light-emitting device include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material).

The light-emitting device can emit infrared, red, green, blue, cyan, magenta, yellow, or white light, for example. Furthermore, color purity can be increased when the light-emitting device has a microcavity structure.

One of a pair of electrodes of the light-emitting device functions as an anode, and the other electrode functions as a cathode.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

In this embodiment, the case where a light-emitting device is used as the display element is mainly described as an example.

FIG. 26B is a block diagram illustrating the display apparatus 50A. The display apparatus 50A includes the display portion 162 and the circuit portion 164. The display portion 162 includes a plurality of pixels 230 arranged periodically (a pixel 230 [1,1] to a pixel 230 [m,n], where m and n are each independently an integer greater than or equal to 2). The circuit portion 164 includes a first driver circuit portion 231 and a second driver circuit portion 232.

A circuit included in the first driver circuit portion 231 functions as, for example, a scan line driver circuit. A circuit included in the second driver circuit portion 232 functions as, for example, a signal line driver circuit. Some sort of circuit may be provided to face the first driver circuit portion 231 with the display portion 162 placed therebetween. Some sort of circuit may be provided to face the second driver circuit portion 232 with the display portion 162 placed therebetween.

Any of various circuits such as a shift register circuit, a level shifter circuit, an inverter circuit, a latch circuit, an analog switch circuit, a demultiplexer circuit, and a logic circuit can be used as the circuit portion 164. In the circuit portion 164, a transistor, a capacitor, and the like can be used. Transistors included in the circuit portion 164 may be formed in the same process as the transistors included in the pixels 230.

The display apparatus 50A includes wirings 236 which are arranged substantially parallel to each other and whose potentials are controlled by the circuits included in the first driver circuit portion 231, and wirings 238 which are arranged substantially parallel to each other and whose potentials are controlled by the circuits included in the second driver circuit portion 232. FIG. 26B illustrates an example in which the wiring 236 and the wiring 238 are connected to the pixel 230. Note that the wiring 236 and the wiring 238 are examples, and the wirings connected to the pixel 230 are not limited to the wiring 236 and the wiring 238.

The semiconductor device of one embodiment of the present invention includes a VLFET that has a long channel length and high saturability. An oxide semiconductor (OS) can be suitably used for a channel formation region of the transistor, so that the transistor can have a low off-state current. The semiconductor device of one embodiment of the present invention can be suitably used for one or both of the display portion 162 and the circuit portion 164. The semiconductor device of one embodiment of the present invention can be used for both the display portion 162 and the circuit portion 164; that is, all the transistors included in the display apparatus can be OS transistors. When all the transistors included in the display apparatus are OS transistors as described above, an effect of reducing the manufacturing cost can be obtained.

### Structure Example 2

Using a latch circuit as an example, a structure example of a circuit that can be used in the circuit portion 164 is described.

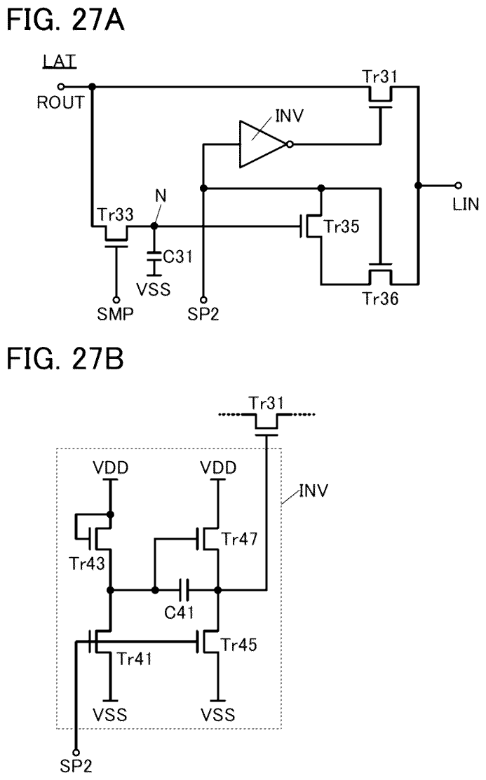

FIG. 27A is a circuit diagram illustrating a structure example of a latch circuit LAT. The latch circuit LAT illustrated in FIG. 27A includes a transistor Tr31, a transistor Tr33, a transistor Tr35, a transistor Tr36, a capacitor C31, and an inverter circuit INV. In FIG. 27A, a node where one of a source and a drain of the transistor Tr33, a gate of the transistor Tr35, and one electrode of the capacitor C31 are electrically connected to one another is referred to as a node N.

In the latch circuit LAT illustrated in FIG. 27A, when a high potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is retained and the data written to the latch circuit LAT is retained. Specifically, when the potential of the node N is a low potential, data “O” is retained in the latch circuit LAT and when the potential of the node Nis a high potential, data “1” is retained in the latch circuit LAT, for example.

A transistor with a low off-state current is preferably used as the transistor Tr33. An OS transistor can be suitably used as the transistor Tr33. Thus, the latch circuit LAT can retain data for a long period. Thus, the frequency of rewriting data in the latch circuit LAT can be lowered.

In this specification and the like, writing data to the latch circuit LAT such that a signal input from a terminal SP2 is output to a terminal LIN is simply referred to as “writing data to the latch circuit LAT”, in some cases. That is, for example, data “1” is written to the latch circuit

LAT, which is referred to simply as “writing data to the latch circuit LAT” in some cases. The semiconductor device of one embodiment of the present invention can be suitably used for the latch circuit LAT. For example, the VLFET (the transistor 200 or the like) or the VFET (the transistor 100 or the like) included in the semiconductor device of one embodiment of the present invention can be used as one or more of the transistor Tr31, the transistor Tr33, the transistor Tr35, and the transistor Tr36.

FIG. 27B illustrates a structure example of the inverter circuit INV. The inverter circuit INV includes a transistor Tr41, a transistor Tr43, a transistor Tr45, a transistor Tr47, and a capacitor C41.

When the latch circuit LAT has the structure illustrated in FIG. 27A and the inverter circuit INV has the structure illustrated in FIG. 27B, all the transistors included in the latch circuit LAT can be transistors having the same polarity, for example, n-channel transistors. Thus, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same process.

The semiconductor device of one embodiment of the present invention can be suitably used for the inverter circuit INV. For example, the VLFET (the transistor 200 or the like) or the VFET (the transistor 100 or the like) included in the semiconductor device of one embodiment of the present invention can be used for one or more of the transistor Tr41, the transistor Tr43, the transistor Tr45, and the transistor Tr47.

The VLFET (the transistor 200 or the like) with a long channel length included in the semiconductor device of one embodiment of the present invention can be suitably used for a transistor that requires high saturability. When the VFET (the transistor 100 or the like) with a short channel length is used, the area occupied by the transistor can be reduced, so that the display apparatus can have a narrow bezel. The VFET (the transistor 100 or the like) with a short channel length can be suitably used as a transistor that requires a high on-state current. Accordingly, the display apparatus can have high performance.

### Structure Example 3

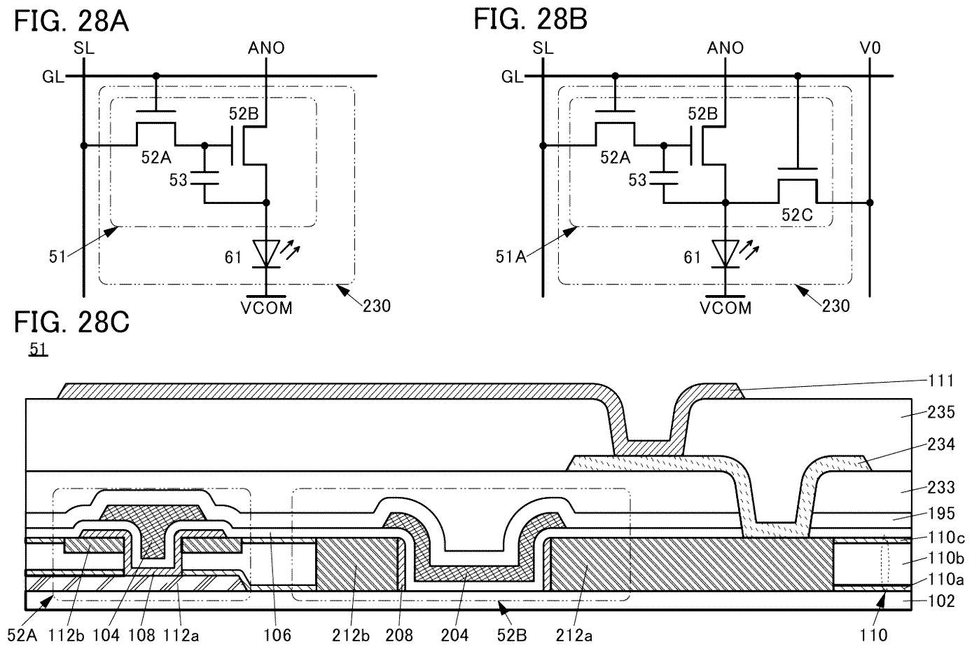

FIG. 28A illustrates a structure example of the pixel 230. The pixel 230 includes a pixel circuit 51 and a light-emitting device 61.

The pixel circuit 51 illustrated in FIG. 28A is a 2Tr1C-type pixel circuit including a transistor 52A, a transistor 52B, and a capacitor 53. Note that there is no particular limitation on the pixel circuit that can be used for the display apparatus of one embodiment of the present invention.

An anode of the light-emitting device 61 is electrically connected to one of a source and a drain of the transistor 52B and one electrode of the capacitor 53. The other of the source and the drain of the transistor 52B is electrically connected to a wiring ANO. A gate of the transistor 52B is electrically connected to one of a source and a drain of the transistor 52A and the other electrode of the capacitor 53. The other of the source and the drain of the transistor 52A is electrically connected to a wiring GL. A gate of the transistor 52A is electrically connected to the wiring GL. A cathode of the light-emitting device 61 is electrically connected to a wiring VCOM.

The wiring GL corresponds to the wiring 236, and a wiring SL corresponds to the wiring 238. The wiring VCOM is a wiring that supplies a potential for supplying current to the light-emitting device 61. The transistor 52A has a function of controlling the conduction state or the non-conduction state between the wiring SL and the gate of the transistor 52B on the basis of the potential of the wiring GL. For example, VDD is supplied to the wiring ANO, and VSS is supplied to the wiring VCOM.

The transistor 52B has a function of controlling the amount of current flowing through the light-emitting device 61. The capacitor 53 has a function of retaining a gate potential of the transistor 52B. The intensity of light emitted by the light-emitting device 61 is controlled in accordance with an image signal supplied to the gate of the transistor 52B.

Some or all of the transistors included in the pixel circuit 51 may be provided with a back gate. For example, a structure may be employed where the transistor 52B included in the pixel circuit 51 includes a back gate, and the back gate is electrically connected to the one of the source and the drain of the transistor 52B. A structure in which the back gate of the transistor 52B is electrically connected to the gate of the transistor 52B may be employed as well.

The above-described semiconductor device can be suitably used for the pixel circuit 51. The transistor 52B functioning as a driving transistor that controls current flowing through the light-emitting device 61 preferably has higher saturability than the transistor 52A functioning as a selection transistor for controlling a selection state of the pixel 230. When the VLFET (the transistor 200 or the like) with a long channel length of one embodiment of the present invention is used as the transistor 52B, a highly reliable display apparatus can be obtained. Furthermore, when the VFET (the transistor 100 or the like) with a shorter channel length than the transistor 52B is used as the transistor 52A, the area occupied by a pixel circuit 51A can be reduced, so that a high-resolution display apparatus can be obtained.

Note that the VFET (the transistor 100 or the like) with a shorter channel length than the transistor 52A may be used as the transistor 52B. The use of a transistor having a short channel length as the transistor 52B enables the display apparatus to have high luminance. Furthermore, the area occupied by the pixel circuit 51 can be reduced, so that a high-resolution display apparatus can be obtained.

FIG. 28B illustrates a structure example different from that of the pixel 230 illustrated in FIG. 28A. The pixel 230 includes the pixel circuit 51A and the light-emitting device 61. The pixel circuit 51A illustrated in FIG. 28B is different from the pixel circuit 51 illustrated in FIG. 28A mainly in including a transistor 52C. The pixel circuit 51A is a 3Tr1C-type pixel circuit including the transistor 52A, the transistor 52B, the transistor 52C, and the capacitor 53.

One of a source and a drain of the transistor 52C is electrically connected to one of a source and a drain of the transistor 52B. The other of the source and the drain of the transistor 52C is electrically connected to a wiring V0. For example, a reference potential is supplied to the wiring V0. A gate of the transistor 52C is electrically connected to the wiring GL.

The transistor 52C has a function of controlling the conduction state or the non-conduction state between one of a source electrode and a drain electrode of the transistor 52B and the wiring V0 on the basis of the potential of the wiring GL. Variations in voltage between the gate and the source of the transistor 52B can be inhibited by the reference potential of the wiring V0 supplied through the transistor 52C.

A current value that can be used for setting pixel parameters can be obtained with the use of the wiring V0. Specifically, the wiring V0 can function as a monitor line for outputting current flowing through the transistor 52B or current flowing through the light-emitting device 61 to the outside. Current output to the wiring V0 is converted into a voltage by a source follower circuit and can be output to the outside. Alternatively, the current is converted into a digital signal by an A/D converter and can be output to the outside.

The above-described semiconductor device can be suitably used for the pixel circuit 51A. When the VLFET (the transistor 200 or the like) with a long channel length of one embodiment of the present invention is used as the transistor 52B, a highly reliable display apparatus can be provided. Furthermore, when the VFET (the transistor 100 or the like) with a shorter channel length than the transistor 52B is used as each of the transistor 52A and the transistor 52C, the area occupied by the pixel circuit 51A can be reduced, so that a high-resolution display apparatus can be obtained. Note that the VFET (the transistor 100 or the like) with a shorter channel length than the transistor 52A may be used as the transistor 52B.

FIG. 28C illustrates a structure example of the pixel circuit 51. FIG. 28C is a cross-sectional view of the pixel circuit 51. FIG. 28C selectively illustrates the transistor 52A, the transistor 52B, and a pixel electrode of the light-emitting device 61. Note that the electrical connection between the transistor 52A and the transistor 52B is omitted.

The transistor 52A includes the conductive layer 104, the insulating layer 106, the semiconductor layer 108, the conductive layer 112a, and the conductive layer 112b. The transistor 52B includes the insulating layer 106, the semiconductor layer 208, the conductive layer 204, the conductive layer 212a, and the conductive layer 212b. The above description can be referred to for the transistor 52A and the transistor 52B; thus, the detailed description is omitted.

The insulating layer 195 is provided to cover the transistor 52A, the transistor 52B, and the capacitor 53, an insulating layer 233 is provided to cover the insulating layer 195, and an insulating layer 235 is provided to cover the insulating layer 233. The light-emitting device 61 can be provided over the insulating layer 235. FIG. 28C illustrates a pixel electrode 111 functioning as one electrode of the light-emitting device 61. The insulating layer 106, the insulating layer 195, and the insulating layer 233 include a first opening reaching the conductive layer 212a, and a conductive layer 234 is provided to cover the first opening. The conductive layer 234 is electrically connected to the conductive layer 212a through the first opening. The insulating layer 235 includes a second opening reaching the conductive layer 234, and the pixel electrode 111 is provided to cover the second opening. The pixel electrode 111 is electrically connected to the conductive layer 234 through the second opening. The above description can be referred to for the insulating layer 195; thus, the detailed description thereof is omitted. The insulating layer 233 and the insulating layer 235 have a function of reducing unevenness due to the transistor 52A, the transistor 52B, and the transistor 52C and making the formation surface of the light-emitting device 61 flatter. Note that in this specification and the like, each of the insulating layer 233 and the insulating layer 235 is referred to as a planarization layer in some cases.

An organic insulating film is suitable as each of the insulating layer 233 and the insulating layer 235. Examples of a material that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The insulating layer 235 may have a stacked-layer structure of an organic insulating film and an inorganic insulating film. The insulating layer 235 preferably has a stacked-layer structure of an organic insulating film and an inorganic insulating film over the organic insulating film. Thus, the inorganic insulating film can function as an etching protective layer at the time of forming the light-emitting device 61. Specifically, the inorganic insulating film can inhibit formation of a depressed portion in the insulating layer 235 due to etching of part of the insulating layer 235 at the time of forming the pixel electrode 111. Alternatively, a depressed portion may be formed in the insulating layer 235 at the time of forming the pixel electrode 111. Similarly, the insulating layer 233 may have a stacked-layer structure of an organic insulating film and an inorganic insulating film.

Note that the conductive layer 234 and the insulating layer 233 are not necessarily provided when not needed; in that case, the pixel electrode 111 and the conductive layer 212a are electrically connected to each other through an opening provided in the insulating layer 235.

### Structure Example 4

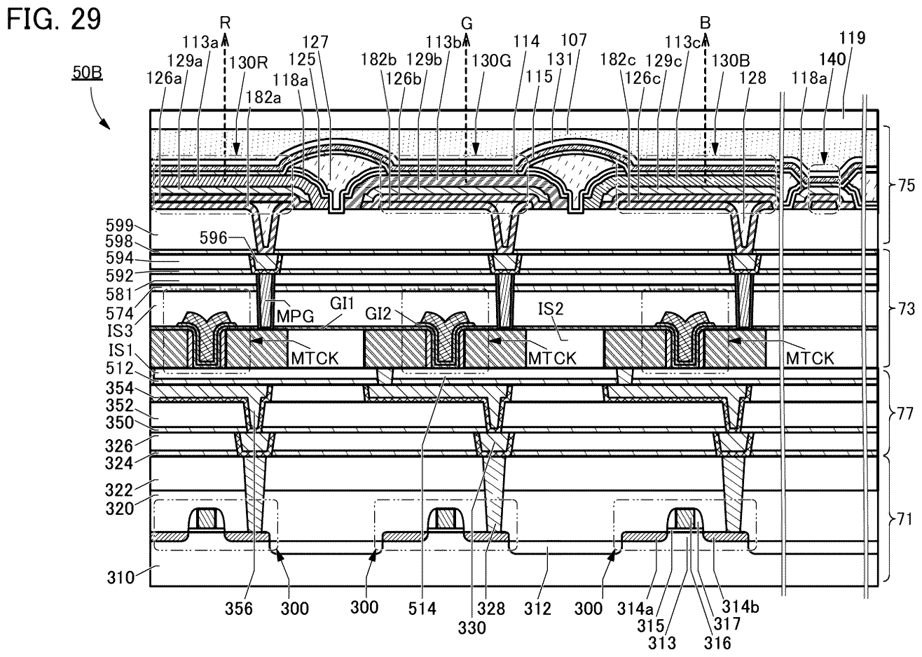

FIG. 29 illustrates a structure example different from the above. A display apparatus 50B has a structure provided with a pixel circuit, a driver circuit, and the like over a substrate 310. The display apparatus 50B includes an element layer 71, an element layer 73, an element layer 75, and a wiring layer 77. The wiring layer 77 is a layer provided with a wiring.

The element layer 71 includes the substrate 310, and a transistor 300 is formed over the substrate 310. The wiring layer 77 is provided above the transistor 300, and the wiring layer 77 includes a wiring that electrically connects the transistor 300, a transistor MTCK, a light-emitting device 130R, a light-emitting device 130G, and a light-emitting device 130B. The element layer 73 and the element layer 75 are provided above the wiring layer 77, and the element layer 73 includes the transistor MTCK, for example. The element layer 75 includes the light-emitting device 130 (the light-emitting device 130R, the light-emitting device 130G, and the light-emitting device 130B in FIG. 29), for example.

The transistor 300 can be a transistor included in the element layer 71. The transistor MTCK can be a transistor included in the element layer 73. The light-emitting device 130 can be a light-emitting device included in the element layer 75.

As the substrate 310, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 310. In the description of this embodiment, the substrate 310 is a semiconductor substrate containing silicon as a material. Therefore, the transistor included in the element layer 71 can be a Si transistor.

The transistor 300 includes an element isolation layer 312, a conductive layer 316, an insulating layer 315, an insulating layer 317, a semiconductor region 313 that is part of the substrate 310, and a low-resistance region 314a and a low-resistance region 314b that function as a source region and a drain region. Thus, the transistor 300 is a Si transistor. Although FIG. 29 illustrates a structure in which one of a source and a drain of the transistor 300 is electrically connected to a conductive layer 330, a conductive layer 356, and a conductive layer 514, which are described later, through a conductive layer 328 described later, the electrical connection in the display apparatus of one embodiment of the present invention is not limited thereto. The display apparatus of one embodiment of the present invention may have a structure in which, for example, a gate of the transistor 300 is electrically connected to the conductive layer 514 through the conductive layer 328.

The transistor 300 can be a Fin-type transistor when, for example, the top surface of the semiconductor region 313 and the side surface thereof in the channel width direction are covered with the conductive layer 316 with the insulating layer 315 functioning as a gate insulating layer therebetween. The effective channel width can be increased in the Fin-type transistor 300, so that the on-state characteristics of the transistor 300 can be improved. In addition, contribution of the electric field of a gate electrode can be increased, so that the off-state characteristics of the transistor 300 can be improved. The transistor 300 may have a planar structure instead of a Fin-type structure.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 300 may be an HEMT (High Electron Mobility Transistor) using gallium arsenide and aluminum gallium arsenide, for example.

For the conductive layer 316 functioning as a gate electrode, a semiconductor material such as silicon containing an element that imparts n-type conductivity, such as arsenic or phosphorus, or an element that imparts p-type conductivity, such as boron or aluminum, can be used. Alternatively, for the conductive layer 316, a conductive material such as a metal material, an alloy material, or a metal oxide material can be used, for example.

Note that since a work function depends on the material of the conductor, the threshold voltage of the transistor can be adjusted by selecting the material of the conductor. Specifically, it is preferable to use one or both of titanium nitride and tantalum nitride as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Over the transistor 300 illustrated in FIG. 29, an insulating layer 320 and an insulating layer 322 are provided to be stacked sequentially from the substrate 310 side.

For the insulating layer 320 and the insulating layer 322, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 322 may have a function of a planarization film for eliminating a level difference caused by the transistor 300 or the like covered with the insulating layer 320 and the insulating layer 322. For example, the top surface of the insulating layer 322 may be planarized through planarization treatment using CMP treatment to increase the level of planarity.

The conductive layer 328 connected to the transistor MTCK and the like provided above the insulating layer 322 is embedded in the insulating layer 320 and the insulating layer 322. Note that the conductive layer 328 has a function of a plug or a wiring. Thus, a material that can be used for a conductive layer MPG can be used for the conductive layer 328.

In the display apparatus 50B, the wiring layer 77 is provided over the transistor 300. The wiring layer 77 includes, for example, an insulating layer 324, an insulating layer 326, the conductive layer 330, an insulating layer 350, an insulating layer 352, an insulating layer 354, and the conductive layer 356.

Over the insulating layer 322 and the conductive layer 328, the insulating layer 324 and the insulating layer 326 are provided to be stacked in this order. An opening is formed in the insulating layer 324 and the insulating layer 326 in a region overlapping with the conductive layer 328. In addition, the conductive layer 330 is embedded in the opening.

The insulating layer 350, the insulating layer 352, and the insulating layer 354 are provided to be stacked sequentially over the insulating layer 326 and the conductive layer 330. An opening is formed in the insulating layer 350, the insulating layer 352, and the insulating layer 354 in a region overlapping with the conductive layer 330. The conductive layer 356 is embedded in the opening.

The conductive layer 330 and the conductive layer 356 have a function of a plug or a wiring that is connected to the transistor 300. Note that the conductive layer 330 and the conductive layer 356 can be provided using a material similar to that for the conductive layer 328 or a conductive layer 596.

Note that like an insulating layer 592, for example, each of the insulating layer 324 and the insulating layer 350 is preferably formed using an insulator having a barrier property against one or more selected from hydrogen, oxygen, and water. Like an insulating layer 594, each of the insulating layer 326, the insulating layer 352, and the insulating layer 354 is preferably formed using an insulator having a comparatively low relative dielectric constant to reduce parasitic capacitance generated between wirings. Each of the insulating layer 326, the insulating layer 352, and the insulating layer 354 has a function of an interlayer insulating film and a planarization film. Furthermore, the conductive layer 356 preferably includes a conductor having a barrier property against one or more selected from hydrogen, oxygen, and water.

For the conductor having a barrier property against hydrogen, tantalum nitride is used, for example. The use of a stack including tantalum nitride and tungsten that has high conductivity can inhibit diffusion of hydrogen from the transistor 300 while the conductivity of a wiring is kept. In that case, a tantalum nitride layer having a barrier property against hydrogen is preferably in contact with the insulating layer 350 having a barrier property against hydrogen.

An insulating layer 512 is provided over the insulating layer 354 and the conductive layer 356. An insulating layer IS1 is provided over the insulating layer 512. The conductive layer 514 functioning as a plug or a wiring is embedded in the insulating layer IS1 and the insulating layer 512. Thus, one of a source and a drain of the transistor MTCK is electrically connected to the one of the source and the drain of the transistor 300. Note that a material that can be used for the conductive layer MPG can be used for the conductive layer 514, for example.

The transistor MTCK is provided over the insulating layer IS1 and the conductive layer 514. An insulating layer 574 is formed over the transistor MTCK, and an insulating layer 581 is formed over the insulating layer 574. The conductive layer MPG functioning as a plug or a wiring is embedded in an insulating layer IS3, the insulating layer 574, and the insulating layer 581. Embodiment 2 can be referred to for the insulating layer, the conductive layer, and the semiconductor layer around the transistor MTCK.

The insulating layer IS3 is formed above the transistor MTCK. The insulating layer 574 and the insulating layer 581 are provided to be stacked in this order over the insulating layer IS3.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits the entry of the impurities into the transistor MTCK. In addition, it is preferable that the insulating layer 574 have a function of inhibiting diffusion of oxygen (e.g., one or both of an oxygen atom and an oxygen molecule). For example, the insulating layer 574 preferably has lower oxygen permeability than an insulating layer IS2 and the insulating layer IS3.

Thus, the insulating layer 574 preferably functions as a barrier insulating film that inhibits diffusion of impurities such as water and hydrogen. Accordingly, it is preferable to use, for the insulating layer 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulating layer 574. Accordingly, it is possible to inhibit diffusion of impurities such as water and hydrogen into the transistor MTCK from above the insulating layer 574. Alternatively, oxygen contained in the insulating layer IS3 and the like can be inhibited from diffusing above the insulating layer 574.

The insulating layer 581 is preferably a film functioning as an interlayer film and preferably has a lower dielectric constant than the insulating layer 574. When a material having a low dielectric constant is used for an interlayer film, parasitic capacitance generated between wirings can be reduced. For example, the relative dielectric constant of the insulating layer 581 is preferably lower than 4, further preferably lower than 3. The relative dielectric constant of the insulating layer 581 is, for example, preferably 0.7 times or less, further preferably 0.6 times or less the relative dielectric constant of the insulating layer 574. When the insulating layer 581 is an interlayer film formed using a material having a low dielectric constant, the parasitic capacitance generated between wirings can be reduced.

The concentration of impurities such as water and hydrogen in the film of the insulating layer 581 is preferably reduced. In this case, for the insulating layer 581, silicon oxide, silicon oxynitride, silicon nitride oxide, or silicon nitride can be used, for example. For the insulating layer 581, for example, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Moreover, the insulating layer 581 can be formed using a resin. A material that can be used for the insulating layer 581 may be an appropriate combination of the above-described materials.

The insulating layer 592 and the insulating layer 594 are provided to be stacked in this order over the insulating layer 574 and the insulating layer 581.

For the insulating layer 592, it is preferable to use an insulating film having a barrier property (referred to as a barrier insulating film) which prevents diffusion of impurities such as water and hydrogen from the substrate 310 or the transistor MTCK to a region above the insulating layer 592 (e.g., a region where the light-emitting device 130R, the light-emitting device 130G, the light-emitting device 130B, and the like are provided). Accordingly, for the insulating layer 592, it is preferable to use an insulating material that has a function of inhibiting diffusion of impurities such as a hydrogen atom, a hydrogen molecule, and a water molecule (through which the above impurities are unlikely to pass). Furthermore, depending on the situation, for the insulating layer 592, it is preferable to use an insulating material that has a function of inhibiting diffusion of impurities such as a nitrogen atom, a nitrogen molecule, a nitrogen oxide molecule (e.g., N₂0, NO, and NO₂), and a copper atom (through which the above oxygen is unlikely to pass). Alternatively, it is preferable that the insulating layer 592 have a function of inhibiting diffusion of oxygen (e.g., one or both of an oxygen atom and an oxygen molecule).

For the film having a barrier property against hydrogen, for example, silicon nitride formed by a CVD method can be used.

The amount of released hydrogen can be analyzed by thermal desorption spectrometry (TDS), for example. The amount of hydrogen released from the insulating layer 324 that is converted into hydrogen atoms per area of the insulating layer 324 is less than or equal to 10×10¹⁵ atoms/cm², preferably less than or equal to 5×10¹⁵ atoms/cm² in the TDS in a film-surface temperature range of 50° C. to 500° C., for example.

Like the insulating layer 581, the insulating layer 594 is preferably an interlayer film having a low dielectric constant. Thus, for the insulating layer 594, a material that can be used for the insulating layer 581 can be used.

Note that the dielectric constant of the insulating layer 594 is preferably lower than that of the insulating layer 592. For example, the relative dielectric constant of the insulating layer 594 is preferably lower than 4, further preferably lower than 3. The relative dielectric constant of the insulating layer 594 is, for example, preferably 0.7 times or less, further preferably 0.6 times or less the relative dielectric constant of the insulating layer 592. When the insulating layer 594 is an interlayer film formed using a material having a low dielectric constant, the parasitic capacitance generated between wirings can be reduced.

The conductive layer MPG functioning as a plug or a wiring is embedded in an insulating layer GI1 and the insulating layer IS3, and the conductive layer 596 functioning as a plug or a wiring is embedded in the insulating layer 592 and the insulating layer 594. In particular, the conductive layer MPG and the conductive layer 596 are electrically connected to the light-emitting device or the like provided above the insulating layer 594. A plurality of conductive layers each having a function of a plug or a wiring are collectively denoted by the same reference numeral in some cases. In this specification and the like, a wiring and a plug connected to the wiring may be a single component. That is, part of a conductive layer functions as a wiring in some cases and part of a conductive layer functions as a plug in other cases.

As a material of each of plugs and wirings (e.g., the conductive layer MPG and the conductive layer 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulating layer 598 and an insulating layer 599 are formed in this order over the insulating layer 594 and the conductive layer 596.

Like the insulating layer 592, the insulating layer 598 is preferably formed using an insulator having a barrier property against one or more selected from hydrogen, oxygen, and water.

Like the insulating layer 594, the insulating layer 599 is preferably formed using an insulator having a relatively low relative dielectric constant to reduce parasitic capacitance generated between wirings. The insulating layer 599 has functions of an interlayer insulating film and a planarization film.

The light-emitting device 130 and the connection portion 140 are formed over the insulating layer 599.

The connection portion 140 is referred to as a cathode contact portion in some cases, and is electrically connected to cathode electrodes of the light-emitting device 130R, the light-emitting device 130G, and the light-emitting device 130B. The connection portion 140 in FIG. 29 includes one or more conductive layers selected from a conductive layer 182a to a conductive layer 182c to be described later, at least one conductive layer selected from a conductive layer 126a to a conductive layer 126c to be described later, one or more conductive layers selected from a conductive layer 129a to a conductive layer 129c to be described later, a common layer 114 to be described later, and a common electrode 115 to be described later.

Note that the connection portion 140 may be provided to surround four sides of the display portion in the plan view, or may be provided in the display portion (e.g., between adjacent light-emitting devices 130) (not illustrated).

The light-emitting device 130R includes the conductive layer 182a, the conductive layer 126a over the conductive layer 182a, and the conductive layer 129a over the conductive layer 126a. All of the conductive layer 182a, the conductive layer 126a, and the conductive layer 129a can be referred to as pixel electrodes, or one or two of them can be referred to as pixel electrodes. The light-emitting device 130G includes the conductive layer 182b, the conductive layer 126b over the conductive layer 182b, and the conductive layer 129b over the conductive layer 126b. As in the light-emitting device 130R, all of the conductive layer 182b, the conductive layer 126b, and the conductive layer 129b can be referred to as pixel electrodes, or one or two of them can be referred to as pixel electrodes. The light-emitting device 130B includes the conductive layer 182c, the conductive layer 126c over the conductive layer 182c, and the conductive layer 129c over the conductive layer 126c. As in the light-emitting device 130R and the light-emitting device 130G, all of the conductive layer 182c, the conductive layer 126c, and the conductive layer 129c can be referred to as pixel electrodes, or one or two of them can be referred to as pixel electrodes.

As each of the conductive layer 182a to the conductive layer 182c and the conductive layer 126a to the conductive layer 126c, a conductive layer functioning as a reflective electrode can be used, for example. For the conductive layer functioning as a reflective electrode, a conductive layer with high visible-light reflectance such as silver, aluminum, or an alloy film of silver (Ag), palladium (Pd), and copper (Cu) (an Ag—Pd—Cu (APC) film) can be used. The conductive layer 182a to the conductive layer 182c and the conductive layer 126a to the conductive layer 126c can each be a stacked-layer film in which a pair of titanium films sandwich aluminum (a film in which Ti, A1, and Ti are stacked in this order), or a stacked-layer film in which a pair of indium tin oxide films sandwich silver (a film in which ITO, Ag, and ITO are stacked in this order).

For example, a conductive layer functioning as a reflective electrode may be used as each of the conductive layer 182a to the conductive layer 182c, and a material with a high light-transmitting property may be used for each of the conductive layer 126a to the conductive layer 126c. Examples of the material with a high light-transmitting property include an alloy of silver and magnesium and indium tin oxide (sometimes referred to as ITO).

A conductive layer functioning as a transparent electrode can be used as each of the conductive layer 129a to the conductive layer 129c. For the conductive layer functioning as a transparent electrode, for example, the above-described conductive layer with a high light-transmitting property can be used.

A microcavity structure may be provided in the light-emitting device 130 to be described in detail later. The microcavity structure refers to a structure in which the distance between the bottom surface of the light-emitting layer and the top surface of a lower electrode is set to a thickness corresponding to the wavelength of color of light emitted from the light-emitting layer. In that case, a light-transmitting and light-reflective conductive material is preferably used for each of the conductive layer 129a to the conductive layer 129c serving as an upper electrode (a common electrode), and a light-reflective conductive material is preferably used for each of the conductive layer 182a to the conductive layer 182c and the conductive layer 126a to the conductive layer 126c which serve as lower electrodes (pixel electrodes).

The microcavity structure refers to a structure in which the optical distance between the lower electrode and the light-emitting layer is adjusted to be (2n-1)λ/4 (n is a natural number greater than or equal to 1, and 2 is the wavelength of emitted light to be amplified). Thus, light that is reflected back by the lower electrode (reflected light) considerably interferes with light that directly enters the upper electrode from the light-emitting layer (incident light). Accordingly, the phases of the reflected light and the incident light each having the wavelength 2 can be aligned with each other, and the light emitted from the light-emitting layer can be further amplified. Meanwhile, in the case where the reflected light and the incident light each have a wavelength other than the wavelength 2, their phases are not aligned with each other, resulting in attenuation without resonation.

The conductive layer 182a is connected to the conductive layer 596 embedded in the insulating layer 594 through an opening provided in the insulating layer 599. An end portion of the conductive layer 126a is positioned outward from an end portion of the conductive layer 182a. The end portion of the conductive layer 126a and an end portion of the conductive layer 129a are aligned or substantially aligned with each other.

Detailed description of the conductive layer 182b, the conductive layer 126b, and the conductive layer 129b of the light-emitting device 130G and the conductive layer 182c, the conductive layer 126c, and the conductive layer 129c of the light-emitting device 130B is omitted because these conductive layers are similar to the conductive layer 182a, the conductive layer 126a, and the conductive layer 129a of the light-emitting device 130R.

Depressed portions are formed in the conductive layer 182a, the conductive layer 182b, and the conductive layer 182c to cover the openings provided in the insulating layer 599. A layer 128 is embedded in the depressed portions.

The layer 128 has a function of filling the depressed portions of the conductive layer 182a to the conductive layer 182c. The conductive layer 126a to the conductive layer 126c electrically connected to the conductive layer 182a to the conductive layer 182c, respectively, are provided over the conductive layer 182a to the conductive layer 182c and the layer 128. Thus, regions overlapping with the depressed portions of the conductive layer 182a to the conductive layer 182c can also be used as light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching or wet etching on the surfaces of the conductive layer 182a, the conductive layer 182b, and the conductive layer 182c. When the layer 128 is formed using a negative photosensitive resin, the layer 128 can sometimes be formed using the same photomask (light-exposure mask) as the photomask used for forming the opening in the insulating layer 599.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and a side surface of the conductive layer 126a and the top surface and a side surface of the conductive layer 129a. Similarly, the second layer 113b is formed to cover the top surface and a side surface of the conductive layer 126b and the top surface and a side surface of the conductive layer 129b. Similarly, the third layer 113c is formed to cover the top surface and a side surface of the conductive layer 126c and the top surface and a side surface of the conductive layer 129c. Accordingly, regions provided with the conductive layer 126a, the conductive layer 126b, and the conductive layer 126c can be entirely used as light-emitting regions of the light-emitting device 130R, the light-emitting device 130G, and the light-emitting device 130B, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer.

There is no particular limitation on the structure of the light-emitting device in this embodiment, and the light-emitting device can have a single structure or a tandem structure.

Each of the first layer 113a, the second layer 113b, and the third layer 113c is processed into an island shape by a photolithography method. At each of end portions of the first layer 113a, the second layer 113b, and the third layer 113c, the angle formed by the top surface and a side surface is approximately 90°. By contrast, for example, an organic film formed using an FMM tends to have a thickness that gradually decreases with decreasing distance to an end portion, and has a sloped top surface in the range of greater than or equal to 1 μm and less than or equal to 10 μm from the top, for example; thus, such an organic film has a shape whose top surface and side surface cannot be easily distinguished from each other.

The top surface and the side surface of each of the first layer 113a, the second layer 113b, and the third layer 113c are clearly distinguished from each other. Accordingly, as for the first layer 113a and the second layer 113b which are adjacent to each other, one of the side surfaces of the first layer 113a and one of the side surfaces of the second layer 113b are placed to face to each other. This applies to a combination of any of the first layer 113a, the second layer 113b, and the third layer 113c.

The first layer 113a, the second layer 113b, and the third layer 113c each include at least a light-emitting layer. For example, a structure is preferable in which the first layer 113a includes a light-emitting layer that emits red light, the second layer 113b includes a light-emitting layer that emits green light, and the third layer 113c includes a light-emitting layer that emits blue light. Other than the above colors, cyan, magenta, yellow, or white can be employed for the light-emitting layers.

The first layer 113a, the second layer 113b, and the third layer 113c each preferably include a light-emitting layer and a carrier-transport layer (an electron-transport layer or a hole-transport layer) over the light-emitting layer. Since surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. As illustrated in FIG. 29, the common electrode 115 shared by the plurality of light-emitting devices is electrically connected to a conductive layer included in the connection portion 140.

An insulating layer 125 preferably has a function of a barrier insulating layer against one or both of water and oxygen. Alternatively, the insulating layer 125 preferably has a function of inhibiting diffusion of one or both of water and oxygen. Alternatively, the insulating layer 125 preferably has a function of capturing or fixing (also referred to as gettering) one or both of water and oxygen. When the insulating layer 125 has a function of a barrier insulating layer or a gettering function, entry of impurities (typically, one or both of water and oxygen) that would diffuse into the light-emitting devices from the outside can be inhibited. With this structure, a highly reliable light-emitting device and a highly reliable display panel can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against one or both of water and oxygen can be increased. For example, the insulating layer 125 preferably has one of a sufficiently low hydrogen concentration and a sufficiently low carbon concentration, desirably both of them.

As an insulating layer 127, an insulating layer containing an organic material can be suitably used. As the organic material, a photosensitive organic resin is preferably used; for example, a photosensitive resin composite containing an acrylic resin may be used. The viscosity of the material for the insulating layer 127 is greater than or equal to 1 cP and less than or equal to 1500 cP, and is preferably greater than or equal to 1 cP and less than or equal to 12 cP. By setting the viscosity of the material for the insulating layer 127 in the above range, the insulating layer 127 having a tapered shape, which is to be described later, can be formed relatively easily. Note that in this specification and the like, an acrylic resin refers to not only a polymethacrylic acid ester or a methacrylic resin, but also all the acrylic polymer in a broad sense in some cases.

Note that the organic material that can be used for the insulating layer 127 is not limited to the above as long as the insulating layer 127 has a tapered side surface as described later. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, or precursors of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulating layer 127 in some cases. For the insulating layer 127, for example, a photoresist can be used as the photosensitive resin in some cases. Note that as the photosensitive resin, a positive material or a negative material can be used.

The insulating layer 127 may be formed using a material absorbing visible light. When the insulating layer 127 absorbs light emitted from the light-emitting device, leakage of light (stray light) from the light-emitting device to the adjacent light-emitting device through the insulating layer 127 can be inhibited. Thus, the display quality of the display panel can be improved. Since the display quality of the display panel can be improved without using a polarizing plate, the weight and thickness of the display panel can be reduced.

Examples of the material absorbing visible light include materials containing pigment of black or the like, materials containing dye, light-absorbing resin materials (e.g., polyimide), and resin materials that can be used for color filters (color filter materials). Using the resin material obtained by stacking or mixing color filter materials of two or three or more colors is particularly preferable, in which case the effect of blocking visible light is enhanced. In particular, mixing color filter materials of three or more colors enables the formation of a black or nearly black resin layer.

For example, the insulating layer 127 can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 127 is preferably formed by spin coating.

The insulating layer 127 is formed at a temperature lower than the upper temperature limit of the EL layer. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulating layer 127 or the like using the structure of the insulating layer 127 between the light-emitting device 130R and the light-emitting device 130G as an example. Note that the same can apply to the insulating layer 127 between the light-emitting device 130G and the light-emitting device 130B, the insulating layer 127 between the light-emitting device 130B and the light-emitting device 130R, and the like. In the description below, an end portion of the insulating layer 127 over the second layer 113b is used as an example in some cases, and the same can apply to an end portion of the insulating layer 127 over the first layer 113a and an end portion of the insulating layer 127 over the third layer 113c.

The insulating layer 127 preferably has the tapered side surface with a taper angle θ1 in the cross-sectional view of the display apparatus. The taper angle θ1 is the angle formed by the side surface of the insulating layer 127 and the substrate surface. Note that the taper angle θ1 is not limited to the angle with the substrate surface, and may be the angle formed by the side surface of the insulating layer 127 and the top surface of the flat portion of the insulating layer 125 or the top surface of the flat portion of the second layer 113b. When the side surface of the insulating layer 127 has a tapered shape, a side surface of the insulating layer 125 and a side surface of a mask layer 118a also have a tapered shape in some cases.

The taper angle θ1 of the insulating layer 127 is less than 90°, preferably less than or equal to 60°, further preferably less than or equal to 45°. Such a forward tapered shape of an end portion of the side surface of the insulating layer 127 can prevent disconnection, local thinning, or the like from occurring in the common layer 114 and the common electrode 115 which are provided over the end portion of the side surface of the insulating layer 127, leading to film formation with good coverage. Accordingly, the in-plane uniformity of the common layer 114 and the common electrode 115 can be improved, leading to higher display quality of the display apparatus.

The top surface of the insulating layer 127 preferably has a convex curved shape in the cross-sectional view of the display apparatus. The convex curved shape of the top surface of the insulating layer 127 is preferably a shape gently bulged toward the center. The insulating layer 127 preferably has a shape such that the convex curved surface portion at the center portion of the top surface is connected smoothly to the tapered portion of the end portion of the side surface. When the insulating layer 127 has such a shape, the common layer 114 and the common electrode 115 can be formed with good coverage over the entire insulating layer 127.

The insulating layer 127 is formed in a region between two EL layers (e.g., a region between the first layer 113a and the second layer 113b). At this time, part of the insulating layer 127 is placed at a position sandwiched between an end portion of the side surface of one of the EL layers (e.g., the first layer 113a) and an end portion of the side surface of the other of the EL layers (e.g., the second layer 113b).

One end portion of the insulating layer 127 preferably overlaps with the conductive layer 126a functioning as a pixel electrode, and the other end portion of the insulating layer 127 preferably overlaps with the conductive layer 126b functioning as a pixel electrode. With such a structure, the end portions of the insulating layer 127 can be formed over a substantially flat region of the first layer 113a (the second layer 113b). This makes it relatively easy to process the tapered shape of the insulating layer 127 as described above.

By providing the insulating layer 127 and the like as described above, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where the distance between two adjacent island-shaped EL layers is less than or equal to 1 μm, preferably less than or equal to 0.5 μm (500 nm), further preferably less than or equal to 100 nm. The distance between the light-emitting devices is shortened in this manner, whereby a display apparatus with high resolution and a high aperture ratio can be provided.

A protective layer 131 is provided over the light-emitting devices 130. The protective layer 131 is a film functioning as a passivation film for protecting the light-emitting devices 130. Provision of the protective layer 131 covering the light-emitting devices can inhibit impurities such as water and oxygen from entering the light-emitting devices, and increase the reliability of the light-emitting devices 130. For the protective layer 131, aluminum oxide, silicon nitride, or silicon nitride oxide can be used, for example.

The protective layer 131 and a substrate 119 are bonded to each other with an adhesive layer 107. A solid sealing structure, a hollow sealing structure, or the like can be employed to seal the light-emitting devices. In FIG. 29, a solid sealing structure is employed, in which a space between the substrate 310 and the substrate 119 is filled with the adhesive layer 107. Alternatively, a hollow sealing structure may be employed, in which the space is filled with an inert gas (e.g., nitrogen or argon). Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet may be used.

The display apparatus 50B has a top-emission structure. Light from the light-emitting devices is emitted toward the substrate 119 side. Thus, for the substrate 119, a material having a high visible-light-transmitting property is preferably used. For example, among substrates usable as the substrate 310, a substrate having a high visible-light-transmitting property may be selected as the substrate 119. The pixel electrode contains a material that reflects visible light, and a counter electrode (the common electrode 115) contains a material that transmits visible light.

Note that the display apparatus of one embodiment of the present invention may be not a top-emission display apparatus but a bottom-emission display apparatus where light from the light-emitting devices is emitted to the substrate 310 side. In that case, a substrate having a high visible-light-transmitting property is selected as the substrate 310.

When one of the above-described structure examples is applied to a display apparatus, the display apparatus having high definition and high resolution can be achieved in some cases. Specifically, for example, a display apparatus with a definition of HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320) can be achieved in some cases. Furthermore, specifically, for example, a display apparatus with a resolution of greater than or equal to 100 ppi, greater than or equal to 300 ppi, greater than or equal to 500 ppi, greater than or equal to 1000 ppi, greater than or equal to 2000 ppi, greater than or equal to 3000 ppi, greater than or equal to 5000 ppi, or greater than or equal to 6000 ppi can be achieved in some cases.

Note that this embodiment can be combined with the same embodiment or any of the other embodiments described in this specification as appropriate. For example, the configurations, structures, methods, and the like described in this embodiment can be used in an appropriate combination with any of the configurations, structures, methods, and the like described in the embodiment. For example, the configurations, structures, methods, and the like described in this embodiment can be used in an appropriate combination with any of the configurations, structures, methods, and the like described in the other embodiments and the like.

At least part of the structure examples, the drawings corresponding thereto, and the like described as examples in this embodiment can be combined with the other structure examples, the other drawings, and the like as appropriate.

### Embodiment 5

In this embodiment, an electronic device, a display apparatus, and the like of one embodiment of the present invention will be described. For example, one embodiment of the present invention can be suitably used for a wearable electronic device for VR or AR applications.

### <Structure Example of Electronic Device>

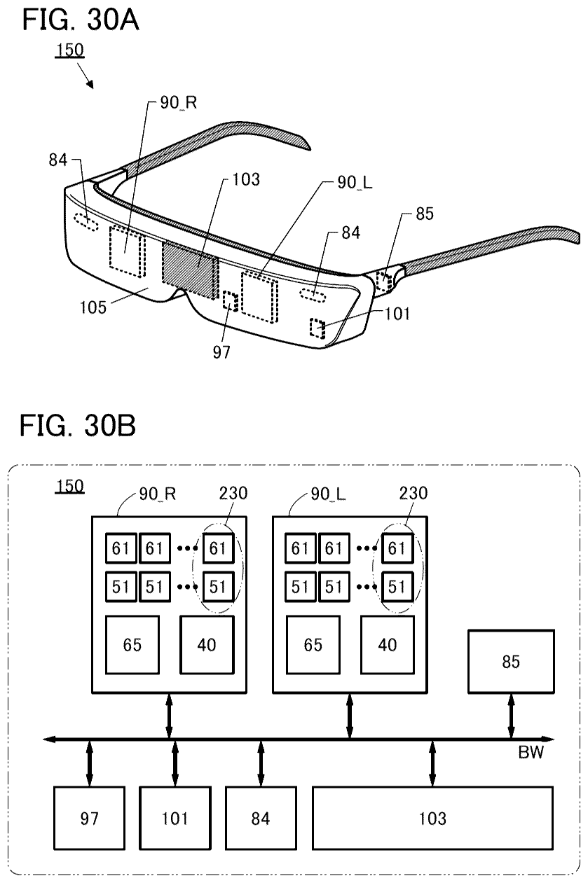

FIG. 30A illustrates a perspective view of a glasses-type electronic device 150 as an example of a wearable electronic device. FIG. 30A illustrates the electronic device 150 that includes, in a housing 105, a pair of display apparatuses 90 (a display apparatus 90_L and a display apparatus 90_R), a motion detection portion 101, gaze detection portions 84, an arithmetic portion 103, and a communication portion 85.

FIG. 30B is a block diagram of the electronic device 150 in FIG. 30A. As in FIG. 30A, the electronic device 150 includes the display apparatus 90_L, the display apparatus 90_R, the motion detection portion 101, the gaze detection portions 84, the arithmetic portion 103, and the communication portion 85, and a variety of signals are transmitted and received between these components through a bus wiring BW. Each of the display apparatus 90_L and the display apparatus 90_R includes a plurality of pixels 230, a driver circuit 65, and a functional circuit 40.

One pixel 230 includes one light-emitting device 61 and one pixel circuit 51. Thus, each of the display apparatus 90_L and the display apparatus 90_R includes a plurality of light-emitting devices 61 and a plurality of pixel circuits 51.

The motion detection portion 101 has a function of detecting the motion of the housing 105, i.e., the motion of the head of the user who wears the electronic device 150. The motion detection portion 101 can include a motion sensor using a MEMS technology, for example. As the motion sensor, a three-axis motion sensor, a six-axis motion sensor, or the like can be used. Information on the motion of the housing 105 detected by the motion detection portion 101 may be referred to as first information, motion information, or the like.

The gaze detection portion 84 has a function of obtaining information regarding the user's gaze. Specifically, the gaze detection portion 84 has a function of detecting the user's gaze. The user's gaze, for example, is obtained by a gaze measurement (eye tracking) method such as a pupil center corneal reflection method or a bright/dark pupil effect method. Alternatively, the user's gaze may be obtained by a gaze measurement method using a laser, an ultrasonic wave, or the like.

The arithmetic portion 103 has a function of calculating the user's gaze point by using a gaze detection result in the gaze detection portion 84. That is, an object the user is gazing in the image being displayed on the display apparatus 90_L and the display apparatus 90_R can be found. In addition, whether or not the user is gazing at a part other than the screen can be found. Note that information regarding the user's gaze obtained by the gaze detection portion 84 (the gaze detection result) is referred to as second information, gaze information, or the like in some cases.

The arithmetic portion 103 has a function of performing drawing processing (arithmetic process of image data) in accordance with the motion of the housing 105. The arithmetic portion 103 performs the drawing processing in accordance with the motion of the housing 105 with the use of the first information and image data that is input from the outside through the communication portion 85. As the image data, for example, a 360-degree omnidirectional image data can be used. The 360-degree omnidirectional image data is image data captured by a celestial sphere camera (an omnidirectional camera or a 360° camera) or image data generated by computer graphics or the like, for example. The arithmetic portion 103 has a function of converting the 360-degree omnidirectional image data on the basis of the first information into image data that can be displayed on the display apparatus 90_L and the display apparatus 90_R.

The arithmetic portion 103 has a function of determining the size and shape of a plurality of regions that are set for each of the display portions of the display apparatus 90_L and the display apparatus 90_R with use of the second information. Specifically, the arithmetic portion 103 calculates a gaze point on the display portion on the basis of the second information and sets a first region S1 to a third region S3 and the like described later on the display portion with use of the gaze point as a reference.

A microprocessor such as a central processing unit (CPU), a DSP (Digital Signal Processor), or a GPU (Graphics Processing Unit) can be used alone or in combination as the arithmetic portion 103. A structure may be employed in which such a microprocessor is obtained with a PLD (Programmable Logic Device) such as an FPGA (Field Programmable Gate Array) or an FPAA (Field Programmable Analog Array).

The arithmetic portion 103 interprets and executes instructions from various programs with the use of a processor to perform various kinds of data processing and program control. The programs that might be executed by the processor may be stored in a memory region included in the processor or a memory portion which is additionally provided. As the memory portion, a memory device using a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device using a volatile memory element, such as a DRAM (Dynamic RAM) or an SRAM (Static RAM); or the like may be used, for example.

The communication portion 85 has a function of communicating with an external device by wire or wirelessly to obtain a variety of data, including image data. The communication portion 85 is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), or WCDMA (Wideband Code Division Multiple Access: registered trademark), or a communication standard developed by IEEE such as Wi-Fi (registered trademark), Bluetooth (registered trademark), or ZigBee (registered trademark). The third-generation mobile communication system (3G), the fourth-generation mobile communication system (4G), the fifth-generation mobile communication system (5G), or the like defined by the International Telecommunication Union (ITU) can also be used.

The communication portion 85 may include an external port such as a LAN (Local Area Network) connection terminal, a digital broadcast-receiving terminal, or an AC adaptor connection terminal.

Each of the display apparatus 90_L and the display apparatus 90_R includes the plurality of light-emitting devices 61, the plurality of pixel circuits 51, the driver circuit 65, and the functional circuit 40. The pixel circuit 51 has a function of controlling light emission of the light-emitting device 61. The driver circuit 65 has a function of controlling the pixel circuit 51.

Information on the plurality of regions in the display portion of the display apparatus determined by the arithmetic portion 103 can be used for driving such that the definition differs from region to region. The functional circuit 40 has a function of controlling the driver circuit 65 such that the display definition is high in a region close to a gaze point and controlling the driver circuit 65 such that the display definition is low in a region distant from the gaze point.

For example, when rewriting of image data is performed for every other pixel or every other plurality of pixels, display with low definition can be achieved. By reducing the number of pixels that perform rewriting of image data, power consumption of the display apparatus can be reduced.

The electronic device 150 may be provided with a sensor 97. The sensor 97 has a function of obtaining information on one or more of the senses of sight, hearing, touch, taste, and smell of the user. Specifically, the sensor 97 has a function of sensing or measuring one or more of the following information: force, displacement, position, speed, acceleration, angular velocity, rotational frequency, distance, light, magnetism, temperature, sound, time, electric field, current, voltage, power, radiation, humidity, gradient, oscillation, smell, and infrared rays. The electronic device 150 may be provided with one or more sensors 97.

With use of the sensor 97, ambient temperature, humidity, illumination, odor, and the like may be measured. Furthermore, with use of the sensor 97, information for personal authentication using a fingerprint, a palm print, an iris, a retina, a shape of a blood vessel (including a shape of a vein and a shape of an artery), a face, or the like may be obtained, for example. Moreover, with use of the sensor 97, the number of blinks, eyelid behavior, pupil size, body temperature, pulse, oxygen saturation in blood, or the like of the user may be measured, so that the user's fatigue level, health condition, and the like can be detected. The electronic device 150 may sense the user's fatigue level, health condition, and the like and display an alert or the like on the display apparatus 90.

The operation of the electronic device 150 may be controlled by detecting the user's gaze and eyelid movement. Since the user does not need to touch and operate the electronic device 150, an input operation or the like can be achieved with holding nothing in both hands (in a state where both hands are free).

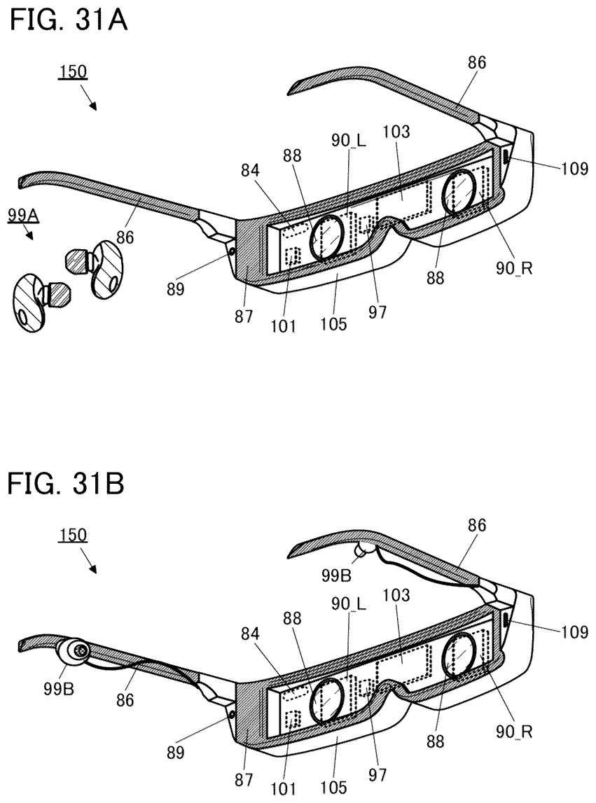

FIG. 31A is a perspective view illustrating the electronic device 150. In FIG. 31A, the housing 105 of the electronic device 150 includes, for example, a wearing portion 86, a cushion 87, a pair of lenses 88, and the like, in addition to the pair of the display apparatus 90_L, the display apparatus 90_R, and the arithmetic portion 103. The pair of the display apparatus 90_L and the display apparatus 90_R are positioned inside the housing 105 so as to be seen through the lenses 88.

An input terminal 109 and an output terminal 89 are provided in the housing 105 illustrated in FIG. 31A. To the input terminal 109, a cable for supplying an image signal (image data) from a video output device or the like, power for charging a battery (not illustrated) provided in the housing 105, or the like can be connected. The output terminal 89 can function as, for example, an audio output terminal to which earphones, headphones, or the like can be connected.

The housing 105 preferably includes a mechanism by which the left and right positions of the lenses 88, the display apparatus 90_L, and the display apparatus 90_R can be adjusted to the optimal positions in accordance with the positions of the user's eyes. Moreover, the housing 105 preferably includes a mechanism for adjusting focus by changing the distance between the lenses 88 and each of the display apparatus 90_L and the display apparatus 90_R.

The cushion 87 is a portion to be in contact with the user's face (forehead, cheek, or the like). When the cushion 87 is in close contact with the user's face, external light incidence (light leakage) can be prevented, which increases the sense of immersion. A soft material is preferably used for the cushion 87 so that the cushion 87 is in close contact with the user's face when the user wears the electronic device 150. Using such a material is preferable because it provides a soft texture and the user does not feel cold when wearing the electronic device in a cold season, for example. The member to be in contact with the user's skin, such as the cushion 87 or the wearing portion 86, is preferably detachable, in which case cleaning or replacement can be easily performed.

The electronic device of one embodiment of the present invention may further include earphones 99A. The earphones 99A include a communication portion (not illustrated) and have a wireless communication function. The earphones 99A can output audio data with the wireless communication function. The earphones 99A may include a vibration mechanism to function as bone-conduction earphones.

The earphones 99A can be connected to the wearing portion 86 directly or by wire like earphones 99B illustrated in FIG. 31B. The earphones 99B and the wearing portion 86 may each have a magnet. This is preferable because the earphones 99B can be fixed to the wearing portion 86 with magnetic force and thus can be easily housed.

### <Structure Example of Display Apparatus>

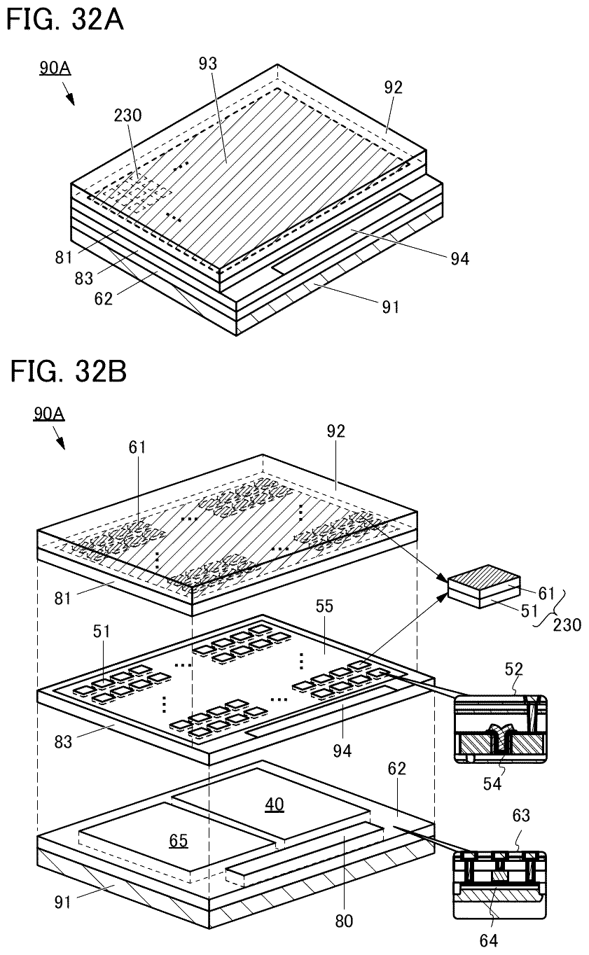

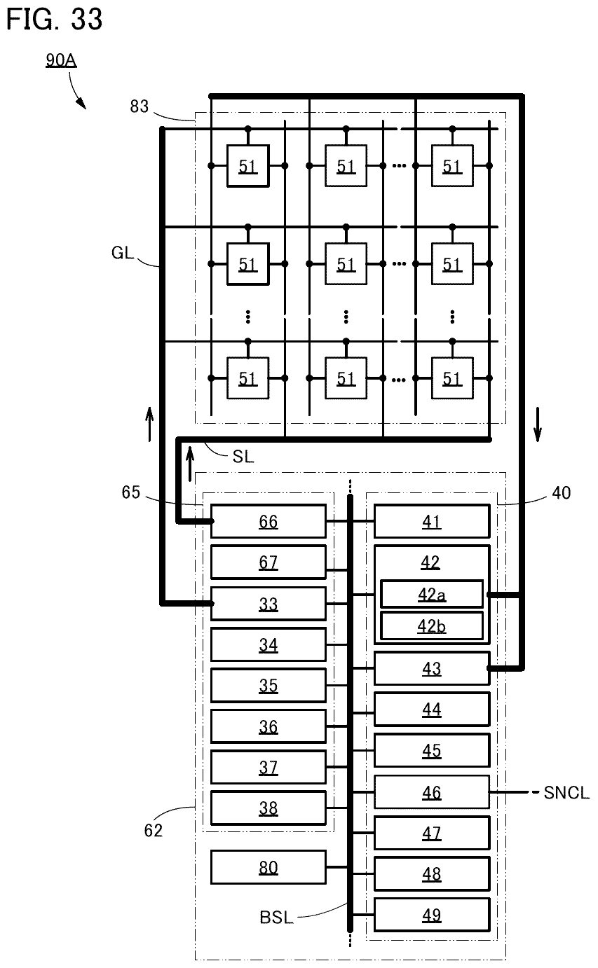

A structure of a display apparatus 90A that can be used as the display apparatus 90_L and the display apparatus 90_R illustrated in FIG. 30A and FIG. 30B will be described with reference to FIG. 32A, FIG. 32B, and FIG. 33.

FIG. 32A is a perspective view of a display apparatus 90A that can be used as the display apparatus 90_L and the display apparatus 90_R illustrated in FIG. 30A and FIG. 30B.

The display apparatus 90A includes a substrate 91 and a substrate 92. The display apparatus 90A includes a display portion 93 provided between the substrate 91 and the substrate 92. The display portion 93 includes the plurality of pixels 230. The pixel 230 includes the pixel circuit 51 and the light-emitting device 61. The display portion 93 is a region where an image is displayed in the display apparatus 90A.

By using the pixels 230 arranged in a matrix of 1920×1080 pixels, the display portion 93 can achieve display with a definition of a so-called full hi-vision (also referred to as “2K definition”, “2K1K”, “2K”, or the like). For example, by using the pixels 230 arranged in a matrix of 3840×2160 pixels, the display portion 93 can achieve display with a definition of a so-called ultra hi-vision (also referred to as “4K definition”, “4K2K”, “4K”, or the like). For example, by using the pixels 230 arranged in a matrix of 7680×4320 pixels, the display portion 93 can achieve display with a definition of a so-called super hi-vision (also referred to as “8K definition”, “8K4K”, “8K”, or the like). By increasing the number of pixels 230, the display portion 93 that can perform display with 16K or 32K definition can also be obtained.

The pixel density (resolution) of the display portion 93 is preferably higher than or equal to 1000 ppi and lower than or equal to 10000 ppi. For example, the resolution may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 93. For example, the display portion 93 is compatible with a variety of screen ratios such as 1:1 (a square), 4:3, 16:9, and 16:10.

In this specification and the like, the term “element” can be replaced with the term “device” in some cases. For example, a display element, a light-emitting element, and a liquid crystal element can be rephrased as a display device, a light-emitting device, and a liquid crystal device, respectively.

Various kinds of signals and power supply potentials are input to the display apparatus 90A from the outside via a terminal portion 94, so that image display can be performed using a display element provided in the display portion 93. Any of a variety of elements can be used as the display element. Typically, a light-emitting device having a function of emitting light, such as an organic EL element (an OLED element) or an LED element, a liquid crystal element, a MEMS element, or the like can be used.

A plurality of layers are provided between the substrate 91 and the substrate 92, and each of the layers is provided with a transistor for a circuit operation, or a display element which emits light. A pixel circuit having a function of controlling an operation of the display element, a driver circuit having a function of controlling the pixel circuit, a functional circuit having a function of controlling the driver circuit, and the like are provided in the plurality of layers.

FIG. 32B is a perspective view schematically illustrating the structures of the layers provided between the substrate 91 and the substrate 92.

A layer 62 is provided over the substrate 91. The layer 62 includes the driver circuit 65, the functional circuit 40, and an input/output circuit 80. The layer 62 includes a transistor 63 containing silicon in a channel formation region 64 (such a transistor is also referred to as a Si transistor). As the substrate 91, a silicon substrate can be used, for example. A silicon substrate is preferable because it has higher thermal conductivity than a glass substrate. By providing the driver circuit 65, the functional circuit 40, and the input/output circuit 80 in the same layer, wirings electrically connecting the driver circuit 65, the functional circuit 40, and the input/output circuit 80 can be short. As a result, charge and discharge time of a control signal used when the functional circuit 40 controls the driver circuit 65 becomes short, leading to a reduction in power consumption. In addition, charge and discharge time during which a signal is supplied from the input/output circuit 80 to the functional circuit 40 and the driver circuit 65 becomes short, leading to a reduction in power consumption.

The transistor 63 can be, for example, a transistor containing single crystal silicon in its channel formation region (such a transistor is also referred to as a “c-Si transistor”). In particular, the use of a transistor containing single crystal silicon in a channel formation region as the transistor provided in the layer 62 can increase the on-state current of the transistor. This enables high-speed driving of circuits included in the layer 62 and is thus preferable. The Si transistor can be formed by microfabrication to have a channel length greater than or equal to 3 nm and less than or equal to 10 nm, for example; thus, a CPU, an accelerator such as a GPU, an application processor, or the like can be integral with the display portion in the display apparatus 90A.

A transistor containing polycrystalline silicon in its channel formation region (also referred to as a “Poly-Si transistor”) may be provided in the layer 62. As the polycrystalline silicon, LTPS may be used. Note that a transistor containing LTPS in its channel formation region is also referred to as an “LTPS transistor”. An OS transistor may be provided in the layer 62 as necessary.

Any of a variety of circuits such as a shift register, a level shifter, an inverter, a latch, an analog switch, and a logic circuit can be used as the driver circuit 65. The driver circuit 65 includes a gate driver circuit, a source driver circuit, or the like, for example. In addition, an arithmetic circuit, a memory circuit, a power supply circuit, and the like may be included. Since the gate driver circuit, the source driver circuit, and other circuits can be placed to overlap with the display portion 93, the width of a non-display region (also referred to as a bezel) provided along the outer periphery of the display portion 93 of the display apparatus 90A can be extremely narrow compared with the case where these circuits and the display portion 93 are arranged side by side, whereby the display apparatus 90A can be reduced in size.

The functional circuit 40 has a function of an application processor for controlling the circuits in the display apparatus 90A and generating signals used for controlling the circuits, for example. The functional circuit 40 may include a circuit used for correcting image data of a CPU, an accelerator such as a GPU, and the like. The functional circuit 40 may include an LVDS (Low Voltage Differential Signaling) circuit, an MIPI (Mobile Industry Processor Interface) circuit, and a D/A (Digital to Analog) converter circuit, for example, having a function of an interface for receiving image data or the like from the outside of the display apparatus 90A. The functional circuit 40 may include a circuit for compressing and decompressing image data and a power supply circuit, for example.

A layer 83 is provided over the layer 62. The layer 83 includes a pixel circuit group 55 including the plurality of pixel circuits 51. An OS transistor may be provided in the layer 83. Each of the pixel circuits 51 may include an OS transistor. Note that the layer 83 can be stacked over the layer 62.

A Si transistor may be provided in the layer 83. For example, the pixel circuits 51 may each include a transistor containing single crystal silicon or polycrystalline silicon in its channel formation region. As the polycrystalline silicon, LTPS may be used. For example, the layer 83 can be formed over another substrate and bonded to the layer 62.

As another example, the pixel circuits 51 may each include a plurality of kinds of transistors using different semiconductor materials. In the case where the pixel circuits 51 each include a plurality of kinds of transistors using different semiconductor materials, different kinds of transistors may be provided in different layers. For example, in the case where the pixel circuits 51 each include a Si transistor and an OS transistor, the Si transistor and the OS transistor may be provided to overlap with each other. Providing the transistors to overlap with each other reduces the area occupied by the pixel circuits 51. Thus, the resolution of the display apparatus 90A can be improved. Note that a structure in which an LTPS transistor and an OS transistor are combined is referred to as LTPO in some cases.

It is preferable to use, as the transistor 52 that is an OS transistor, a transistor including an oxide containing at least one of indium, an element M (the element M is aluminum, gallium, yttrium, or tin), and zinc in a channel formation region 54. Such an OS transistor has a characteristic of an extremely low off-state current. Thus, it is particularly preferable to use the OS transistor as a transistor provided in the pixel circuit, in which case analog data written to the pixel circuit can be retained for a long period.

A layer 81 is provided over the layer 83. Over the layer 81, the substrate 92 is provided. The substrate 92 is preferably a light-transmitting substrate or a layer formed of a light-transmitting material. The layer 81 includes the plurality of light-emitting devices 61. The layer 81 can be stacked over the layer 83. As the light-emitting device 61, an organic electroluminescent element (also referred to as an organic EL element) or the like can be used, for example. However, the light-emitting device 61 is not limited thereto, and an inorganic EL element formed of an inorganic material may be used, for example. Note that an “organic EL element” and an “inorganic EL element” are collectively referred to as “EL element” in some cases. The light-emitting device 61 may contain an inorganic compound such as quantum dots. For example, when used for a light-emitting layer, the quantum dots can function as a light-emitting material.

As illustrated in FIG. 32B, the display apparatus 90A of one embodiment of the present invention can have a structure in which the light-emitting devices 61, the pixel circuits 51, the driver circuit 65, and the functional circuit 40 are stacked; thus, the aperture ratio (effective display area ratio) of the pixels can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits 51 can be arranged extremely densely, and thus the resolution of the pixels can be extremely high. For example, the pixels can be arranged in the display portion 93 of the display apparatus 90A (a region where the pixel circuits 51 and the light-emitting devices 61 are stacked) with a resolution of higher than or equal to 2000 ppi and lower than or equal to 3000 ppi, higher than or equal to 3000 ppi and lower than or equal to 20000 ppi, higher than or equal to 5000 ppi and lower than or equal to 20000 ppi, or higher than or equal to 6000 ppi and lower than or equal to 20000 ppi.

The display apparatus 90A described above has an extremely high resolution, and thus can be suitably used for a device for VR such as a head-mounted display or a glasses-type device for AR. For example, even in the case of a structure in which the display portion of the display apparatus 90A is seen through an optical member such as a lens, pixels of the extremely-high-resolution display portion included in the display apparatus 90A are not seen when the display portion is magnified by the lens, so that display providing a high sense of immersion can be performed.

Note that in the case where the display apparatus 90A is used as a wearable display apparatus for VR or AR, the display portion 93 can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 93 may have a diagonal size of 1.5 inches or approximately 1.5 inches. When the display portion 93 has a diagonal size less than or equal to 2.0 inches, the number of times of light exposure treatment using a light-exposure apparatus (typically, a scanner apparatus) can be one; thus, the productivity of a manufacturing process can be improved.

The display apparatus 90A of one embodiment of the present invention can be used for an electronic device other than a wearable electronic device. In that case, the display portion 93 can have a diagonal size greater than 2.0 inches. The structure of transistors used in the pixel circuits 51 may be selected as appropriate depending on the diagonal size of the display portion 93. In the case where a single crystal Si transistors are used in the pixel circuits 51, for example, the diagonal size of the display portion 93 is preferably greater than or equal to 0.1 inches and less than or equal to 3 inches. In the case where LTPS transistors are used in the pixel circuits 51, the diagonal size of the display portion 93 is preferably greater than or equal to 0.1 inches and less than or equal to 30 inches, further preferably greater than or equal to 1 inch and less than or equal to 30 inches. In the case where LTPO is employed in the pixel circuit 51, the diagonal size of the display portion 93 is preferably greater than or equal to 0.1 inches and less than or equal to 50 inches, further preferably greater than or equal to 1 inch and less than or equal to 50 inches. In the case where OS transistors are used in the pixel circuits 51, the diagonal size of the display portion 93 is preferably greater than or equal to 0.1 inches and less than or equal to 200 inches, further preferably greater than or equal to 50 inches and less than or equal to 100 inches.

It is extremely difficult to make the size of a display apparatus including a single crystal Si transistor in the pixel circuit 51 or the like larger than that of a single crystal Si substrate. Furthermore, for the display apparatus including an LTPS transistor in the pixel circuit 51 or the like, a laser crystallization apparatus is used in the manufacturing process; thus, the display apparatus is unlikely to respond to a size increase (typically to a screen diagonal size greater than 30 inches). By contrast, since the manufacturing process does not necessarily require a laser crystallization apparatus or the like or can be performed at a relatively low process temperature (typically, lower than or equal to 450° C.), OS transistors can be used for a display apparatus with a relatively large area (typically, a diagonal size greater than or equal to 50 inches and less than or equal to 100 inches). In addition, LTPO is applicable to a diagonal size of a display portion between the case of using LTPS transistors and the case of using OS transistors (typically, greater than or equal to 1 inch and less than or equal to 50 inches).

Specific structure examples of the driver circuit 65 and the functional circuit 40 are described with reference to FIG. 33. FIG. 33 is a block diagram of the structure of the display apparatus 90A, illustrating a plurality of wirings connecting the pixel circuit 51, the driver circuit 65, and the functional circuit 40, a bus wiring in the display apparatus 90A, and the like.

In the display apparatus 90A illustrated in FIG. 33, the plurality of pixel circuits 51 are arranged in a matrix in the layer 83.

The driver circuit 65, the functional circuit 40, and the input/output circuit 80 are provided in the layer 62 in the display apparatus 90A illustrated in FIG. 33. The driver circuit 65 includes, for example, a source driver circuit 66, a digital-analog converter (DAC) circuit 67, a gate driver circuit 33, a level shifter 34, an amplifier circuit 35, an inspection circuit 36, a video generation circuit 37, and a video distribution circuit 38. The functional circuit 40 includes, for example, a memory device 41, a GPU (AI accelerator) 42, an EL correction circuit 43, a timing controller 44, a CPU 45, a sensor controller 46, a power supply circuit 47, a temperature sensor 48, and a luminance correction circuit 49. The functional circuit 40 has a function of an application processor.

The input/output circuit 80 is compatible with a transmission method such as LVDS, and the input/output circuit 80 has a function of distributing control signals, image data, and the like input via the terminal portion 94 to the driver circuit 65 and the functional circuit 40. Furthermore, the input/output circuit 80 has a function of outputting information of the display apparatus 90A to the outside via the terminal portion 94.

The display apparatus 90A in FIG. 33 illustrates an example of a structure in which the circuits included in the driver circuit 65, the circuits included in the functional circuit 40, and the input/output circuit 80 are each electrically connected to a bus wiring BSL.

The source driver circuit 66 has a function of transmitting image data to the pixel circuits 51 included in the pixels 230, for example. Thus, the source driver circuit 66 is electrically connected to the pixel circuits 51 through the wiring SL. Note that a plurality of source driver circuits 66 may be provided.

The digital-analog converter circuit 67 has a function of converting image data that has been digitally processed by a GPU, a correction circuit, or the like described later, into analog data, for example. The image data converted into analog data is amplified by the amplifier circuit 35 such as an operational amplifier and is transmitted to the pixel circuits 51 via the source driver circuit 66. Note that the image data may be transmitted to the source driver circuit 66, the digital-analog converter circuit 67, and the pixel circuits 51 in this order. The digital-analog converter circuit 67 and the amplifier circuit 35 may be included in the source driver circuit 66.

The gate driver circuit 33 has a function of selecting the pixel circuit to which image data is to be transmitted among the pixel circuits 51, for example. Thus, the gate driver circuit 33 is electrically connected to the pixel circuits 51 through the wiring GL. Note that a plurality of gate driver circuits 33 may be provided such that the number of the gate driver circuits 33 corresponds to the number of the source driver circuits 66.

The level shifter 34 has a function of converting signals to be input to the source driver circuit 66, the digital-analog converter circuit 67, the gate driver circuit 33, and the like into signals with appropriate levels, for example.

The memory device 41 has a function of storing image data to be displayed by the pixel circuits 51, for example. Note that the memory device 41 can be configured to store the image data as digital data or analog data.

In the case where the memory device 41 stores image data, the memory device 41 is preferably a nonvolatile memory. In that case, a NAND memory or the like can be used as the memory device 41, for example.

In the case where the memory device 41 stores temporary data generated in the GPU 42, the EL correction circuit 43, the CPU 45, or the like, the memory device 41 is preferably a volatile memory. In that case, an SRAM, a DRAM, or the like can be used as the memory device 41, for example.

The GPU 42 has a function of performing processing for outputting, to the pixel circuits 51, image data read from the memory device 41, for example. Specifically, the GPU 42 is configured to perform pipeline processing in parallel and thus can perform high-speed processing of image data to be output to the pixel circuits 51. The GPU 42 can also have a function of a decoder for decoding an encoded image.

The functional circuit 40 may include a plurality of circuits that can improve the display quality of the display apparatus 90A. As such circuits, for example, correction (toning and dimming) circuits that detect color irregularity of a displayed image and correct the color irregularity to obtain an optimal image may be provided. In the case where a light-emitting device utilizing organic EL is used as the display element, for example, an EL correction circuit that corrects image data in accordance with the properties of the light-emitting device may be provided in the functional circuit 40. The functional circuit 40 includes, for example, the EL correction circuit 43.

The above-described image correction may be performed using artificial intelligence. For example, current flowing in a pixel circuit (or a voltage applied to the pixel circuit) may be monitored and obtained, a displayed image may be obtained with an image sensor or the like, the current (or voltage) and the image may be used as input data in an arithmetic operation of the artificial intelligence (e.g., an artificial neural network), and the output result may be used to judge whether the image should be corrected.

Such an arithmetic operation of artificial intelligence can be applied to not only image correction but also upconversion processing for increasing the definition of image data. As an example, FIG. 33 illustrates the GPU 42 that includes blocks for performing arithmetic operations for various kinds of correction (e.g., color irregularity correction 42a and upconversion 42b).

The upconversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+method, an SRCNN (Super-Resolution Convolutional Neural Network) method, and the like.

The algorithm used for the upconversion processing may be different for each region determined in accordance with a gaze point. For example, upconversion processing for a region including the gaze point and the vicinity of the gaze point is performed using an algorithm with a low processing speed but high accuracy, and upconversion processing for a region other than the above region is performed using an algorithm with low accuracy but a high processing speed. In that case, the time required for upconversion processing can be shortened. In addition, power consumption required for upconversion processing can be reduced.

Without limitation to upconversion processing, downconversion processing for decreasing the definition of image data may be performed. In the case where the definition of image data is higher than the definition of the display portion 93, part of the image data is not displayed on the display portion 93, in some cases. In that case, downconversion processing enables the entire image data to be displayed on the display portion 93.

The timing controller 44 has a function of controlling driving frequency (e.g., a frame frequency, a frame rate, or a refresh rate) for displaying an image, for example. In the case where a still image is displayed on the display apparatus 90A, for example, the driving frequency is lowered by the timing controller 44, so that power consumption of the display apparatus 90A can be reduced.

The CPU 45 has a function of performing general-purpose processing such as execution of an operating system, control of data, and execution of various kinds of arithmetic operations and programs, for example. The CPU 45 has a role in, for example, giving an instruction for a writing operation or a reading operation of image data in the memory device 41, an operation for correcting image data, an operation for a later-described sensor, or the like. Furthermore, the CPU 45 may have a function of transmitting a control signal to at least one of the circuits included in the functional circuit 40, for example.

The sensor controller 46 has a function of controlling a sensor, for example. FIG. 33 illustrates a wiring SNCL as a wiring for electrical connection to the sensor.

The sensor can be, for example, a touch sensor that can be provided in the display portion. Alternatively, the sensor can be an illuminance sensor, for example.

The power supply circuit 47 has a function of generating voltages to be supplied to circuits included in the pixel circuits 51, the driver circuit 65, and the functional circuit 40, for example. Note that the power supply circuit 47 may have a function of selecting a circuit to which a voltage is to be supplied. The power supply circuit 47 can stop supply of a voltage to the CPU 45, the GPU 42, and the like during a period in which a still image is displayed so that the power consumption of the whole display apparatus 90A is reduced, for example.

As described above, the display apparatus of one embodiment of the present invention can have a structure in which display elements, the pixel circuits, the driver circuit, and the functional circuit 40 are stacked. The driver circuit and the functional circuit, which are peripheral circuits, can be provided so as to overlap with the pixel circuits and thus the width of the bezel can be made extremely small, so that the display apparatus can be downsized. The display apparatus of one embodiment of the present invention has a structure in which circuits are stacked and thus wirings connecting the circuits can be shortened, resulting in a reduction in weight of the display apparatus. The display apparatus of one embodiment of the present invention can include a display portion with an increased resolution of pixels; thus, the display apparatus can have high display quality.

### <Structure Example of Display Module>

Next, a structure example of a display module including the display apparatus 90A will be described.

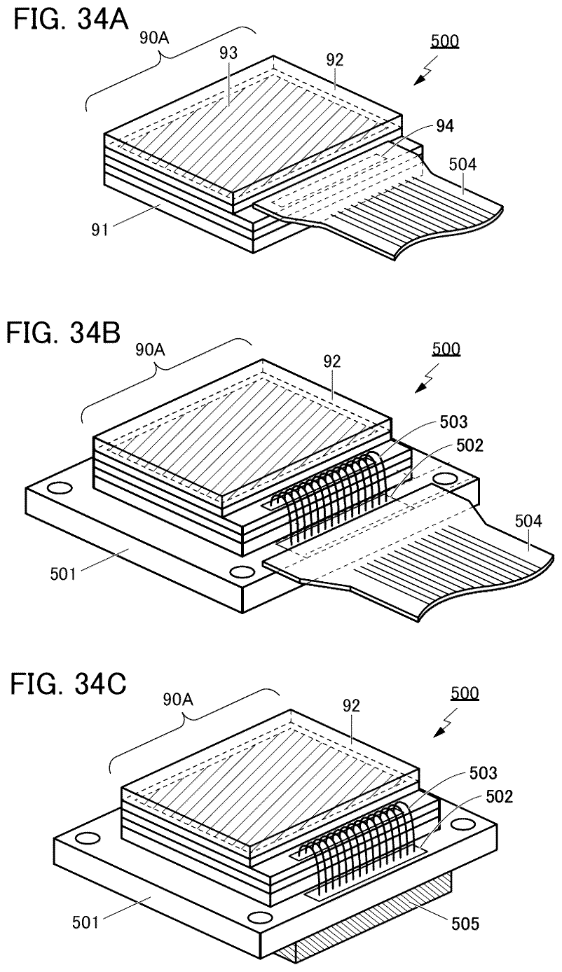

FIG. 34A to FIG. 34C are each a perspective view of a display module 500. The display module 500 has a structure in which an FPC 504 is provided on the terminal portion 94 of the display apparatus 90A. The FPC 504 has a structure in which a film formed of an insulator is provided with a wiring. The FPC 504 is flexible. The FPC 504 functions as a wiring for supplying a video signal, a control signal, a power supply potential, and the like to the display apparatus 90A from the outside. An IC may be mounted on the FPC 504.

The display module 500 illustrated in FIG. 34A includes the display apparatus 90A over a printed wiring board 501. The printed wiring board 501 includes wirings inside a substrate formed of an insulator and/or on the surface of the substrate.

In the display module 500 illustrated in FIG. 34B, the terminal portion 94 of the display apparatus 90A is electrically connected to a terminal portion 502 of the printed wiring board 501 through a wire 503. The wire 503 can be formed by wire bonding. Ball bonding or wedge bonding can be used as the wire bonding.

After the wire 503 is formed, the wire 503 may be covered with a resin material or the like. Note that the display apparatus 90A and the printed wiring board 501 may be electrically connected to each other by a method other than the wire bonding. For example, the display apparatus 90A and the printed wiring board 501 may be electrically connected to each other using an anisotropic conductive adhesive, a bump, or the like.

In the display module 500 illustrated in FIG. 34B, the terminal portion 502 of the printed wiring board 501 is electrically connected to the FPC 504. In the case where the electrode pitch in the terminal portion 94 of the display apparatus 90A is different from the electrode pitch in the FPC 504, for example, the terminal portion 94 may be electrically connected to the FPC 504 via the printed wiring board 501. Specifically, the interval (pitch) between a plurality of electrodes in the terminal portion 94 can be converted into the interval between a plurality of electrodes in the terminal portion 502 using wirings formed on the printed wiring board 501. Accordingly, even when the electrode pitch in the terminal portion 94 is different from the electrode pitch in the FPC 504, electrical connection between the electrodes can be made.

The printed wiring board 501 can be provided with a variety of elements such as a resistor, a capacitor, and a semiconductor element.

As in the display module 500 illustrated in FIG. 34C, the terminal portion 502 may be electrically connected to a connection portion 505 provided on the bottom surface (a surface where the display apparatus 90A is not provided) of the printed wiring board 501. With the use of a socket-type connection portion as the connection portion 505, for example, the display module 500 can be easily attached to and detached from another device.

<Structure example of pixel circuit>

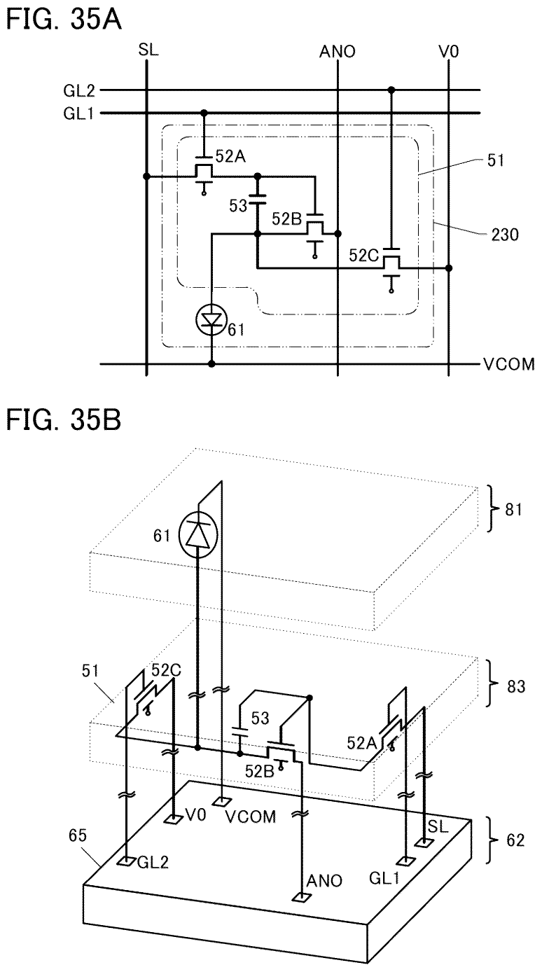

FIG. 35A and FIG. 35B illustrate a structure example of the pixel circuit 51 and the light-emitting device 61 connected to the pixel circuit 51. FIG. 35A schematically illustrates connection of the elements, and FIG. 35B schematically illustrates the vertical positional relation of the layer 62 including the driver circuit, the layer 83 including a plurality of transistors of the pixel circuit, and the layer 81 including the light-emitting device.

The pixel circuit 51 illustrated as an example in FIG. 35A and FIG. 35B includes the transistor 52A, the transistor 52B, the transistor 52C, and the capacitor 53. The transistor 52A, the transistor 52B, and the transistor 52C can be OS transistors. Each of the OS transistors of the transistor 52A, the transistor 52B, and the transistor 52C preferably includes a back gate electrode, in which case the structure in which the back gate electrode is supplied with the same signals as those supplied to the gate electrode or the structure in which the back gate electrode is supplied with signals different from those supplied to the gate electrode can be used.

The transistor 52B includes the gate electrode electrically connected to the transistor 52A, a first electrode electrically connected to the light-emitting device 61, and a second electrode electrically connected to a wiring ANO. The wiring ANO is a wiring for supplying a potential for supplying current to the light-emitting device 61.

The transistor 52A includes a first terminal electrically connected to the gate electrode of the transistor 52B, a second terminal electrically connected to the wiring SL which functions as a source line, and the gate electrode having a function of controlling the conduction state or non-conduction state on the basis of the potential of a wiring GL1 which functions as a gate line.

The transistor 52C includes a first terminal electrically connected to a wiring V0, a second terminal electrically connected to the light-emitting device 61, and the gate electrode having a function of controlling the conduction state or non-conduction state on the basis of the potential of a wiring GL2 which functions as a gate line. The wiring V0 is a wiring for supplying a reference potential and a wiring for outputting current flowing through the pixel circuit 51 to the driver circuit 65 or the functional circuit 40.

The capacitor 53 includes a conductive film electrically connected to the gate electrode of the transistor 52B and a conductive film electrically connected to the second electrode of the transistor 52C.

The light-emitting device 61 includes a first electrode electrically connected to the first electrode of the transistor 52B and a second electrode electrically connected to the wiring VCOM. The wiring VCOM is a wiring for supplying a potential for supplying current to the light-emitting device 61.

Accordingly, the intensity of light emitted from the light-emitting device 61 can be controlled in accordance with an image signal supplied to the gate electrode of the transistor 52B. Furthermore, variations in voltage between the gate and the source of the transistor 52B can be reduced by the reference potential of the wiring V0 supplied through the transistor 52C.

A current value that can be used for setting pixel parameters can be output from the wiring V0. Specifically, the wiring V0 can function as a monitor line for outputting current flowing through the transistor 52B or current flowing through the light-emitting device 61 to the outside. Current output to the wiring V0 is converted into a voltage by a source follower circuit or the like and output to the outside. Alternatively, the current output to the wiring V0 can be converted into a digital signal by an A-D converter or the like and output to the functional circuit 40 or the like.

Note that the light-emitting device described in one embodiment of the present invention refers to a self-luminous display element such as an OLED. Note that the light-emitting device electrically connected to the pixel circuit can be a self-luminous light-emitting device such as an LED, a micro LED, a QLED, or a semiconductor laser.

Note that in the structure illustrated as an example in FIG. 35B, the wirings electrically connecting the pixel circuit 51 and the driver circuit 65 can be shortened, so that wiring resistance of the wirings can be reduced. Thus, data can be written at high speed, which enables high-speed driving of the display apparatus 90A. Therefore, even when the number of the pixel circuits 51 included in the display apparatus 90A is increased, a sufficient frame period can be ensured, and thus, the pixel density of the display apparatus 90A can be increased. In addition, the increased pixel density of the display apparatus 90A can increase the resolution of an image displayed by the display apparatus 90A. For example, the pixel density of the display apparatus 90A can be higher than or equal to 1000 ppi, higher than or equal to 5000 ppi, or higher than or equal to 7000 ppi. Thus, the display apparatus 90A can be, for example, a display apparatus for AR or VR and can be suitably used in an electronic device with a short distance between a display portion and the user, such as an HMD.

Although FIG. 35A and FIG. 35B illustrate, as an example, the pixel circuit 51 including three transistors in total, one embodiment of the present invention is not limited thereto. Structure examples and a driving method example of a pixel circuit which can be used for the pixel circuit 51 will be described below.

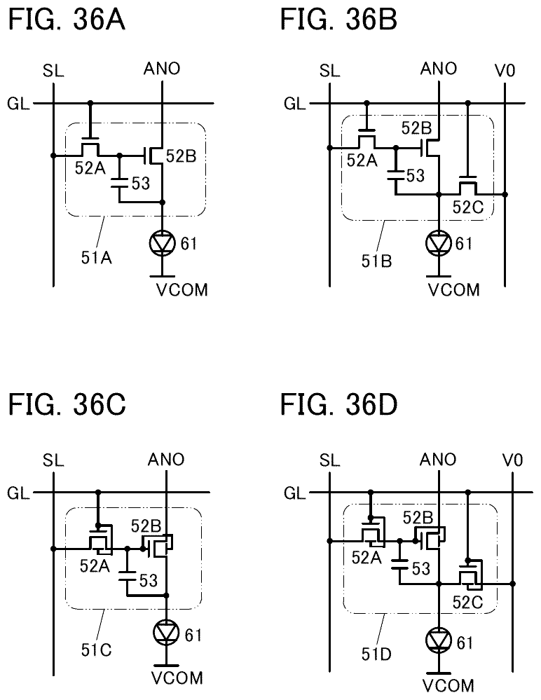

A pixel circuit 51A illustrated in FIG. 36A includes the transistor 52A, the transistor 52B, and the capacitor 53. FIG. 36A illustrates the light-emitting device 61 connected to the pixel circuit 51A. The wiring SL, the wiring GL, the wiring ANO, and the wiring VCOM are electrically connected to the pixel circuit 51A. The pixel circuit 51A has a structure in which the transistor 52C is removed from the pixel circuit 51 illustrated in FIG. 35A and the wiring GL1 and the wiring GL2 are replaced with the wiring GL.

A gate of the transistor 52A is electrically connected to the wiring GL, one of a source and a drain of the transistor 52A is electrically connected to the wiring SL, and the other of the source and the drain of the transistor 52A is electrically connected to a gate of the transistor 52B and one electrode of a capacitor C1. One of a source and a drain of the transistor 52B is electrically connected to the wiring ANO and the other of the source and the drain of the transistor 52B is electrically connected to an anode of the light-emitting device 61. The other electrode of the capacitor C1 is electrically connected to the anode of the light-emitting device 61. A cathode of the light-emitting device 61 is electrically connected to the wiring VCOM.

A pixel circuit 51B illustrated in FIG. 36B has a structure in which the transistor 52C is added to the pixel circuit 51A. In addition, the wiring V0 is electrically connected to the pixel circuit 51B.

A pixel circuit 51C illustrated in FIG. 36C is an example of the case where a transistor including a pair of gates electrically connected to each other is used as each of the transistor 52A and the transistor 52B of the pixel circuit 51A. A pixel circuit 51D illustrated in FIG. 36D is an example of the case where such a transistor is used in the pixel circuit 51B. Thus, the amount of current that can flow through the transistor can be increased. Note that although a transistor including a pair of gates electrically connected to each other is used as each of the transistors here, one embodiment of the present invention is not limited thereto. A transistor that includes a pair of gates electrically connected to different wirings may be used. For example, by using a transistor in which one of gates is electrically connected to a source, the reliability can be increased.

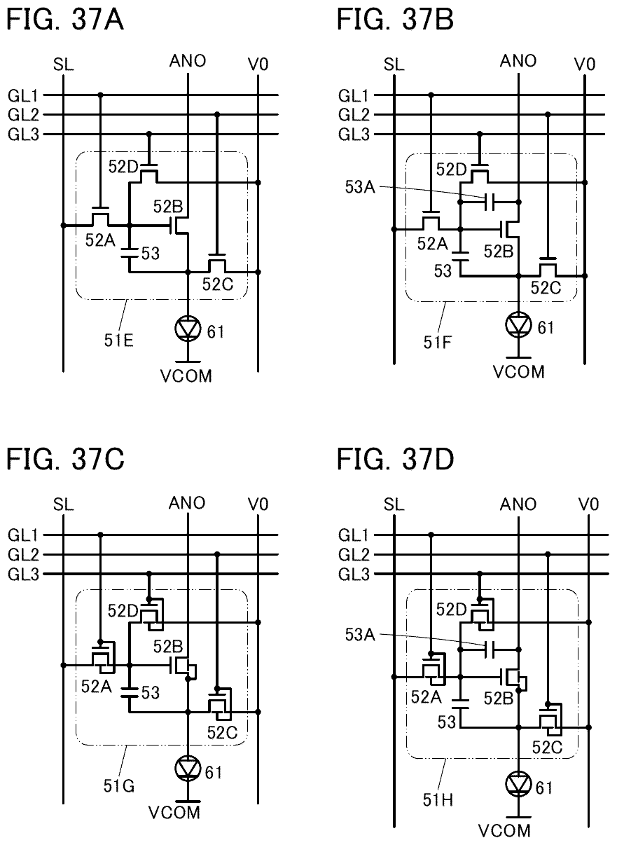

A pixel circuit 51E illustrated in FIG. 37A has a structure in which a transistor 52D is added to the pixel circuit 51B. The wiring GL1, the wiring GL2, and a wiring GL3 functioning as gate lines are electrically connected to the pixel circuit 51E. Note that in this embodiment and the like, the wiring GL1, the wiring GL2, and the wiring GL3 are collectively referred to as the wiring GL in some cases. Thus, the wiring GL is not limited to one wiring and consists of a plurality of wirings in some cases.

A gate of the transistor 52D is electrically connected to the wiring GL3, one of a source and a drain of the transistor 52D is electrically connected to the gate of the transistor 52B, and the other of the source and the drain of the transistor 52D is electrically connected to the wiring V0. The gate of the transistor 52A is electrically connected to the wiring GL1, and the gate of the transistor 52C is electrically connected to the wiring GL2.

When the transistor 52C and the transistor 52D are turned on at the same time, the source and the gate of the transistor 52B have the same potential, so that the transistor 52B can be turned off. Thus, current flowing to the light-emitting device 61 can be blocked forcibly. Such a pixel circuit is suitable for the case of using a display method in which a display period and a non-lighting period are alternately provided.

A pixel circuit 51F illustrated in FIG. 37B is an example of the case where a capacitor 53A is added to the pixel circuit 51E. The capacitor 53A functions as a storage capacitor.

A pixel circuit 51G illustrated in FIG. 37C and a pixel circuit 51H illustrated in FIG. 37D are each an example in which a transistor including a pair of gates is used in the pixel circuit 51E or the pixel circuit 51F. A transistor including a pair of gates electrically connected to each other is used as each of the transistor 52A, the transistor 52C, and the transistor 52D, and a transistor including a source electrically connected to one of gates is used as the transistor 52B.

### Variation Example

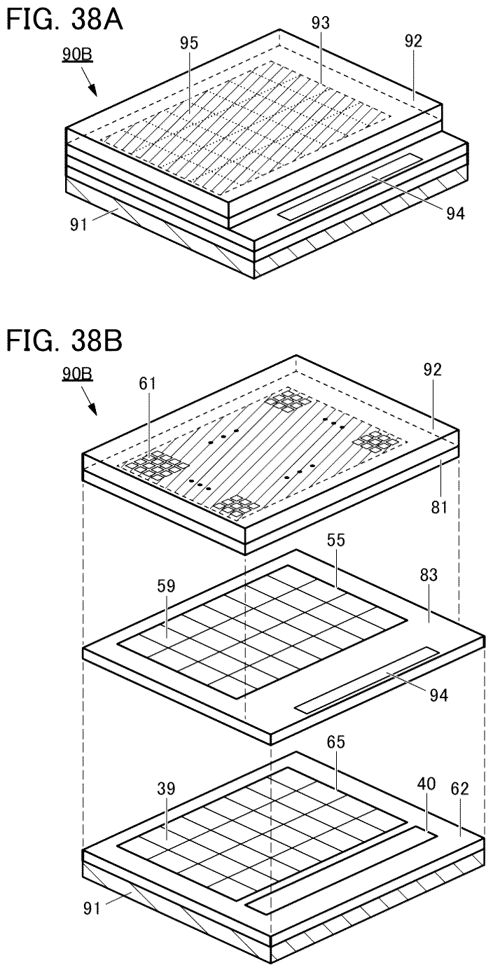

FIG. 38A and FIG. 38B are perspective views of a display apparatus 90B, which is a variation example of the display apparatus 90A. FIG. 38B is a perspective view for illustrating structures of layers included in the display apparatus 90B. Description is made mainly on portions different from those of the display apparatus 90A to reduce repeated description.

In the display apparatus 90B, the driver circuit 65 and the pixel circuit group 55 including the plurality of pixel circuits 51 are provided to overlap with each other. In the display apparatus 90B, the pixel circuit group 55 is divided into a plurality of sections 59 and the driver circuit 65 is divided into a plurality of sections 39. The plurality of sections 39 each include the source driver circuit 66 and the gate driver circuit 33.

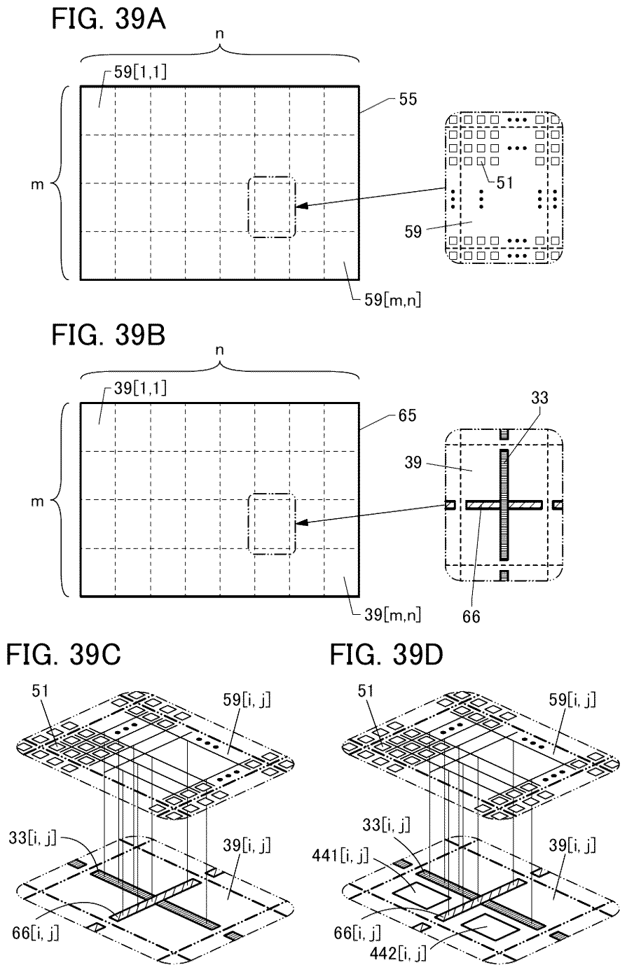

FIG. 39A illustrates a structure example of the pixel circuit group 55 included in the display apparatus 90B. FIG. 39B illustrates a structure example of the driver circuit 65 included in the display apparatus 90B. The sections 59 and the sections 39 are each arranged in a matrix of m rows and n columns (m and n are each an integer greater than or equal to 1). In this specification and the like, the section 59 in the first row and the first column is denoted by a section 59 [i,j], and the section 59 in the m-th row and the n-th column is denoted by a section 59 [m,n]. Similarly, the section 39 in the first row and the first column is denoted by a section 39 [i,j], and the section 39 in the m-th row and the n-th column is denoted by a section 39 [m,n]. FIG. 39A and FIG. 39B illustrate a case where m is 4 and n is 8. That is, the pixel circuit group 55 and the driver circuit 65 are each divided into 32 sections.

The plurality of sections 59 each include the plurality of pixel circuits 51, a plurality of wirings SL, and a plurality of wirings GL. In each of the plurality of sections 59, one of the plurality of pixel circuits 51 is electrically connected to at least one of the plurality of wirings SL and at least one of the plurality of wirings GL.

One of the sections 59 and one of the sections 39 are provided to overlap with each other (see FIG. 39C). For example, a section 59 [i,j] (i is an integer greater than or equal to 1 and less than or equal to m, and j is an integer greater than or equal to 1 and less than or equal to n) and a section 39 [i,j] are provided to overlap with each other. A source driver circuit 66 [i,j] included in the section 39 [i,j] is electrically connected to the wiring SL included in the section 59 [i,j]. A gate driver circuit 33 [i,j] included in the section 39 [i,j] is electrically connected to the wiring GL included in the section 59 [i,j]. The source driver circuit 66 [i,j] and the gate driver circuit 33 [i,j] have a function of controlling the plurality of pixel circuits 51 included in the section 59 [i,j].

When the section 59 [i.j] and the section 39 [i,j] are provided to overlap with each other, a connection distance (wiring length) between the pixel circuit 51 included in the section 59 [i,j] and each of the source driver circuit 66 and the gate driver circuit 33 included in the section 39 [i,j] can be made extremely short. As a result, the wiring resistance and the parasitic capacitance are reduced, and thus time taken for charging and discharging can be reduced and high-speed driving can be achieved. Moreover, power consumption can be reduced. Furthermore, the size and weight of the display apparatus can be reduced.

The display apparatus 90B includes the source driver circuit 66 and the gate driver circuit 33 in each of the sections 39. Thus, the display portion 93 can be divided into the sections 59 corresponding to the sections 39, and image rewriting can be performed. For example, in the display portion 93, image data rewriting can be performed only in a section where an image has been changed and image data can be retained in a section with no change, so that power consumption can be reduced.

In this embodiment and the like, one section of the display portion 93 divided into the sections 59 is referred to as a sub-display portion 95. Thus, the sub-display portion 95 is also one of the sections 39 obtained by dividing the display portion 93. The display portion 93 includes a plurality of sub-display portions 95. The display portion 93 can also be regarded as being formed of the plurality of sub-display portions 95. In the display apparatus 90B described with reference to FIG. 34 and FIG. 35, the display portion 93 is divided into 32 sub-display portions 95 (see FIG. 38A). Each one of the sub-display portions 95 includes the plurality of pixels 230 illustrated in FIG. 31 and the like. Specifically, each one of the sub-display portions 95 includes the plurality of light-emitting devices 61 and one of the sections 59 including the plurality of pixel circuits 51. Each one of the sections 39 has a function of controlling the plurality of pixels 230 included in one of the sub-display portions 95.

In the display apparatus 90B, driving frequency at the time of displaying an image can be set freely for each of the sub-display portions 95 by the timing controller 44 included in the functional circuit 40. The functional circuit 40 has a function of controlling operations in the plurality of sections 39 and the plurality of sections 59. In other words, the functional circuit 40 has a function of controlling driving frequency and operation timing of each of the plurality of sub-display portions 95 arranged in a matrix. In addition, the functional circuit 40 has a function of adjusting synchronization between the sub-display portions.

A timing controller 441 and an input/output circuit 442 may be provided for each of the sections 39 (see FIG. 39D). For the input/output circuit 442, an I2C (Inter-Integrated Circuit) interface can be used, for example. The timing controller 441 included in the section 39 [i.f] is denoted as a timing controller 441 [i,j] in FIG. 39C and FIG. 39D. Furthermore, the input/output circuit 442 included in the section 39 [i,j] is denoted as an input/output circuit 442 [i,j].

The functional circuit 40 supplies to the input/output circuit 442 [i.j], for example, setting signals for the scan direction and driving frequency of the gate driver circuit 33 [i.j] and operation parameters, such as the number of pixels in image data reduced for decreasing a definition (the number of pixels where image data rewriting is not performed at the time of image data rewriting). The source driver circuit 66 [i,j] and the gate driver circuit 33 [i,j] operate in accordance with the operation parameters.

In the case where the sub-display portions 95 each include a light-receiving device described later, the input/output circuit 442 outputs information obtained by photoelectric conversion by the light-receiving device to the functional circuit 40.

In the display apparatus 90B in the electronic device of one embodiment of the present invention, the pixel circuit 51 and the driver circuit 65 are stacked and the driving frequency is different in each of the sub-display portions 95 in accordance with the motion of the user's gaze, whereby low power consumption can be achieved.

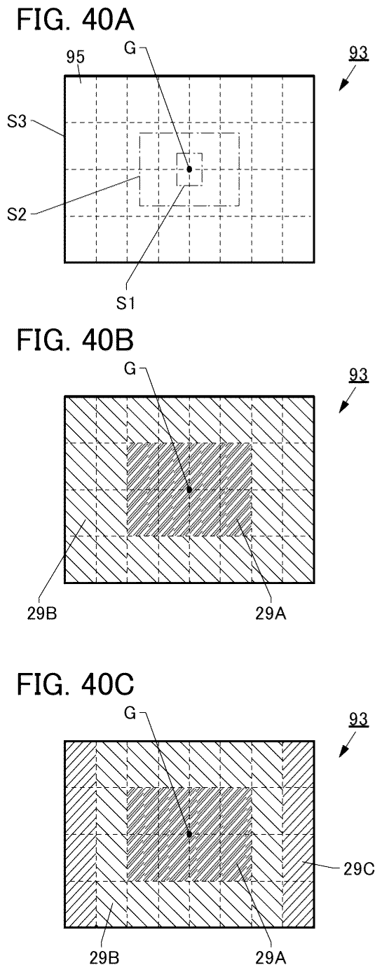

FIG. 40A illustrates the display portion 93 including the sub-display portions 95 in four rows and eight columns. FIG. 40A also illustrates the first region S1 to the third region S3 with a gaze point G as a center. The arithmetic portion 103 allocates the plurality of sub-display portions 95 to a first section 29A overlapping with the first region S1 or the second region S2 or a second section 29B overlapping with the third region S3. That is, the arithmetic portion 103 allocates the plurality of sections 39 to the first section 29A or the second section 29B. In this case, the first section 29A overlapping with the first region S1 and the second region S2 includes a region overlapping with the gaze point G. Furthermore, the second section 29B includes the sub-display portions 95 positioned outside the first section 29A (see FIG. 40B).

The operations of the driver circuits (the source driver circuit 66 and the gate driver circuit 33) included in each of the plurality of sections 39 are controlled by the functional circuit 40. For example, the second section 29B is a section overlapping with the third region S3 including the above-described stable visual field, inducting visual field, and supplementary visual field, and is hard for the user to discriminate. Thus, the user perceives a small reduction in practical display quality (hereinafter also referred to as “practical display quality”) even when the number of times of image data rewriting per unit time (hereinafter also referred to as “image rewriting frequency”) at the time of displaying an image is smaller in the second section 29B than in the first section 29A. In other words, a reduction in practical display quality is small even when driving frequency of the sub-display portion 95 included in the second section 29B (also referred to as “second driving frequency”) is lower than driving frequency of the sub-display portions 95 included in the first section 29A (also referred to as “first driving frequency”).

A decrease in the driving frequency can result in a reduction in power consumption of the display apparatus. On the other hand, a decrease in the driving frequency reduces the display quality. In particular, the display quality in displaying a moving image is reduced. According to one embodiment of the present invention, the second driving frequency is made lower than the first driving frequency; thus, power consumption can be reduced in a section where the visibility by the user is low and the reduction of the practical display quality can be suppressed. According to one embodiment of the present invention, both display quality maintenance and a reduction in power consumption can be achieved.

The first driving frequency can be higher than or equal to 30 Hz and lower than or equal to 500 Hz, preferably higher than or equal to 60 Hz and lower than or equal to 500 Hz. The second driving frequency is preferably lower than or equal to the first driving frequency, further preferably lower than or equal to a half of the first driving frequency, still further preferably lower than or equal to one fifth of the first driving frequency.

A section of the sub-display portions 95 overlapping with the third region S3 may be set as a third section 29C (see FIG. 40C) on the outer side of the second section 29B, and the driving frequency of the sub-display portions 95 included in the third section 29C (also referred to as “third driving frequency”) may be made lower than the driving frequency in the second section 29B. The third driving frequency is preferably lower than or equal to the second driving frequency, further preferably lower than or equal to a half of the second driving frequency, still further preferably lower than or equal to one fifth of the second driving frequency. By significantly lowering image rewriting frequency, power consumption can be further reduced. Note that rewriting of image data may be stopped if necessary. By stopping rewriting of image data, power consumption can be further reduced.

In the case where such a driving method is employed, a transistor with an extremely low off-state current is suitably used as a transistor included in the pixel circuit 51. For example, an OS transistor is suitably used as the transistor included in the pixel circuit 51. An OS transistor has an extremely low off-state current and thus can achieve long-term retention of image data supplied to the pixel circuit 51. It is particularly suitable to use an OS transistor as the transistor 52A.

In some cases, an image whose brightness, contrast, color tone, or the like is greatly different from that of the previous image is displayed as in the case where a video scene displayed on the display portion 93 is changed, for example. Such a case causes a mismatch of the timing at which an image is changed between the first section 29A and a section whose driving frequency is lower than that of the first section 29A. This might cause a great difference in the brightness, contrast, color tone, or the like between the sections, leading to the loss of the practical display quality. In such a case where a video scene is changed, image rewriting can be performed in the sections other than the first section 29A at a driving frequency which is the same as that of the first section 29A once, and then the driving frequency of the sections other than the first section 29A can be decreased.

In the case where the fluctuation amount of the gaze point G is judged to be exceeding a certain value, image rewriting may be performed in the sections other than the first section 29A at a driving frequency which is the same as that of the first section 29A, and in the case where the fluctuation amount is judged to be within the certain value, the driving frequency of the sections other than the first section 29A may be decreased. In the case where the fluctuation amount of the gaze point G is judged to be small, the driving frequency of the sections other than the first section 29A may be further decreased.

In the case where the display apparatus 90B does not include a frame memory, which is a memory device for temporarily retaining image data, or includes one frame memory for the entire display portion 93, each of the second driving frequency and the third driving frequency needs to be an integral submultiple of the first driving frequency.

When the plurality of sub-display portions 95 are provided with respective frame memories, each of the second driving frequency and the third driving frequency can be set to a given value without limitation to an integral submultiple of the first driving frequency. When the second driving frequency and the third driving frequency are set to given values, the degree of flexibility in setting the driving frequencies can be increased. As a result, a reduction in the practical display quality can be small.

Note that sections set for the display portion 93 are not limited to the three sections of the first section 29A, the second section 29B, and the third section 29C. The display portion 93 may include four or more sections. When a plurality of sections are set for the display portion 93 and the driving frequencies of the sections are gradually lowered, a reduction in the practical display quality can be smaller.

The above-described upconversion processing may be performed on an image to be displayed on the first section 29A. When an image obtained by the upconversion processing is displayed on the first section 29A, the display quality can be increased. The above-described upconversion processing may be performed on an image to be displayed on the sections other than the first section 29A. When an image obtained by the upconversion processing is displayed on the sections other than the first section 29A, a reduction in the practical display quality that occurs in the case where the driving frequencies of the sections other than the first section 29A are lowered can be smaller.

Note that the upconversion processing of an image to be displayed on the first section 29A may be performed using an algorithm with high accuracy, and the upconversion processing of an image to be displayed on the sections other than the first section 29A may be performed using an algorithm with low accuracy. A reduction in the practical display quality that occurs in the case where the driving frequencies of the sections other than the first section 29A are lowered can be smaller also in such a case.

In the case where the definition of image data is higher than the definition of the display portion 93, or in the case where high-speed rewriting and low power consumption have a priority, for example, downconversion processing may be performed on an image displayed on the sections other than the first section 29A in accordance with the purpose or the like. For example, high-speed rewriting and low power consumption can be achieved by rewriting an image displayed on the sections other than the first section 29A every several rows, every several columns, or every several pixels.

The definitions of images displayed on the sections other than the first section 29A including a gaze point are lower than the definition of an image displayed on the first section 29A, enabling a reduction in the load at the time of generation of a video signal (rendering). The processing is also referred to as foveated rendering. When foveated rendering is combined with a reduction in driving frequency of the sections other than the first section 29A, power consumption can be further reduced while a reduction in display quality is inhibited.

When image data rewriting performed in each of the sub-display portions 95 is performed concurrently in all of the sub-display portions 95, high-speed rewriting can be achieved. That is, when image data rewriting performed in each of the sections 39 is performed concurrently in all of the sections 39, high-speed rewriting can be achieved.

In general, while pixels in one row are selected by a gate driver circuit, a source driver circuit writes image data to all of the pixels in one row concurrently in the case of line sequential driving. In the case where the display portion 93 is not divided into the sub-display portions 95 and has a definition of 4000×2000 pixels, for example, image data needs to be written to 4000 pixels by the source driver circuit while the pixels in one row are selected by the gate driver circuit.

In the case where the frame frequency is 120 Hz, one frame period is approximately 8.3 msec. Accordingly, the gate driver needs to select 2000 rows in approximately 8.3 msec, and the time for selecting one gate line in one row, that is, the time for writing image data to each pixel is approximately 4.17 usec. That is, it becomes more difficult to ensure sufficient time for rewriting image data as the definition of the display portion increases or as the frame frequency increases.

The display portion 93 of the display apparatus 90B described as an example in this embodiment is divided into four parts in the row direction. Thus, the time for writing image data to each pixel in one sub-display portion 95 can be four times as long as that of the case where the display portion 93 is not divided. According to one embodiment of the present invention, the time for rewriting image data can be easily ensured even in the case where the frame frequency is 240 Hz or 360 Hz; thus, a display apparatus with high display quality can be achieved.

Since the display portion 93 of the display apparatus 90B described as an example in this embodiment is divided into four parts in the row direction, the length of the wiring SL electrically connecting the source driver circuit and the pixel circuit becomes one fourth. Accordingly, each of the resistance value and parasitic capacitance of the wiring SL becomes one fourth, whereby the time required for writing (rewriting) image data can be shortened.

In addition, the display portion 93 of the display apparatus 90B described as an example in this embodiment is divided into eight parts in the column direction; thus, the length of the wiring GL electrically connecting the gate driver circuit and the pixel circuit becomes one eighth. Accordingly, each of the resistance value and parasitic capacitance of the wiring GL becomes one eighth, whereby degradation and delay of a signal can be suppressed and the time for rewriting image data can be easily ensured.

According to the display apparatus 90B of one embodiment of the present invention, sufficient time for writing image data can be easily ensured, and thus high-speed rewriting of a display image can be achieved. Thus, a display apparatus with high display quality can be achieved. In particular, a display apparatus that excels in displaying a moving image can be achieved.

Here, a mode is described in which the display apparatus 90 of one embodiment of the present invention is employed for a thin client. In recent years, the thin client in which main arithmetic processing is performed on a server side and only limited processing is performed on a client side has been attracting attention. As a thin client execution method, a network boot method, a server base method, a blade PC method, a virtual desktop infrastructure (VDI) method, and the like have been proposed.

In any of the methods, a large amount of data is transmitted from a server to a client in a thin client, so that power consumption at the time of transmitting data is increased. With the use of an electronic device including the display apparatus 90 of one embodiment of the present invention as a client, power saving during data transmission can be achieved.

Note that the display apparatus 90B of one embodiment of the present invention is described as an example in which the display portion 93 is divided into the 32 sub-display portions 95. However, the division number of the display portion 93 in the display apparatus 90B of one embodiment of the present invention may be 16, 64, 128, or the like, without limitation to 32. As the division number of the display portion 93 increases, a reduction in practical display quality perceived by the user can be smaller.

At least part of the structure examples, the drawings corresponding thereto, and the like described as examples in this embodiment can be combined with the other structure examples, the other drawings, and the like as appropriate.

### Embodiment 6

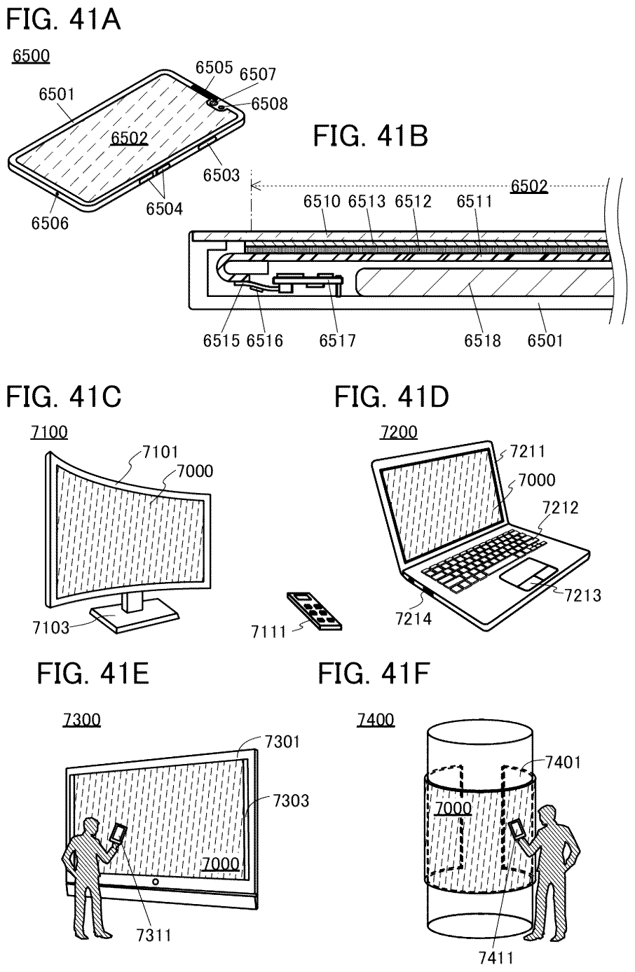

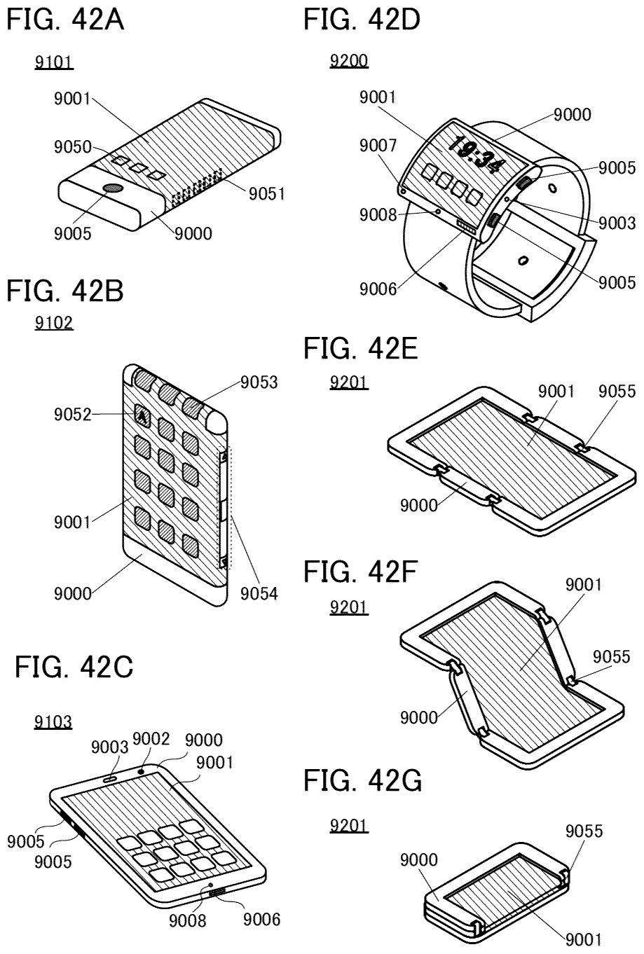

In this embodiment, electronic appliances of one embodiment of the present invention will be described with reference to FIG. 41A to FIG. 42G.

Electronic appliances of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic appliances.

The semiconductor device of one embodiment of the present invention can also be applied to any other portion of an electronic appliance than a display portion. For example, the semiconductor device of one embodiment of the present invention is preferably used for a control portion or the like of an electronic appliance because lower power consumption can be achieved.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, a desktop or laptop personal computer, a monitor of a computer or the like, digital signage, and a large game machine such as a pachinko machine.

In particular, the display apparatus of one embodiment of the present invention can have high resolution, and thus can be suitably used for an electronic appliance including a relatively small display portion. Examples of such an electronic appliance include watch-type and bracelet-type information terminals (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic appliance of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays).

The electronic appliance of this embodiment can have a variety of functions. For example, the electronic appliance can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data recorded in a recording medium.

An electronic appliance 6500 illustrated in FIG. 41A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 41B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display apparatus of one embodiment of the present invention can be used for the display panel 6511. Thus, an extremely lightweight electronic appliance can be achieved. Since the display panel 6511 is extremely thin, the battery 6518 with high capacity can be mounted while an increase in thickness of the electronic appliance is reduced. Moreover, part of the display panel 6511 is folded back so that a connection portion with the FPC 6515 is provided on the back side of the display portion 6502, whereby an electronic appliance with a narrow bezel can be achieved.

FIG. 41C illustrates an example of a television device. In a television device 7100, a display portion 7000 is incorporated in a housing 7101. Here, a structure in which the housing 7101 is supported by a stand 7103 is illustrated.

The display apparatus of one embodiment of the present invention can be used for the display portion 7000.

Operation of the television device 7100 illustrated in FIG. 41C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 41D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 41E and FIG. 41F illustrate examples of digital signage.

Digital signage 7300 illustrated in FIG. 41E includes a housing 7301, the display portion 7000, a speaker 7303, and the like. Furthermore, the digital signage 7300 can also include an LED lamp, an operation key (including a power switch or an operation switch), a connection terminal, a variety of sensors, a microphone, and the like.

FIG. 41F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 41E and FIG. 41F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 41E and FIG. 41F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

Electronic appliances illustrated in FIG. 42A to FIG. 42G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays), a microphone 9008, and the like.

The display apparatus of one embodiment of the present invention can be used for the display portion 9001 in FIG. 42A to FIG. 42G.

The electronic appliances illustrated in FIG. 42A to FIG. 42G have a variety of functions. For example, the electronic appliances can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data recorded in a recording medium. Note that the functions of the electronic appliances are not limited thereto, and the electronic appliances can have a variety of functions. The electronic appliances may each include a plurality of display portions. The electronic appliances may each be provided with a camera or the like and have a function of taking a still image or a moving image and storing the taken image in a recording medium (an external recording medium or a recording medium incorporated in the camera), a function of displaying the taken image on the display portion, or the like.

The electronic appliances illustrated in FIG. 42A to FIG. 42G are described in detail below.

FIG. 42A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 42A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 42B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 42C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 42D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 42E to FIG. 42G are perspective views illustrating a foldable portable information terminal 9201. FIG. 42E is a perspective view of an opened state of the portable information terminal 9201, FIG. 42G is a perspective view of a folded state thereof, and FIG. 42F is a perspective view of a state in the middle of change from one of FIG. 42E and FIG. 42G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Embodiment 7

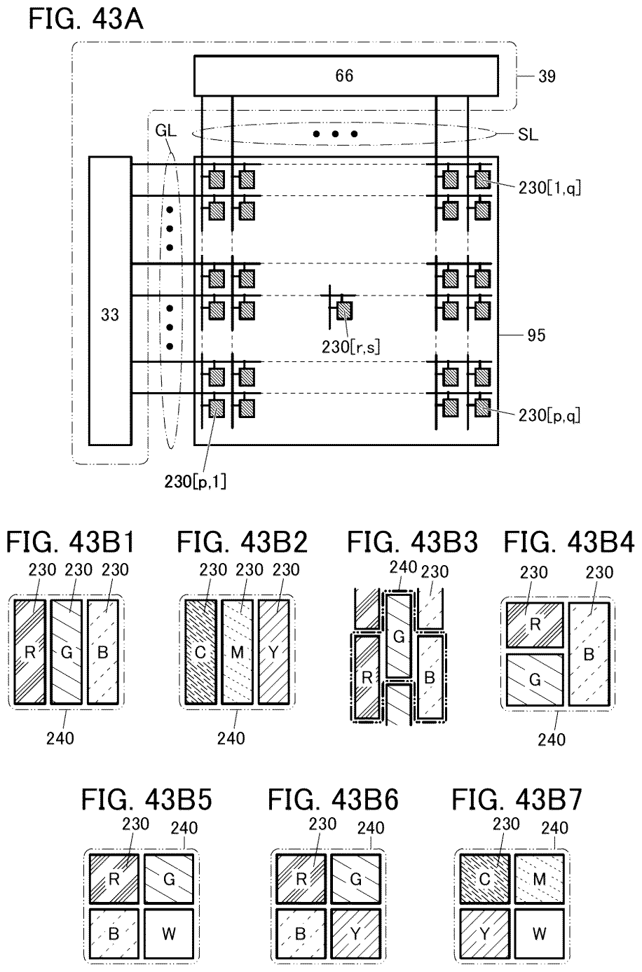

In this embodiment, a structure example of the sub-display portion 95 including a plurality of pixels 230 arranged in a matrix of p rows and q columns (p and q are each an integer greater than or equal to 2) will be described. FIG. 43A is a block diagram illustrating the sub-display portion 95. The sub-display portion 95 is electrically connected to the source driver circuit 66 and the gate driver circuit 33 which are provided in the section 39.

In FIG. 43A, the pixel 230 in the p-th row and the first column is denoted as a pixel 230 [p,1], the pixel 230 in the first row and the q-th column is denoted as a pixel 230 [1,q], and the pixel 230 in the p-th row and the q-th column is denoted as a pixel 230 [p,q].

A circuit included in the gate driver circuit 33 functions as, for example, a scan line driver circuit. A circuit included in the source driver circuit 66 functions as, for example, a signal line driver circuit.

For example, OS transistors may be used as the transistors included in the pixels 230 and Si transistors may be used as the transistors included in a driver circuit. The off-state current of an OS transistor is low, so that power consumption can be reduced. A Si transistor is suitably used in a driver circuit because of having a higher operation speed than an OS transistor. The display apparatus may include OS transistors as both the transistors included in the pixels 230 and the transistors included in a driver circuit. The display apparatus may include Si transistors as both the transistors included in the pixels 230 and the transistors included in a driver circuit. Alternatively, the display apparatus may include Si transistors as the transistors included in the pixels 230 and OS transistors as the transistors included in a driver circuit.

Both a Si transistor and an OS transistor may be used as the transistors included in the pixels 230. Both a Si transistor and an OS transistor may be used as the transistors included in a driver circuit.

In FIG. 43A, p wirings GL are arranged substantially parallel to each other and the potentials thereof are controlled by the gate driver circuit 33, and q wirings SL are arranged substantially parallel to each other and the potentials thereof are controlled by the source driver circuit 66. For example, the pixels 230 arranged in the r-th row (r represents a given number and is an integer greater than or equal to 1 and less than or equal to p in this embodiment and the like) are electrically connected to the gate driver circuit 33 through the wiring GL of the r-th row. The pixels 230 arranged in the s-th column (s represents a given number and is an integer greater than or equal to 1 and less than or equal to q in this embodiment and the like) are electrically connected to the source driver circuit 66 through the wiring SL of the s-th column. In FIG. 43A, the pixel 230 in the r-th row and the s-th column is denoted as a pixel 230 [r,s].

Note that the number of the wirings GL electrically connected to the pixels 230 included in one row is not limited to one. Furthermore, the number of the wirings SL electrically connected to the pixels 230 included in one column is not limited to one. The wiring GL and the wiring SL are examples, and wirings connected to the pixels 230 are not limited to the wiring GL and the wiring SL.

Full-color display can be achieved by making the pixel 230 that controls red light, the pixel 230 that controls green light, and the pixel 230 that controls blue light, which are arranged in a stripe pattern, collectively function as one pixel 240 and by controlling the amount of light emission (emission luminance) from each of the pixels 230. In other words, each of the three pixels 230 functions as a subpixel. That is, three subpixels each control the emission amount or the like of red light, green light, and blue light (see FIG. 43B1). Note that the colors of light controlled by the three subpixels are not limited to a combination of red (R), green (G), and blue (B) and may be cyan (C), magenta (M), and yellow (Y) (see FIG. 43B2).

When the pixels 240 are arranged in a matrix of 1920×1080, the display portion 93 can achieve full-color display with a so-called 2K definition. For example, when the pixels 240 are arranged in a matrix of 3840×2160, the display portion 93 can achieve full-color display with a so-called 4K definition. For example, when the pixels 240 are arranged in a matrix of 7680×4320, the display portion 93 can achieve full-color display with a so-called 8K definition. By increasing the number of pixels 240, the display portion 93 that can perform full-color display with 16K or 32K definition can also be obtained.

The three pixels 230 constituting one pixel 240 may be arranged in a delta arrangement (see FIG. 43B3). Specifically, the three pixels 230 constituting one pixel 240 may be arranged such that the lines connecting the center points of the three pixels 230 form a triangle. Note that the arrangement of the pixels 230 is not limited to a stripe arrangement or a delta arrangement. The pixels 230 may be arranged in a zigzag arrangement, an S-stripe arrangement, a Bayer arrangement, or a PenTile arrangement.

The three subpixels (pixels 230) do not necessarily have the same area. In the case where the emission efficiency, reliability, and the like vary depending on emission colors, the subpixel area may be changed depending on the emission color (see FIG. 43B4).

Four subpixels may collectively function as one pixel. For example, a subpixel that controls white light may be added to the three subpixels that control red light, green light, and blue light (see FIG. 43B5). The addition of the subpixel that controls white light can increase the luminance of a display region. Alternatively, a subpixel that controls yellow light may be added to the three subpixels that control red light, green light, and blue light (see FIG. 43B6). Further alternatively, a subpixel that controls white light may be added to the three subpixels that control cyan light, magenta light, and yellow light (see FIG. 43B7).

When the number of subpixels functioning as one pixel is increased and subpixels that control light of red, green, blue, cyan, magenta, yellow, and the like are used in an appropriate combination, the reproducibility of halftones can be increased. Thus, display quality can be improved.

The display apparatus of one embodiment of the present invention can reproduce the color gamut of various standards. For example, the display apparatus of one embodiment of the present invention can reproduce the color gamut of the PAL (Phase Alternating Line) standard and the NTSC (National Television System Committee) standard for TV broadcasting; the sRGB (standard RGB) standard and the Adobe RGB standard widely used for display apparatuses used in electronic devices such as personal computers, digital cameras, and printers; the ITU-R BT.709 (International Telecommunication Union Radiocommunication Sector Broadcasting Service (Television) 709) standard for HDTV (High Definition Television, also referred to as Hi-Vision); the DCI-P3 (Digital Cinema Initiatives P3) standard for digital cinema projection; the ITU-R BT.2020 (REC.2020 (Recommendation 2020)) standard for UHDTV (Ultra High Definition Television, also referred to as Super Hi-Vision); and the like.

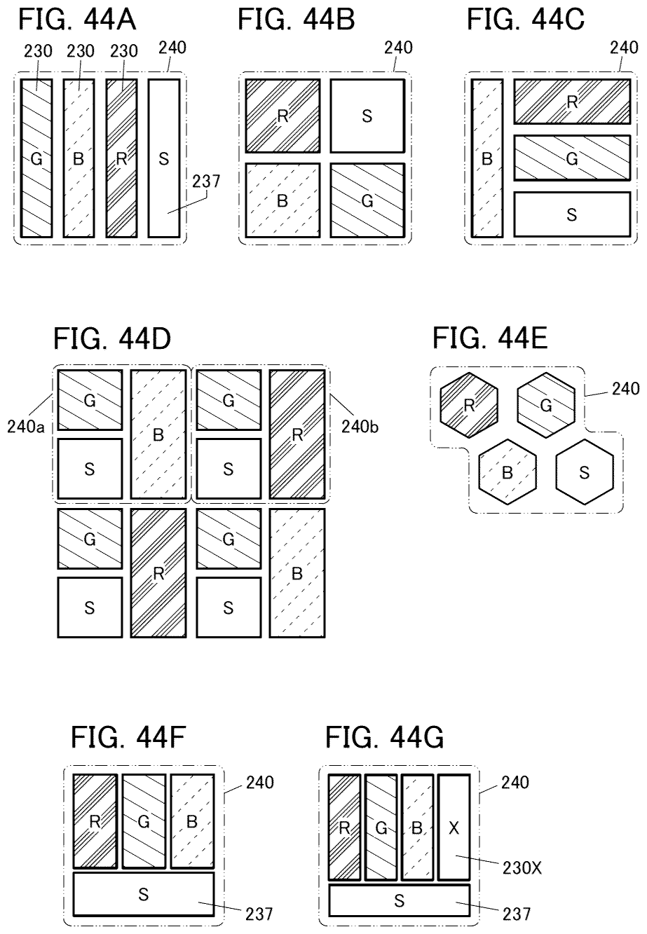

A pixel 237 including a light-receiving device may be provided in one pixel 240. In the pixel 240 illustrated in FIG. 44A, a pixel 230 (G) exhibiting green light, a pixel 230 (B) exhibiting blue light, a pixel 230 (R) exhibiting red light, and a pixel 237 (S) including a light-receiving device are arranged in a stripe pattern. Note that in this specification and the like, the pixel 237 is also referred to as an “image capturing pixel”.

The light-receiving device included in the pixel 237 is preferably an element that detects visible light and is further preferably an element that detects one or more of blue light, violet light, bluish violet light, green light, yellowish green light, yellow light, orange light, red light, and the like. The light-receiving device included in the pixel 237 may be an element that detects infrared light.

The pixel 240 illustrated in FIG. 44A employs a stripe arrangement. Note that in the case where the pixel 237 including a light-receiving device detects light of a specific color, the pixel 230 exhibiting light of the color is preferably positioned adjacent to the pixel 237, whereby detection accuracy can be increased.

Three pixels 230 and one pixel 237 are arranged in a matrix in the pixel 240 illustrated in FIG. 44B. Although FIG. 44B illustrates an example in which the pixel 230 exhibiting red light is adjacent to the pixel 237 including a light-receiving device in the row direction and the pixel 230 exhibiting blue light is adjacent to the pixel 230 exhibiting green light in the row direction, one embodiment of the present invention is not limited thereto.

The pixel 240 illustrated in FIG. 44C has a structure in which the pixel 237 is added to an S-stripe arrangement. The pixel 240 in FIG. 44C includes one vertically oriented pixel 230, two horizontally oriented pixels 230, and one horizontally oriented pixel 237. Note that the vertically oriented pixel 230 may be any one of R, G, and S, and there is no limitation on the arrangement order of the horizontally oriented subpixels.

FIG. 44D illustrates an example in which a pixel 240a and a pixel 240b are alternately arranged. The pixel 240a includes the pixel 230 exhibiting blue light, the pixel 230 exhibiting green light, and the pixel 237 including a light-receiving device. The pixel 240b includes the pixel 230 exhibiting red light, the pixel 230 exhibiting green light, and the pixel 237 including a light-receiving device. The pixel 240a and the pixel 240b function as one pixel 240. Although FIG. 44D illustrates the pixel 240a and the pixel 240b each including the pixel 230 exhibiting green light and the pixel 237, one embodiment of the present invention is not limited thereto. When the pixel 240a and the pixel 240b each include the pixel 237, the resolution of an image capturing pixel can be increased.

The layout illustrated in FIG. 44E is preferable because the aperture ratio of each subpixel can be increased. FIG. 44F illustrates an example in which the top surface shapes of the pixels 230 and the pixel 237 are hexagonal.

The pixel 240 illustrated in FIG. 44F is an example in which the pixels 230 are arranged horizontally in one line and the pixel 237 is placed beneath the pixels 230.

The pixel 240 illustrated in FIG. 44G is an example in which the pixels 230 and a pixel 230X are arranged horizontally in one line and the pixel 237 is placed beneath the pixels 230 and the pixel 230X.

As the pixel 230X, for example, the pixel 230 that exhibits infrared light (IR) can be used. That is, the pixel 230X includes the light-emitting device 61 that emits infrared light (IR). In that case, the pixel 237 preferably includes a light-receiving device that detects infrared light. For example, while an image is displayed by the pixel 230 emitting visible light, the pixel 237 can detect reflected light of infrared light emitted by a subpixel X.

A plurality of pixels 237 may be provided in one pixel 240. In that case, light detected by the plurality of pixels 237 may have the same wavelength range or different wavelength ranges.

For example, some of the plurality of pixels 237 may detect visible light and others may detect infrared light.

The pixel 237 is not necessarily provided in all the pixels 240. The pixel 240 including the pixel 237 may be provided for every certain number of pixels.

By using the pixel 237 or using the pixel 237 and the sensor 97, for example, information for personal authentication using a fingerprint, a palm print, an iris, a retina, a shape of a blood vessel (including the shape of a vein and the shape of an artery), face, or the like can be detected. Furthermore, by using the pixel 237 or using the pixel 237 and the sensor 97, the number of blinks, eyelid behavior, pupil size, body temperature, pulse, oxygen saturation in blood, or the like of the user may be measured, so that the user's fatigue level, health condition, and the like can be detected.

The electronic device can be operated using the motion of gaze, the number of blinks, the rhythm of blinks, and the like of the user. Specifically, by using the pixel 237 or using the pixel 237 and the sensor 97, information on the motion of gaze, the number of blinks, the rhythm of blinks, and the like of the user are detected, and one or more combinations of these information may be used as an operation signal of the electronic device. For example, it is possible to replace a blink with a clicking of a mouse. When the motion of a gaze and a blink are detected, the user can perform an input operation of the electronic device with holding nothing in his/her hand.

Thus, the operability of the electronic device can be improved.

When a plurality of image capturing pixels (the pixels 237) are provided in the display apparatus 90, the plurality of image capturing pixels can be used as the gaze detection portion 84. Thus, the number of components of the electronic device can be reduced. Accordingly, improvement in productivity, reductions in weight and costs, and the like of the electronic device can be achieved.

### <Structure Example of Light-Emitting Device>

The light-emitting device 61 that can be used in the display apparatus of one embodiment of the present invention is described.

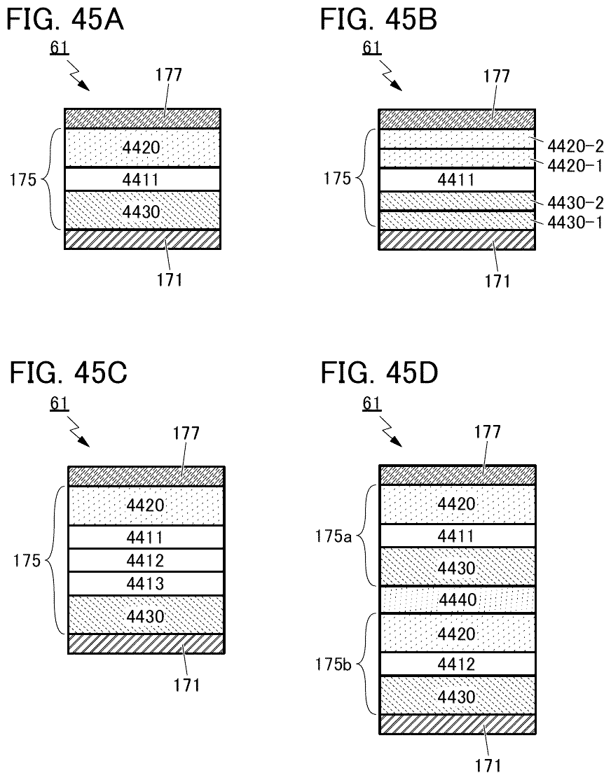

As illustrated in FIG. 45A, the light-emitting device 61 includes an EL layer 175 between a pair of electrodes (a conductive layer 171 and a conductive layer 177). The EL layer 175 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which are provided between the pair of electrodes, can function as a single light-emitting unit, and the structure in FIG. 45A is referred to as a single structure in this specification and the like.

FIG. 45B is a variation example of the EL layer 175 included in the light-emitting device 61 illustrated in FIG. 45A. Specifically, the light-emitting device 61 illustrated in FIG. 45B includes a layer 4430-1 over the conductive layer 171, a layer 4430-2 over the layer 4430-1, the light-emitting layer 4411 over the layer 4430-2, a layer 4420-1 over the light-emitting layer 4411, a layer 4420-2 over the layer 4420-1, and the conductive layer 177 over the layer 4420-2. In the case where the conductive layer 171 serves as an anode and the conductive layer 177 serves as a cathode, for example, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, in the case where the conductive layer 171 serves as a cathode and the conductive layer 177 serves as an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layered structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 45C is another example of the single structure.

The structure in which a plurality of light-emitting units (an EL layer 175a and an EL layer 175b) are connected in series with an intermediate layer (charge-generation layer) 4440 therebetween as illustrated in FIG. 45D is referred to as a tandem structure or a stack structure in this specification and the like. Note that the tandem structure enables a light-emitting device capable of emitting light with high luminance.

In the case where the light-emitting device 61 has the tandem structure illustrated in FIG. 45D, the EL layer 175a and the EL layer 175b may emit light of the same color. For example, the EL layer 175a and the EL layer 175b may both emit green light.

Note that full-color display can be achieved by using the light-emitting device 61 emitting red light (R), the light-emitting device 61 emitting green light (G), and the light-emitting device 61 emitting blue light (B) as subpixels and constituting one pixel with these three subpixels. In the case where the display portion 93 includes three kinds of subpixels of R, G, and B, the light-emitting devices may each have a tandem structure. Specifically, the EL layer 175a and the EL layer 175b in the subpixel of R each contain a material capable of emitting red light, the EL layer 175a and the EL layer 175b in the subpixel of G each contain a material capable of emitting green light, and the EL layer 175a and the EL layer 175b in the subpixel of B each contain a material capable of emitting blue light. In other words, the light-emitting layer 4411 and the light-emitting layer 4412 may contain the same material. When the EL layer 175a and the EL layer 175b emit light of the same color, the current density per unit emission luminance can be reduced. Thus, the reliability of the light-emitting device 61 can be improved.

The emission color of the light-emitting device can be red, green, blue, cyan, magenta, yellow, white, or the like depending on the material of the EL layer 175. Furthermore, the color purity can be further increased when the light-emitting device has a microcavity structure.

The light-emitting layer may contain two or more light-emitting substances that emit light of R (red), G (green), B (blue), Y (yellow), O (orange), or the like. The light-emitting device that emits white light preferably contains two or more kinds of light-emitting substances in the light-emitting layer. To obtain white light emission, two or more light-emitting substances are selected such that they emit light having a relationship of complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

The light-emitting layer preferably contains two or more light-emitting substances that emit light of R (red), G (green), B (blue), Y (yellow), O (orange), or the like. Alternatively, the light-emitting layer preferably contains two or more light-emitting substances that emit light containing two or more of spectral components of R, G, and B. Alternatively, as the light-emitting substance, a substance that emits near-infrared light can be used.

Examples of a light-emitting substance include a substance that emits fluorescent light (a fluorescent material), a substance that emits phosphorescent light (a phosphorescent material), an inorganic compound (e.g., a quantum dot material), and a substance exhibiting thermally activated delayed fluorescence (a TADF material).

At least part of the structure examples, the drawings corresponding thereto, and the like described in this embodiment can be combined with the other structure examples, the other drawings, and the like as appropriate.

### REFERENCE NUMERALS

10: semiconductor device, 20A: semiconductor device, 20B: semiconductor device, 20C: semiconductor device, 20D: semiconductor device, 20E: semiconductor device, 20: semiconductor device, 21: semiconductor layer, 22: insulating layer, 23: conductive layer, 24a: conductive layer, 24b: conductive layer, 25: conductive layer, 29A: first section, 29B: second section, 29C: third section, 30: opening, 31: insulating layer, 32: insulating layer, 33: gate driver circuit, 34: level shifter, 35: amplifier circuit, 36: inspection circuit, 37: video generation circuit, 38: video distribution circuit, 39: section, 40: functional circuit, 41: memory device, 42a: color irregularity correction, 42b: upconversion, 42: GPU, 43: EL correction circuit, 44: timing controller, 45: CPU, 46: sensor controller, 47: power supply circuit, 48: temperature sensor, 49: luminance correction circuit, 50A: display apparatus, 50B: display apparatus, 51A: pixel circuit, 51B: pixel circuit, 51C: pixel circuit, 51D: pixel circuit, 51E: pixel circuit, 51F: pixel circuit, 51G: pixel circuit, 51H: pixel circuit, 51: pixel circuit, 52A: transistor, 52B: transistor, 52C: transistor, 52D: transistor, 52: transistor, 53A: capacitor, 53: capacitor, 54: channel formation region, 55: pixel circuit group, 59: section, 61: light-emitting device, 62: layer, 63: transistor, 64: channel formation region, 65: driver circuit, 66: source driver circuit, 67: digital-analog converter circuit, 71: element layer, 73: element layer, 75: element layer, 77: wiring layer, 80: input/output circuit, 81: layer, 83: layer, 84: gaze detection portion, 85: communication portion, 86: wearing portion, 87: cushion, 88: lens, 89: output terminal, 90_L: display apparatus, 90_R: display apparatus, 90A: display apparatus, 90B: display apparatus, 90: display apparatus, 91: substrate, 92: substrate, 93: display portion, 94: terminal portion, 95: sub-display portion, 97: sensor, 99A: earphone, 99B: earphone, 100: transistor, 101: motion detection portion, 102: substrate, 103: arithmetic portion, 104: conductive layer, 105: housing, 106: insulating layer, 107: adhesive layer, 108: semiconductor layer, 109: input terminal, 110a: insulating layer, 110b: insulating layer, 110c: insulating layer, 110: insulating layer, 111: pixel electrode, 112a: conductive layer, 112b: conductive layer, 112f: conductive layer, 113a: first layer, 113b: second layer, 113c: third layer, 114: common layer, 115: common electrode, 118a: mask layer, 119: substrate, 125: insulating layer, 126a: conductive layer, 126b: conductive layer, 126c: conductive layer, 127: insulating layer, 128: layer, 129a: conductive layer, 129b: conductive layer, 129c: conductive layer, 130B: light-emitting device, 130G: light-emitting device, 130R: light-emitting device, 130: light-emitting device, 131: protective layer, 137: metal oxide film, 140: connection portion, 141: opening, 142: depressed portion, 143: opening, 144a: opening, 144b: opening, 145: opening, 150: electronic device, 151: substrate, 152: substrate, 155: resist mask, 156: resist mask, 157: resist mask, 158: resist mask, 159: resist mask, 162: display portion, 164: circuit portion, 165: conductive layer, 171: conductive layer, 172: FPC, 173: IC, 175a: EL layer, 175b: EL layer, 175: EL layer, 177: conductive layer, 182a: conductive layer, 182b: conductive layer, 182c: conductive layer, 195: insulating layer, 200: transistor, 204: conductive layer, 208f: metal oxide film, 208: semiconductor layer, 210: pixel, 212a: conductive layer, 212b: conductive layer, 212f: conductive film, 230B: pixel, 230G: pixel, 230R: pixel, 230X: pixel, 230: pixel, 231: first driver circuit portion, 232: second driver circuit portion, 233: insulating layer, 234: conductive layer, 235: insulating layer, 236: wiring, 237: pixel, 238: wiring, 240a: pixel, 240b: pixel, 240: pixel, 300: transistor, 310: substrate, 312: element isolation layer, 313: semiconductor region, 314a: low-resistance region, 314b: low-resistance region, 315: insulating layer, 316: conductive layer, 317: insulating layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 441: timing controller, 442: input/output circuit, 500: display module, 501: printed wiring board, 502: terminal portion, 503: wire, 504: FPC, 505: connection portion, 512: insulating layer, 514: conductive layer, 574: insulating layer, 581: insulating layer, 592: insulating layer, 594: insulating layer, 596: conductive layer, 598: insulating layer, 599: insulating layer, 4411: light-emitting layer, 4412: light-emitting layer, 4413: light-emitting layer, 4420-1: layer, 4420-2: layer, 4420: layer, 4430-1: layer, 4430-2: layer, 4430: layer, 4440: intermediate layer, 6500: electronic appliance, 6501: housing, 6502: display portion, 6503: power button, 6504: button, 6505: speaker, 6506: microphone, 6507: camera, 6508: light source, 6510: protection member, 6511 display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a transistor and a first insulating layer,
wherein the transistor comprises a source electrode, a drain electrode, a semiconductor layer, a gate insulating layer, and a gate electrode,
wherein the source electrode and the drain electrode each comprise a top surface with any of a circular shape, an elliptical shape, and a polygonal shape with a rounded corner and are provided in columnar shapes to face each other to be embedded in the first insulating layer,
wherein the first insulating layer comprises an opening between the source electrode and the drain electrode,
wherein in the opening, the semiconductor layer is provided in contact with a side surface of the source electrode and a side surface of the drain electrode facing each other and a side surface of the first insulating layer between the source electrode and the drain electrode,
wherein in the opening, the gate insulating layer is provided in contact with a side surface of the semiconductor layer, and
wherein in the opening, the gate electrode is provided in contact with a side surface of the gate insulating layer to comprise a region facing the semiconductor layer.

2. The semiconductor device according to claim 1,
wherein the semiconductor layer comprises a metal oxide.

3. The semiconductor device according to claim 1,
wherein the first insulating layer comprises a second insulating layer, a third insulating layer over the second insulating layer, and a fourth insulating layer over the third insulating layer,
wherein the second insulating layer and the fourth insulating layer comprise one or both of a nitride and a nitride oxide, and
wherein the third insulating layer comprises one or both of an oxide and an oxynitride.

4. The semiconductor device according to claim 1,
wherein a top surface of the source electrode, a top surface of the drain electrode, and a top surface of the first insulating layer are substantially level with one another.

5. The semiconductor device according to claim 1,
wherein a top surface shape of the opening is any of a circle, an ellipse, a polygon with a rounded corner, and a closed curve that combines a straight line and a curve.

6. A method for manufacturing a semiconductor device, comprising:
forming a first insulating layer;
processing the first insulating layer to form a first opening and a second opening;
forming a first conductive film over the first insulating layer to fill the first opening and the second opening;
performing CMP treatment on the first conductive film until a top surface of the first insulating layer is exposed, thereby forming, in the first opening, a first conductive layer having a top surface substantially level with the top surface of the first insulating layer and forming, in the second opening, a second conductive layer having a top surface substantially level with the top surface of the first insulating layer;
processing the first insulating layer to form a third opening between the first conductive layer and the second conductive layer;
forming a first metal oxide film in contact with the top surface and a side surface of the first conductive layer, the top surface and a side surface of the second conductive layer, and the top surface and a side surface of the first insulating layer, thereby covering the third opening;
processing the first metal oxide film to form a semiconductor layer in contact with the side surface of the first conductive layer in the third opening, the side surface of the second conductive layer in the third opening, and the side surface of the first insulating layer in the third opening;
forming a second insulating layer over the semiconductor layer, the first conductive layer, the second conductive layer, and the first insulating layer;
forming a second conductive film over the second insulating layer; and
processing the second conductive film to form a third conductive layer that comprises a region overlapping with the semiconductor layer in a plan view.

7. The method for manufacturing a semiconductor device according to claim 6,
wherein the first insulating layer comprises a third insulating layer, a fourth insulating layer over the third insulating layer, and a fifth insulating layer over the fourth insulating layer,
wherein the third insulating layer and the fifth insulating layer are formed using a material comprising any one or more of a nitride and a nitride oxide, and
wherein the fourth insulating layer is formed using a material comprising any one or more of an oxide and an oxynitride.

8. The method for manufacturing a semiconductor device according to claim 6,
wherein anisotropic etching is used for processing the first metal oxide film.

9. The method for manufacturing a semiconductor device according to claim 6,
wherein etching treatment through a resist mask is used for processing the first metal oxide film.

10. The method for manufacturing a semiconductor device according to claim 6,
wherein a second metal oxide film is formed after formation of the third insulating layer and the fourth insulating layer, and
wherein a fifth insulating layer is formed after removal of the second metal oxide film.

11. The method for manufacturing a semiconductor device according to claim 6,
wherein a second metal oxide film is formed after formation of the third insulating layer and the fourth insulating layer, and
wherein heat treatment is performed after formation of the second metal oxide film.

12. The method for manufacturing a semiconductor device according to claim 6,
wherein a second metal oxide film is formed after formation of the third insulating layer and the fourth insulating layer, and
wherein treatment for supplying oxygen to the fourth insulating layer is performed after formation of the second metal oxide film.
